(19) United States
(12) Patent Application Publication
(10) Pub. No.: US 2026/0029869 A1
(43) Pub. Date: Jan. 29, 2026

(54) DISPLAY DEVICE

(71) Applicant: LG Display Co., Ltd., Seoul (KR)

(72) Inventors: Dohyeon KIM, Paju-si (KR); Wonchang DO, Paju-si (KR)

(73) Assignee: LG Display Co., Ltd., Seoul (KR)

(21) Appl. No.: 19/270,313

(22) Filed: Jul. 15, 2025

(30) Foreign Application Priority Data
Jul. 29, 2024 (KR) 10-2024-0100343

(51) Int. Cl. G06F 3/041; H10H 29/39

(52) U.S. Cl. CPC G06F 3/04164; H10H 29/39; G06F 2203/04102

(57) ABSTRACT

A display device can include a plurality of sub-touch driving areas disposed in a display area, a plurality of row lines arranged in each of the plurality of sub-touch driving areas, and a driving circuit corresponding to the plurality of sub-touch driving areas. The driving circuit supplies a touch driving signal to a plurality of row lines arranged in a target sub-touch driving area selected from among the plurality of sub-touch driving areas during a touch driving, thereby implementing the low-power driving.

### CROSS-REFERENCE TO RELATED APPLICATION

This application claims priority to Korean Patent Application No. 10-2024-0100343, filed in the Republic of Korea on Jul. 29, 2024, which is hereby expressly incorporated by reference for all purposes as if fully set forth herein into the present application.

### BACKGROUND

### Technical Field

Embodiments of the present disclosure relate to a display device.

### Discussion of the Related Art

A display device is applied to various electronic devices such as televisions, mobile phones, laptops, and tablets. A display device can include a self-luminous organic light emitting display (OLED), and a liquid crystal display (LCD) with a separate light source.

Recently, a display device with light emitting diodes (LED) is attracting attention as a next-generation display device. Since light emitting diodes are made of inorganic materials rather than organic materials, a display device with the light emitting diode has a characteristics of a faster lighting speed and superior light emitting efficiency, and can display high-luminance images compared to a liquid crystal display or an organic light emitting display.

### SUMMARY OF THE DISCLOSURE

Embodiments of the present disclosure can provide a display device capable of being driven by a new touch driving method by supplying a touch driving signal only to a part of touch electrodes.

Embodiments of the present disclosure can provide a display device capable of being driven with low power consumption by supplying a touch driving signal only to a part of touch electrodes.

Embodiments of the present disclosure can provide a display device capable of stably performing the touch driving by changing from a first driving mode in which some touch electrodes are driven to a second driving mode.

A display device according to embodiments of the present disclosure can include a plurality of sub-touch driving areas arranged in a display area, a plurality of row lines arranged in each of the plurality of sub-touch driving areas, and a driving circuit corresponding to the plurality of sub-touch driving areas, wherein the driving circuit supplies, during a touch driving, a touch driving signal to a plurality of row lines arranged in a target sub-touch driving area selected from the plurality of sub-touch driving areas.

A display device according to embodiments of the present disclosure can include a plurality of sub-touch driving areas disposed in a display area, a plurality of row lines and a plurality of column lines arranged in each of the plurality of sub-touch driving areas, a plurality of light emitting devices arranged in each of the plurality of sub-touch driving areas, and a driving circuit configured to drive the plurality of row lines and the plurality of column lines, wherein each of the plurality of column lines is electrically connected in common with a first electrode of two or more light emitting devices among the plurality of light emitting devices, wherein each of the plurality of row lines is electrically connected in common with a second electrode of two or more light emitting devices among the plurality of light emitting devices, wherein a first low-potential voltage is applied to at least some of a plurality of row lines arranged in each of the plurality of sub-touch driving areas during a display driving, and wherein a touch driving signal is applied to a plurality of row lines arranged in at least one of the plurality of sub-touch driving areas during a touch driving.

A display device according to embodiments of the present disclosure can include a first sub-touch driving area, a second sub-touch driving area disposed adjacent to the first sub-touch driving area, a first driver disposed between the first sub-touch driving area and the second sub-touch driving area, a third sub-touch driving area, a fourth sub-touch driving area disposed adjacent to the third sub-touch driving area, and a second driver disposed between the third sub-touch driving area and the fourth sub-touch driving area, wherein, when the first driver supplies a touch driving signal to one of the first sub-touch driving area and the second sub-touch driving area, the second driver does not supply a touch driving signal to the third sub-touch driving area and the fourth sub-touch driving area.

According to embodiments of the present disclosure, it is possible to provide a display device capable of being driven by a new touch driving method by supplying a touch driving signal only to a part of touch electrodes.

According to embodiments of the present disclosure, it is possible to provide a display device capable of being driven with low power consumption by supplying a touch driving signal only to a part of touch electrodes.

According to embodiments of the present disclosure, it is possible to provide a display device capable of stably performing the touch driving by changing from a first driving mode in which some touch electrodes are driven to a second driving mode.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 illustrates a display device according to embodiments of the present disclosure.

FIG. 2 is a plan view of a display device according to embodiments of the present disclosure.

FIG. 3 is a plan view of a display panel according to embodiments of the present disclosure.

FIG. 4 is a plan view of a unit driving area of a display panel according to embodiments of the present disclosure.

FIG. 5 illustrates a subpixel of a display panel according to embodiments of the present disclosure.

FIG. 6 is an equivalent circuit diagram of a unit driving area of a display panel according to embodiments of the present disclosure.

FIG. 7 illustrates a driving timing diagram for n row lines and one column line included in a first sub-driving area of a display panel according to embodiments of the present disclosure.

FIGS. 8 and 9 illustrate circuits for driving n light emitting devices connected to one column line included in a first sub-driving area of a display panel according to embodiments of the present disclosure.

FIG. 10 is a plan view of a display panel according to embodiments of the present disclosure.

FIG. 11 illustrates a unit driving area of a display panel according to embodiments of the present disclosure.

FIGS. 12 and 13 are plan views of a portion of a display panel according to embodiments of the present disclosure.

FIG. 14 is a cross-sectional view of a display panel according to embodiments of the present disclosure.

FIG. 15 is a detailed cross-sectional view of a display panel according to embodiments of the present disclosure, taken along the A-B cutting line of FIG. 10.

FIG. 16 is an enlarged cross-sectional view of a first subpixel of a display panel according to embodiments of the present disclosure.

FIG. 17 briefly illustrates a touch sensing structure of a display device according to embodiments of the present disclosure.

FIG. 18 illustrates a touch sensing system of a display device according to embodiments of the present disclosure.

FIG. 19 illustrates a touch driving structure of a display panel according to embodiments of the present disclosure.

FIG. 20 is a plan view of a touch pixel area of a display panel according to embodiments of the present disclosure.

FIG. 21 illustrates a driving situation for one touch pixel area during a display driving period of a display device according to embodiments of the present disclosure.

FIG. 22 illustrates a driving situation for one touch pixel area during a touch driving period of a display device according to embodiments of the present disclosure.

FIGS. 23 and 24 are driving timing diagrams of a display device according to embodiments of the present disclosure.

FIGS. 25-28 are example diagrams of a touch driving situation for one touch pixel area during a touch driving period of a display device according to embodiments of the present disclosure.

FIG. 29 schematically illustrates a touch control circuit, a first driver, a second driver, and sub-touch driving areas according to embodiments of the present disclosure.

FIG. 30 is a diagram regarding a determination of a defective touch sensitivity according to embodiments of the present disclosure.

FIG. 31 is an example diagram of a touch driving situation for one touch pixel area according to embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, and “constituting” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number, etc. of elements, but is used merely to distinguish the corresponding element from other elements.

When it is mentioned that a first element “is connected or coupled to”, “overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “overlap”, etc. each other via a fourth element. Here, the second element can be included in at least one of two or more elements that “are connected or coupled to”, “overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the present disclosure are described in detail with reference to the accompanying drawings. All the components of each display device according to all embodiments of the present disclosure are operatively coupled and configured.

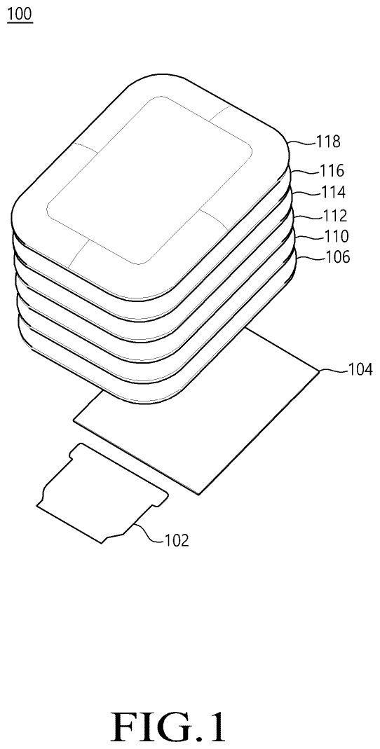

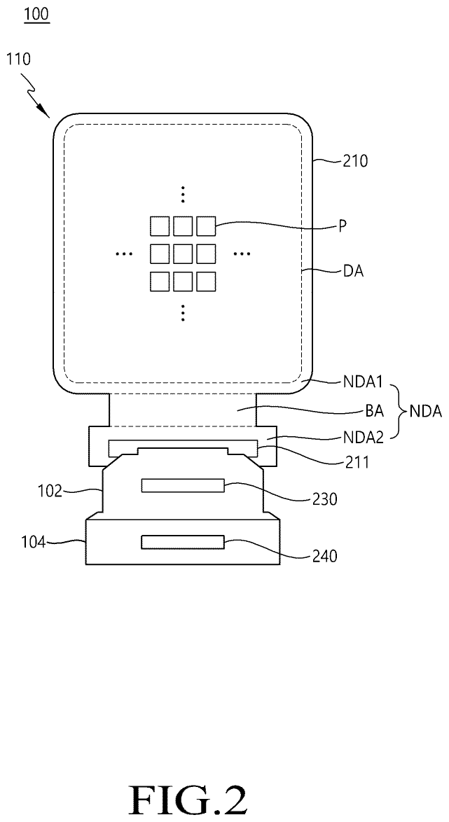

FIG. 1 illustrates a display device 100 according to embodiments of the present disclosure, and FIG. 2 is a plan view of a display device 100 according to embodiments of the present disclosure.

Referring to FIG. 1, the display device 100 according to the embodiments of the present disclosure can include a display panel 110, a cover member 118 disposed on the display panel 110, a flexible printed circuit 102 connected to the display panel 110, and a printed circuit board 104 connected to the flexible printed circuit 102.

The display device 100 according to the embodiments of the present disclosure can further include a support substrate 106 disposed under the display panel 110 and supporting the lower portion of the display panel 110, a polarizing layer 114 disposed on the display panel 110, a first adhesive layer 112 disposed between the display panel 110 and the polarizing layer 114, and a second adhesive layer 116 disposed between the polarizing layer 114 and the cover member 118.

The display panel 110 can include a substrate 210. The substrate 210 can be a member on which various components such as a plurality of metal layers and a plurality of insulating material layers are formed. The substrate 210 can be made of an insulating material. For example, the substrate 210 can be made of glass or resin. In addition, the substrate 210 can be made of a flexible material. For example, the substrate 210 can be made of a flexible plastic material such as polyimide (PI). However, the embodiments of the present disclosure are not limited thereto.

The display panel 110 can display information, videos, and/or images provided to a user. For example, the display panel 110 can include a display area DA and a non-display area NDA. For example, the substrate 210 can include a display area DA and a non-display area NDA. The display area DA and the non-display area NDA are not limited to the substrate 210, but can be described throughout the entire display device 100.

The display area DA can be an area where an image is displayed. The display area DA can include a plurality of pixels P. Each of the plurality of pixels P can be composed of a plurality of subpixels. At least one light emitting device can be arranged in each of the plurality of subpixels. The light emitting device can be configured differently depending on the type of the display device 100. For example, if the display device 100 is an inorganic light emitting display device, the light emitting device can be an inorganic-based light emitting device, such as a light emitting diode (LED), a micro LED, or a mini LED, but the embodiments of the present disclosure are not limited thereto.

The non-display area NDA can be an area where an image is not displayed. In the non-display area NDA, various wirings, and circuits for driving a plurality of pixels P of the display area DA can be arranged. For example, various driving circuits and various wirings can be arranged in the non-display area NDA, and a pad section 211 to which an integrated circuit and a printed circuit are connected can be arranged, but the embodiments of the present disclosure are not limited thereto.

For example, the driving circuit can include a data driving circuit and/or a gate driving circuit, but the embodiments of the present disclosure are not limited thereto. Wires or lines supplied with a control signal for controlling the driving circuit can be arranged on the substrate 210. For example, the control signal can include various timing signals including a clock signal, an input data enable signal, and synchronization signals, but the embodiments of the present disclosure are not limited thereto. The control signal can be supplied to the substrate 210 from the outside of the substrate 210 through the pad section 211. For example, circuit components such as a flexible printed circuit 102 and a printed circuit board 104 can be connected to the pad section 211.

According to the present embodiments, the non-display area NDA can include a first non-display area NDA1, a bending area BA, and a second non-display area NDA2. For example, the first non-display area NDA1 can be an area surrounding at least a portion of the display area DA. The bending area BA can be an area extending from at least one of a plurality of sides of the first non-display area NDA1 and can be a bendable area. The second non-display area NDA2 can be an area extending from the bending area BA and can include a pad section 211. For example, the bending area BA can be in a bent state, and the remaining area of the substrate 210 excluding the bending area BA can be in a flat state. In this case, as the bending area BA is bent, the second non-display area NDA2 can be located on the back surface of the display area DA. However, the embodiments of the present disclosure are not limited thereto.

The display area DA of the substrate 210 or the display device 100 can be configured in various shapes according to the design of the display device 100. For example, the display area DA can be configured in a rectangular shape with four corners formed in a round shape, but the embodiments of the present disclosure are not limited thereto. For another example, the display area DA can be configured in a rectangular shape with four corners formed in a right angle shape, a circular shape or the like, but the embodiments of the present disclosure are not limited thereto.

According to the embodiments of the present disclosure, a width of the second non-display area NDA2 where the pad section 211 is arranged can be wider than a width of the bending area BA. In addition, a width of the display area DA can be wider than the width of the bending area BA. In the drawing, the width of the bending area BA is depicted as being narrower than the width of other areas of the substrate 210, but the shape of the substrate 210 including the bending area BA is an example, and the embodiments of the present disclosure are not limited thereto.

Referring to FIGS. 1 and 2, a flexible printed circuit 102 and a printed circuit board 104 can be disposed at a lower portion of the display panel 110. The flexible printed circuit 102 and the printed circuit board 104 can be arranged at one edge of the display panel 110, but the embodiments of the present disclosure are not limited thereto. One side of the flexible printed circuit 102 can be connected to the display panel 110, and the other side can be connected to the printed circuit board 104, but the embodiments of the present disclosure are not limited thereto. The flexible printed circuit 102 can be a flexible film, but the embodiments of the present disclosure are not limited thereto.

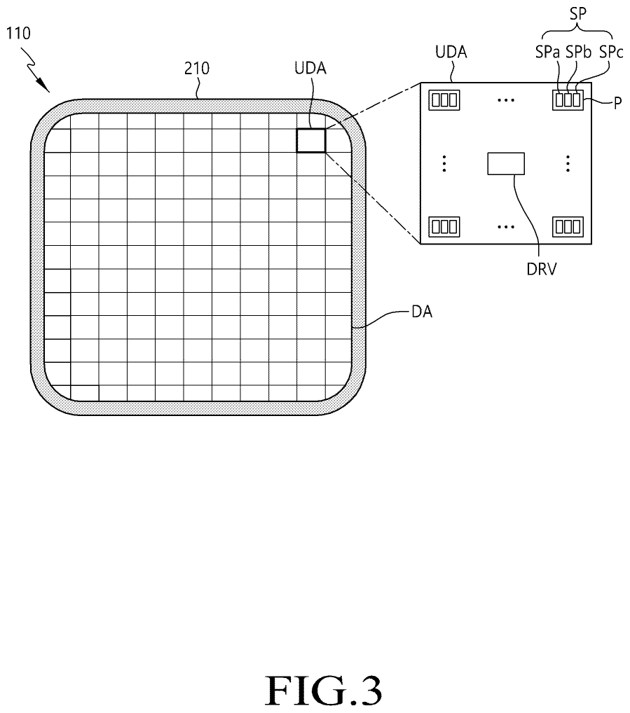

The pad section 211 disposed in the second non-display area NDA2 includes a plurality of pads, and a driving component including one or more flexible printed circuits 102 and a printed circuit board 104 can be attached or bonded. The plurality of pads included in the pad section 211 are electrically connected to one or more flexible printed circuits 102, and can transmit various signals (or power) from the printed circuit board 104 and one or more flexible printed circuits 102 to a driving circuit (for example, a driver DRV of FIG. 3) arranged in the display area DA.

The flexible printed circuit 102 can be a film in which various components are arranged on a flexible base film. For example, a first circuit component 230, such as a gate drive integrated circuit and/or a data drive integrated circuit, can be arranged on one or more flexible printed circuits 102, but the embodiments of the present disclosure are not limited thereto. The first circuit component 230 can be a component that processes data and a driving signal for displaying an image. The first circuit component 230 can be arranged in a manner such as a chip-on-glass (COG), a chip-on-film (COF), or a tape carrier package (TCP) depending on the mounting method, but the embodiments of the present disclosure are not limited thereto. The flexible printed circuit 102 can be attached or bonded to a plurality of pads through a conductive adhesive layer, but the embodiments of the present disclosure are not limited thereto.

The printed circuit board 104 can be a component that is electrically connected to the flexible printed circuit 102 and supplies a signal to the first circuit component 230. The printed circuit board 104 can be arranged on one side of the flexible printed circuit 102 and can be electrically connected to the flexible printed circuit 102. Various components for supplying various signals to the first circuit component 230 can be arranged on the printed circuit board 104. For example, various second circuit components 240, such as a timing controller, a power supply, a memory, or a processor, can be arranged on the printed circuit board 104. For example, the second circuit components 240 arranged on the printed circuit board 104 can include a timing controller and/or a power management integrated circuit (PMIC), but the embodiments of the present disclosure are not limited thereto.

The printed circuit board 104 can include at least one hole, but the embodiments of the present disclosure are not limited thereto. An internal component detecting ambient light or temperature, such as a plurality of sensors, can be arranged in an area corresponding to at least one hole. For example, the internal component can include an ambient light sensor (ALS) or a temperature sensor, but the embodiments of the present disclosure are not limited thereto. For example, the hole can be a transmission hole, but the embodiments of the present disclosure are not limited thereto.

Referring to FIG. 1, a polarizing layer 114 can be arranged on a display panel 110 and can prevent or reduce light generated from an external light source from entering the display panel 110 and affecting a light emitting device.

A cover member 118 can be arranged on a polarizing layer 114 and can be a member for protecting the display panel 110.

A second adhesive layer 116 can be disposed between the polarizing layer 114 and the cover member 118. The second adhesive layer 116 can attach the cover member 118 to the display panel 110 or the polarizing layer 114.

A first adhesive layer 112 can be disposed between the display panel 110 and the polarizing layer 114. The first adhesive layer 112 can attach the polarizing layer 114 to the display panel 110. The first adhesive layer 112 can be omitted.

Each of the first adhesive layer 112 and the second adhesive layer 116 can include an optically clear adhesive (OCA), an optically clear resin (OCR), or a pressure sensitive adhesive (PSA), but the embodiments of the present disclosure are not limited thereto.

The support substrate 106 is disposed between the display panel 110 and the printed circuit board 104 to reinforce the rigidity of the display panel 110. The support substrate 106 can be a back plate, but the embodiments of the present disclosure are not limited thereto.

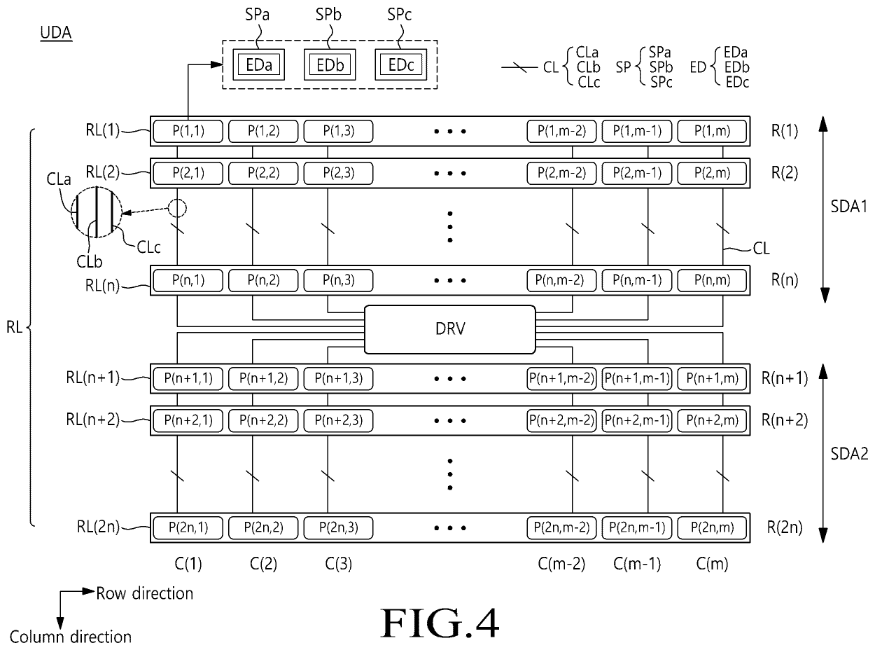

FIG. 3 is a plan view of a display panel 110 according to embodiments of the present disclosure, and FIG. 4 is a plan view of a unit driving area UDA of a display panel 110 according to embodiments of the present disclosure.

Referring to FIG. 3, the display area DA of the display panel 110 according to the embodiments of the present disclosure can include a plurality of unit driving areas UDA.

The display panel 110 according to the embodiments of the present disclosure can include a driver DRV arranged in each of the plurality of unit driving areas UDA. For example, the driver DRV can be a driving chip manufactured using a MOSFET (Metal-oxide-semiconductor field effect transistor) manufacturing process on a semiconductor substrate, but the embodiments of the present disclosure are not limited thereto.

Each of the plurality of unit driving areas UDA can be a driving area driven by one driver DRV. For example, the plurality of unit driving areas UDA can be independent driving areas driven by different drivers DRV.

The display panel 110 according to the embodiments of the present disclosure can include a substrate 210 including a display area DA, and a plurality of pixels P arranged in a matrix form in the display area DA.

A plurality of pixels P can be arranged in each of the plurality of unit driving areas UDA. Each of the plurality of pixels P can include a plurality of subpixels SP. Each of the plurality of subpixels SP can include at least one light emitting device.

For example, the plurality of subpixels SP can include a first subpixel SPa, a second subpixel SPb, and a third subpixel SPc, but is not limited thereto. The first subpixel SPa can include a first light emitting device that emits a first color light, the second subpixel SPb can include a second light emitting device that emits a second color light, and the third subpixel SPc can include a third light emitting device that emits a third color light. For example, the first color light, the second color light, and the third color light can be red light, green light, and blue light, respectively, but are not limited thereto.

Referring to FIG. 4, the display panel 110 according to the embodiments of the present disclosure can include a plurality of light emitting devices ED. Each of the plurality of subpixels SP can include a light emitting device ED.

For example, the first subpixel SPa can include a first light emitting device EDa, the second subpixel SPb can include a second light emitting device EDb, and the third subpixel SPc can include a third light emitting device EDc.

The display panel 110 according to the embodiments of the present disclosure can include a plurality of row lines RL and a plurality of column lines CL.

Each of the plurality of row lines RL can be arranged to extend in a row direction. The plurality of row lines RL can be electrically connected to a first electrode of each of a plurality of light emitting devices ED.

Each of the plurality of column lines CL can be arranged to extend in a column direction. The plurality of column lines CL can be electrically connected to a second electrode of each of the plurality of light emitting device ED.

For example, the first electrode of each of the plurality of light emitting device ED can be an anode electrode, and the second electrode of each of the plurality of light emitting device ED can be a cathode electrode. For another example, the first electrode of each of the plurality of light emitting device ED can be a cathode electrode, and the second electrode of each of the plurality of light emitting device ED can be an anode electrode.

Each of the plurality of row lines RL can be electrically connected to the second electrode of each of the plurality of light emitting device ED. For example, the second electrodes of each of the plurality of light emitting device ED can be commonly connected to one row line RL.

Each of the plurality of column lines CL can be electrically connected to the first electrode of each of the plurality of light emitting device ED. For example, the first electrode of each of the plurality of light emitting device ED can be commonly connected to one column line CL.

The line width of each of the plurality of row lines RL can be greater than the line width of each of the plurality of column lines CL.

The display panel 110 according to the embodiments of the present disclosure can include a plurality of drivers DRV. The plurality of drivers DRV can drive the plurality of light emitting device ED, the plurality of column lines CL, and the plurality of row lines RL.

The plurality of drivers DRV can be built into the display panel 110. The plurality of drivers DRV can be arranged in the display area DA, and can be arranged on the substrate 210. The plurality of drivers DRV can be arranged to correspond to a plurality of unit driving areas UDA. For example, one driver DRV can be arranged in one unit driving area UDA.

Each of the plurality of drivers DRV can drive a plurality of row lines RL and a plurality of column lines CL arranged in a corresponding unit driving area UDA among the plurality of unit driving areas UDA, thereby emitting light from a plurality of light emitting device ED arranged in the corresponding unit driving area UDA.

The plurality of drivers DRV are disposed in the display area DA, and can be positioned closer to the substrate 210 than the plurality of light emitting device ED.

For example, the plurality of row lines RL can be driven sequentially. For another example, the plurality of row lines RL can be driven simultaneously. For another example, two or more row lines RL among the plurality of row lines RL can be driven simultaneously.

For example, during a specific display driving period, among the plurality of row lines RL arranged in the unit driving area UDA, at least one row line RL can be driven, and the remaining row lines RL may not be driven.

According to the embodiments of the present disclosure, a voltage applied to the row line RL can be referred to as a low-potential voltage, and the low-potential voltage can also be referred to as a row line voltage or a cathode voltage. The low-potential voltage can have various voltage values depending on the driving type or driving state. For example, the low-potential voltage can include a first low-potential voltage, a second low-potential voltage, and a third low-potential voltage.

Driving the row line RL can mean that the first low-potential voltage is supplied to the row line RL. Not driving the row line RL can mean that the second low-potential voltage higher than the first low-potential voltage is supplied to the row line RL. Accordingly, the light emitting device ED overlapping with the driven row line RL can emit light, and the light emitting device ED overlapping with the non-driven row line RL may not emit light.

For example, any first row line RL among the plurality of row lines RL can be supplied with a first low-potential voltage during a first period, and can be supplied with a second low-potential voltage higher than the first low-potential voltage during a second period different from the first period. Accordingly, the light emitting devices ED overlapping with the first row line RL can emit light during the first period, and may not emit light during the second period different from the first period. For example, the first period and the second period can be included in one display driving period. For another example, the first period and the second period can be included in different display driving periods.

The structure of one unit driving area UDA will be described in more detail with reference to FIG. 4.

Referring to FIG. 4, as an example, one unit driving area UDA can be divided into a first sub-driving area SDA1 and a second sub-driving area SDA2. As another example, one unit driving area UDA can be divided into three or more sub-driving areas. As another example, one unit driving area UDA may not be divided into two or more sub-driving areas.

One unit driving area UDA can include one driver DRV and (2n×m) pixels P(1, 1), . . . , P(1, m), P(2, 1), . . . , P(2, m), . . . , P(2n, 1), . . . , P(2n, m) driven by one driver DRV.

In the embodiments of the present disclosure, n can be a sequence number of a row, or the number of rows in each of the first sub-driving area SDA1 and the second sub-driving area SDA2, or the number of row lines RL in each of the first sub-driving area SDA1 and the second sub-driving area SDA2, or the number of pixel rows in each of the first sub-driving area SDA1 and the second sub-driving area SDA2. m can be a sequence number of a column, or the number of columns in each of the first sub-driving area SDA1 and the second sub-driving area SDA2, or the number of column lines CL in each of the first sub-driving area SDA1 and the second sub-driving area SDA2, or the number of pixel columns in each of the first sub-driving area SDA1 and the second sub-driving area SDA2.

In the embodiments of the present disclosure, n can be a natural number greater than or equal to 1, and m can be a natural number greater than or equal to 1.

Here, (2n×m) pixels P(1, 1), . . . , P(1, m), P(2, 1), . . . , P(2, m), . . . , P(2n, 1), . . . , P(2n, m) can be arranged in 2n rows R(1), . . . , R(2n) and m columns C(1), . . . , C(m).

Among (2n×m) pixels P(1, 1), . . . , P(1, m), P(2, 1), . . . , P(2, m), . . . , P(2n, 1), . . . , P(2n, m), (n×m) pixels P(1, 1), . . . , P(1, m), P(2, 1), . . . , P(2, m), . . . , P(n, 1), . . . , P(n, m) arranged in the first to n-th rows R(1), . . . , R(n) can be arranged in the first sub-driving area SDA1.

Among (2n×m) pixels P(1, 1), . . . , P(1, m), P(2, 1), . . . , P(2, m), . . . , P(2n, 1), . . . , P(2n, m), (n×m) pixels P(n+1, 1), . . . , P(n+1, m), P(n+2, 1), . . . , P(n+2, m), . . . , P(2n, 1), . . . , P(2n, m) arranged in the (n+1)-th to the 2n-th row R (n+1), . . . , R(2n) can be arranged in the second sub-driving area SDA2.

One unit driving area UDA can include 2n row lines RL(1), . . . , RL(2n) to drive (2n×m) pixels P(1, 1), . . . , P(1, m), P(2, 1), . . . , P(2, m), . . . , P(2n, 1), . . . , P(2n, m).

Among the 2n row lines RL(1), . . . , RL(2n), the first to n-th row lines R(1), . . . , RL(n) can be arranged in the first sub-driving area SDA1. Among the 2n row lines RL(1), . . . , RL(2n), the (n+1)-th to the 2n-th row lines R (n+1), . . . , R(2n) can be arranged in the second sub-driving area SDA2.

Each of the 2n row lines RL(1), . . . , RL(2n) can overlap with m pixels. For example, the first row line RL(1) can overlap with m pixels P(1, 1), . . . , P(1, m) arranged in the first row R(1). The n-th row line RL(n) can overlap with m pixels P(n, 1), . . . , P(n, m) arranged in the n-th row (R(n)). The (n+1)-th row line RL (n+1) can overlap with the m pixels P(n+1, 1), . . . , P(n+1, m) arranged in the (n+1)-th row R (n+1). The 2n-th row line RL(2n) can overlap with the m pixels P(2n, 1), . . . , P(2n, m) arranged in the 2nth row R(2n).

For example, the first row line RL(1) can be connected to the k subpixels SPa, SPb and SPc included in each of the m pixels P(1, 1), . . . , P(1, m) arranged in the first row R(1). More specifically, the first row line RL(1) can be connected to the second electrodes of the k light emitting devices EDa, EDb and EDc included in each of the m pixels P(1, 1), . . . , P(1, m) arranged in the first row R(1).

For example, the n-th row line RL(n) can be connected to the k subpixels SPa, SPb and SPc included in each of the m pixels P(n, 1), . . . , P(n, m) arranged in the n-th row R(n). More specifically, the n-th row line RL(n) can be connected to the first electrodes of the k light emitting devices EDa, EDb and EDc included in each of the m pixels P(n, 1), . . . , P(n, m) arranged in the n-th row R(n).

For example, the (n+1)-th row line RL (n+1) can be connected to k subpixels SPa, SPb and SPc included in each of m pixels P(n+1, 1), . . . , P(n+1, m) arranged in the (n+1)-th row R (n+1). More specifically, the (n+1)-th row line RL (n+1) can be connected to first electrodes of k light emitting devices EDa, EDb and EDc included in each of m pixels P(n+1, 1), . . . , P(n+1, m) arranged in the (n+1)-th row R (n+1).

For example, the 2n-th row line RL(2n) can be connected to k subpixels SPa, SPb and SPc included in each of m pixels P(2n, 1), . . . , P(2n, m) arranged in the 2n-th row R(2n). More specifically, the 2n-th row line RL(2n) can be connected to first electrodes of k light emitting devices EDa, EDb and EDc included in each of m pixels P(2n, 1), . . . , P(2n, m) arranged in the 2n-th row R(2n).

One unit driving area UDA can include (m×k×2) column lines CL to drive (2n×m) pixels P(1, 1), . . . , P(1, m), P(2, 1), . . . , P(2, m), . . . , P(2n, 1), . . . , P(2n, m). Here, k is the number of subpixels SP included in one pixel P. In the example of FIG. 4, k is 3. For example, one pixel P can include three subpixels SPa, SPb and SPc.

The first sub-driving area SDA1 can include (m×k) column lines CL to drive (n×m) pixels P(1, 1), . . . , P(1, m), . . . , P(n, 1), . . . , P(n, m) arranged in the first sub-driving area SDA1. In the example of FIG. 4, since k is 3, the first sub-driving area SDA1 can include 3 m column lines CL.

In the first sub-driving area SDA1, k column lines CLa, CLb and CLb can be arranged in each of the m columns C(1), . . . , C(m). In the example of FIG. 4, since k is 3, in the first sub-driving area SDA1, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 4, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), a second column line CLb can be commonly connected to the first electrodes of the n second light emitting devices EDb arranged in the corresponding column. In each of the m columns C(1), . . . , C(m), a third column line CL3 can be commonly connected to the first electrodes of the n third light emitting devices EDc arranged in the corresponding column.

The second sub-driving area SDA2 can include (m×k) column lines CL to drive (n×m) pixels P(n+1, 1), . . . , P(n+1, m), . . . , P(2n, 1), . . . , P(2n, m) arranged in the second sub-driving area SDA2. In the example of FIG. 4, since k is 3, the second sub-driving area SDA2 can include 3 m column lines CL.

In the second sub-driving area SDA2, k column lines CL can be arranged in each of the m columns C(1), . . . , C(m). In the example of FIG. 4, since k is 3, in the second sub-driving area SDA2, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 4, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), the second column line CLb can be commonly connected to the first electrodes of the n second light emitting devices EDb arranged in the corresponding column. In each of the m columns C(1), . . . , C(m), the third column line CL3 can be commonly connected to the first electrodes of the n third light emitting devices EDc arranged in the corresponding column.

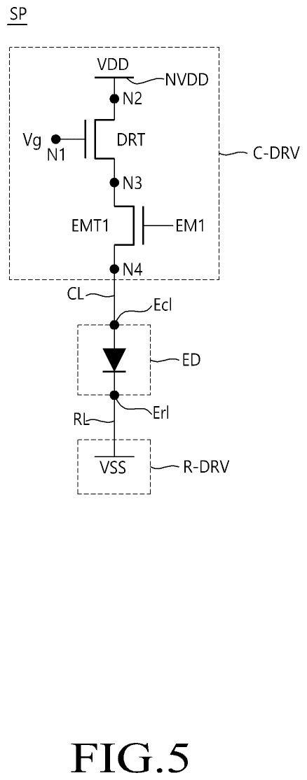

FIG. 5 illustrates a subpixel SP of a display panel 110 according to embodiments of the present disclosure.

Referring to FIG. 5, the subpixel SP according to embodiments of the present disclosure can include a light emitting device ED including a first electrode Ecl and a second electrode Erl, a column driver C-DRV for driving a column line CL electrically connected to the first electrode Ecl of the light emitting device ED, and a row driver R-DRV for driving a row line RL electrically connected to the second electrode Erl of the light emitting device ED.

The light emitting device ED can include a first electrode Ecl and a second electrode Erl. The first electrode Ecl can be electrically connected to a column line CL, and the second electrode Erl can be electrically connected to a row line RL. For example, the first electrode Ecl can be an anode electrode, and the second electrode Erl can be a cathode electrode. For another example, the first electrode Ecl can be a cathode electrode, and the second electrode Erl can be an anode electrode.

A column driver C-DRV included in a unit driving area UDA can be connected to a plurality of column lines CL included in the unit driving area UDA, and can drive a plurality of column lines CL included in the unit driving area UDA. Each of the plurality of column lines CL can be commonly connected to the first electrode Ecl of each of the plurality of light emitting devices ED included in the plurality of subpixels SP arranged in the corresponding column.

A row driver R-DRV included in a unit driving area UDA can be connected to a plurality of row lines RL included in the unit driving area UDA and can drive a plurality of row lines RL included in the unit driving area UDA. Each of the plurality of row lines RL can be commonly connected to a second electrode Erl of each of a plurality of light emitting devices ED included in a plurality of subpixels SP arranged in the corresponding row.

The column driver C-DRV can include main nodes including a first node N1, a second node N2, a third node N3, and a fourth node N4. The column driver C-DRV can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied, also referred to as a driving voltage node. The third node N3 can be a node to which the driving transistor DRT and the first emission control transistor EMT1 are connected. The fourth node N4 can be a node to which the first emission control transistor EMT1 and the light emitting device ED are electrically connected, and can be a node to which the column line CL is electrically connected. Here, a source electrode or a drain electrode of the first emission control transistor EMT1 and the first electrode Ecl of the light emitting device ED can be commonly connected to the column line CL.

The driving transistor DRT supplies a driving current to make the light emitting device ED emit light, is connected between the second node N2 and the third node N3, and can control the connection between the second node N2 and the third node N3 according to the voltage of the first node N1.

The gate electrode of the driving transistor DRT is electrically connected to the first node N1, and a gate voltage Vg can be applied thereto. The drain electrode or the source electrode of the driving transistor DRT can be electrically connected to the second node N2. The source electrode or the drain electrode of the driving transistor DRT can be electrically connected to the third node N3.

The first emission control transistor EMT1 can control a connection of a path through which the driving current flows, and can play a role in controlling an emission of the light emitting device ED.

If the driving transistor DRT and the first emission control transistor EMT1 are turned on between a high potential voltage VDD and a low-potential voltage VSS, the driving current can be supplied to the light emitting device ED through the driving transistor DRT and the first emission control transistor EMT1. Accordingly, the light emitting device ED can emit light.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or drain electrode of the first emission control transistor EMT1 can be electrically connected to the fourth node N4.

The first emission control signal EM1 can be a pulse width modulation signal that varies at a predefined time (for example, each frame, or each sub-frame included in one frame), but the embodiments of the present disclosure are not limited thereto.

The first emission control signal EM1 can be generated by the driver DRV, or can be supplied to the driver DRV from a driving-related circuit such as a timing controller.

The row driver R-DRV can drive at least one row line RL by supplying a low-potential voltage VSS to at least one row line RL.

The row driver R-DRV can perform display-on driving or display-off driving for one row line RL.

The row driver R-DRV can supply a low-potential voltage for display-on driving to one row line RL in order to perform display-on driving for one row line RL. The row driver R-DRV can supply a low-potential voltage for display-off driving to one row line RL in order to perform display-off driving for one row line RL.

A low-potential voltage for display-on driving and a low-potential voltage for display-off driving can be different. For example, the low-potential voltage for display-on driving can be lower than the low-potential voltage for display-off driving. In the embodiments of the present disclosure, the “low-potential voltage for display-on driving” is also referred to as the “first low-potential voltage,” and the “low-potential voltage for display-off driving” is also referred to as the “second low-potential voltage.”

The column driver C-DRV can further include at least one switching element and/or at least one transistor in addition to the driving transistor DRT and the first emission control transistor EMT1. Each of the transistors included in the column driver C-DRV can be an n-type transistor or a p-type transistor.

The column driver C-DRV can further include at least one capacitor.

The column driver C-DRV can further include at least one circuit element. For example, the at least one circuit element can include a power output buffer.

The row driver R-DRV can include at least one switching element and/or at least one transistor. Each of the transistors included in the row driver R-DRV can be an n-type transistor or a p-type transistor.

The row driver R-DRV can further include at least one circuit element. For example, at least one circuit element can include a power output buffer.

The column driver C-DR V and the row driver R-DRV can be internal circuits included in the driver DRV. As another example, the column driver C-DRV and the row driver R-DRV may not be included in the driver DRV and can be circuits formed on the substrate 210 of the display panel 110.

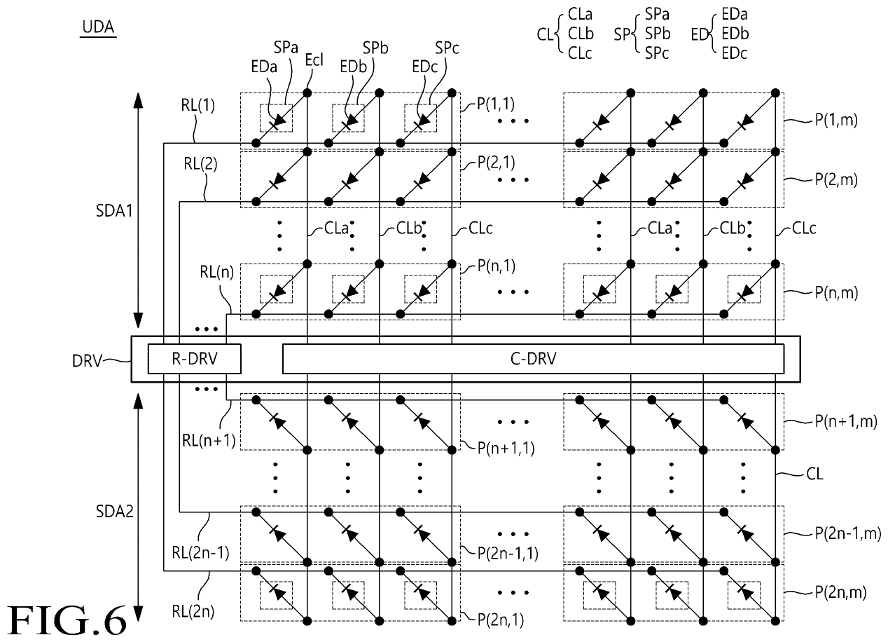

FIG. 6 is an equivalent circuit diagram of a unit driving area UDA of a display panel 110 according to embodiments of the present disclosure. In the following description, FIG. 4 and FIG. 5 are also referred to.

Referring to FIG. 6, each of the plurality of unit driving areas UDA can correspond to one driver DRV among the plurality of drivers DRV. For example, one driver DRV among the plurality of drivers DRV can be arranged in each of the plurality of unit driving areas UDAs.

Each of the plurality of unit driving areas UDAs can include two or more row lines RL(1) to RL(2n) among all row lines RL arranged in the display panel 110 and two or more column lines CL among all column lines CL arranged in the display panel 110.

Each of the plurality of unit driving areas UDAs can include a first sub-driving area SDA1 and a second sub-driving area SDA2. Some of the two or more row lines RL(1) to RL(2n) can be arranged in the first sub-driving area SDA1, and the rest can be arranged in the second sub-driving area SDA2. Some of the two or more column lines CL can be arranged in the first sub-driving area SDA1, and the rest can be arranged in the second sub-driving area SDA2.

Each of the plurality of unit driving areas UDAs can include a plurality of pixels P(1, 1), . . . , P(1, m), P(2, 1), . . . , P(2, m), . . . , P(2n, 1), . . . , P(2n, m) arranged in a matrix form.

Each of the plurality of pixels P(1, 1), . . . , P(1, m), P(2, 1), . . . , P(2, m), . . . , P(2n, 1), . . . , P(2n, m) can include k subpixels SPa, SPb and SPc. The k subpixels SPa, SPb and SPc can include k light emitting devices EDa, EDb and EDc.

Some of the plurality of pixels P(1, 1), . . . , P(1, m), P(2, 1), . . . , P(2, m), . . . , P(2n, 1), . . . , P(2n, m) can be arranged in the first sub-driving area SDA1, and the rest can be arranged in the second sub-driving area SDA2.

The k is the number of subpixels included in one pixel. In the example of FIG. 6, k is 3. For example, one pixel can include three subpixels SPa, SPb and SPc. Hereinafter, it will be described the structure of the unit driving area UDA is an example explained based on an example where k is 3.

The unit driving area UDA can include (2n×m) pixels P(1, 1), . . . , P(1, m), P(2, 1), . . . , P(2, m), . . . , P(2n, 1), . . . , P(2n, m). The (2n×m) pixels P(1, 1), . . . , P(1, m), P(2, 1), . . . , P(2, m), . . . , P(2n, 1), . . . , P(2n, m) can be arranged in 2n rows and m columns.

According to the example of FIG. 6, each of the (2n×m) pixels P(1, 1), . . . , P(1, m), P(2, 1), . . . , P(2, m), . . . , P(2n, 1), . . . , P(2n, m) can include three subpixels SPa, SPb and SPc.

According to the example of FIG. 6, three subpixels can include a first subpixel SPa including a first light emitting device EDa, a second subpixel SPb including a second light emitting device EDb, and a third subpixel SPc including a third light emitting device EDc.

Half of the (2n×m) pixels P(1, 1), . . . , P(1, m), P(2, 1), . . . , P(2, m), . . . , P(2n, 1), . . . , P(2n, m), which are (n×m) pixels P(1, 1), . . . , P(1, m), . . . , P(n, 1), . . . , P(n, m), can be arranged in the first sub-driving area SDA1.

Among the (2n×m) pixels P(1, 1), . . . , P(1, m), P(2, 1), . . . , P(2, m), . . . , P(2n, 1), . . . , P(2n, m), the remaining half (n×m) pixels P(n+1, 1), . . . , P(n+1, m), . . . , P(2n, 1), . . . , P(2n, m) can be arranged in the second sub-driving area SDA2.

According to the example of FIG. 6, the unit driving area UDA can include 2n row lines RL(1) to RL(2n) and (m×3×2) column lines CL.

Here, n row lines RL(1) to RL(n), which are half of 2n row lines RL(1) to RL(2n), can be arranged in the first sub-driving area SDA1, and n row lines RL (n+1) to RL(2n), which are the remaining half of 2n row lines RL(1) to RL(2n), can be arranged in the second sub-driving area SDA2.

The n row lines RL(1)˜RL(n) arranged in the first sub-driving area SDA1 can correspond to (n×m) pixels P(1, 1), . . . , P(1, m), . . . , P(n, 1), . . . , P(n, m) arranged in the first sub-driving area SDA1 by row (i.e., pixel row).

For example, among the n row lines RL(1) to RL(n) arranged in the first sub-driving area SDA1, the first row line RL(1) arranged in the first row (i.e., the first pixel row) can correspond to m pixels P(1, 1), . . . , P(1, m) included in the first pixel row. The first row line RL(1) can be electrically connected to all of the second electrodes Erl of each of the 3 m light emitting devices ED included in the first pixel row.

For another example, among the n row lines RL(1) to RL(n) arranged in the first sub-driving area SDA1, the second row line RL(2) arranged in the second row (i.e., the second pixel row) can correspond to m pixels P(2, 1), . . . , P(2, m) included in the second pixel row. The second row line RL(2) can be electrically connected to all of the second electrodes Erl of each of the 3 m light emitting devices ED included in the second pixel row.

For another example, among the n row lines RL(1) to RL(n) arranged in the first sub-driving area SDA1, the n-th row line RL(n) arranged in the n-th row (i.e., the n-th pixel row) can correspond to the m pixels P(n, 1), . . . , P(n, m) included in the n-th pixel row. The n-th row line RL(n) can be electrically connected to all of the second electrodes Erl of each of the 3 m light emitting devices ED included in the n-th pixel row.

The n row lines RL (n+1) to RL(2n) arranged in the second sub-driving area SDA2 can correspond to the (n×m) pixels P(n+1, 1), . . . , P(n+1, m), . . . , P(2n, 1), . . . , P(2n, m) arranged in the second sub-driving area SDA2 by row (i.e., pixel row).

For example, among the n row lines RL (n+1) to RL(2n) arranged in the second sub-driving area SDA2, the (n+1)-th row line RL (n+1) arranged in the (n+1)-th row (i.e., the (n+1)-th pixel row) can correspond to the m pixels P(n+1, 1), . . . , P(n+1, m) included in the (n+1)-th pixel row. The (n+1)-th row line RL (n+1) can be electrically connected to all of the second electrodes Erl of each of the 3 m light emitting devices ED included in the (n+1)-th pixel row.

For another example, among the n row lines RL (n+1) to RL(2n) arranged in the second sub-driving area SDA2, the (2n−1)-th row line RL(2n−1) arranged in the (2n−1)-th row (i.e., the (2n−1)-th pixel row) can correspond to the m pixels P(2n−1, 1), . . . , P(2n−1, m) included in the (2n−1)-th pixel row. The (2n−1)-th row line RL(2n−1) can be electrically connected to all of the second electrodes Erl of each of the 3 m light emitting devices ED included in the (2n−1)-th pixel row.

For another example, among the n row lines RL (n+1) to RL(2n) arranged in the second sub-driving area SDA2, the 2n-th row line RL(2n) arranged in the 2n-th row (i.e., 2n-th pixel row) can correspond to the m pixels P(2n, 1), . . . , P(2n, m) included in the 2n-th pixel row. The 2n-th row line RL(2n) can be electrically connected to all of the second electrodes Erl of each of the 3 m light emitting devices ED included in the 2n-th pixel row.

Further, 3 m column lines CL, which are half of the (m×3×2) column lines CL, can be arranged in the first sub-driving area SDA1, and the remaining half of the (m×3×2) column lines CL, which are 3 m column lines CL, can be arranged in the second sub-driving area SDA2.

Also, 3 m column lines CL arranged in the first sub-driving area SDA1 can correspond to (n×m) pixels P(1, 1), . . . , P(1, m), . . . , P(n, 1), . . . , P(n, m) placed in the first sub-driving area SDA1 by column (i.e., pixel column).

For example, among the 3 m column lines CL arranged in the first sub-driving area SDA1, three first column lines CLa, CLb and CLc arranged in a first column (i.e., the first pixel column) can correspond to n pixels P(1, 1), P(2, 1), . . . , P(n, 1) arranged in the first pixel column.

In the first sub-driving area SDA1, three first column lines CLa, CLb and CLc arranged in the first pixel column can be connected to three subpixels SPa, SPb and SPc included in each of n pixels P(1, 1), P(2, 1), . . . , P(n, 1) arranged in the first pixel column.

In the first sub-driving area SDA1, three first column lines CLa, CLb and CLc arranged in the first pixel column can be electrically connected to all of the first electrodes Ecl of three light emitting devices EDa, EDb and EDc included in each of n pixels P(1, 1), P(2, 1), . . . , P(n, 1) arranged in the first pixel column.

For example, among the 3 m column lines CL arranged in the first sub-driving area SDA1, three m-th column lines CLa, CLb and CLc arranged in a m-th column (i.e., m-th pixel column) can correspond to n pixels P(1, m), P(2, m), . . . , P(n, m) arranged in the m-th pixel column.

In the first sub-driving area SDA1, three m-th column lines CLa, CLb and CLc arranged in the m-th pixel column can be connected to three subpixels SPa, SPb and SPc included in each of n pixels P(1, m), P(2, m), . . . , P(n, m) arranged in the m-th pixel column.

In the first sub-driving area SDA1, three m-th column lines CLa, CLb and CLc arranged in the m-th pixel column can be electrically connected to all of the first electrodes Ecl of three light emitting devices EDa, EDb and EDc included in each of n pixels P(1, m), P(2, m), . . . , P(n, m) arranged in the m-th pixel column.

Further, 3 m column lines CL arranged in the second sub-driving area SDA2 can correspond to (n×m) pixels P(n+1, 1), . . . , P(n+1, m), . . . , P(2n, 1), . . . , P(2n, m) arranged in the second sub-driving area SDA2 by column (i.e., pixel column).

For example, among the 3 m column lines CL arranged in the second sub-driving area SDA2, three first column lines CLa, CLb and CLc arranged in the first column (i.e., the first pixel column) can correspond to n pixels P(n+1, 1), . . . , P(2n−1, 1), P(2n, 1) arranged in the first pixel column.

In the second sub-driving area SDA2, three first column lines CLa, CLb and CL arranged in the first pixel column can be connected to three subpixels SPa, SPb and SPc included in each of n pixels P(n+1, 1), . . . , P(2n−1, 1), P(2n, 1) arranged in the first pixel column.

In the second sub-driving area SDA2, the three first column lines CLa, CLb and CLc arranged in the first pixel column can be electrically connected to all of the first electrodes Ecl of the three light emitting devices EDa, EDb and EDc included in each of the n pixels P(n+1, 1), . . . , P(2n−1, 1), P(2n, 1) arranged in the first pixel column.

For example, among the 3 m column lines CL arranged in the second sub-driving area SDA2, the three m-th column lines CLa, CLb and CLc arranged in the m-th column (i.e., the m-th pixel column) can correspond to the n pixels P(n+1, m), . . . , P(2n−1, m), P(2n, m) arranged in the m-th pixel column.

In the second sub-driving area SDA2, three m-th column lines CLa, CLb and CLc arranged in the m-th pixel column can be connected to three subpixels SPa, SPb and SPc included in each of n pixels P(n+1, m), . . . , P(2n−1, m), P(2n, m) arranged in the m-th pixel column.

In the second sub-driving area SDA2, three m-th column lines CLa, CLb and CLc arranged in the m-th pixel column can be electrically connected to all of the first electrodes Ecl of three light emitting devices EDa, EDb and EDc included in each of n pixels P(n+1, m), . . . , P(2n−1, m), P(2n, m) arranged in the m-th pixel column.

Two or more row lines RL(1) to RL(2n) arranged in the unit driving area UDA can be electrically connected to the row driver R-DRV included in the driver DRV of the unit driving area UDA. Two or more column lines CL arranged in the unit driving area UDA can be electrically connected to the column driver C-DRV included in the driver DRV of the unit driving area UDA.

The driver DRV can be arranged between the first sub-driving area SDA1 and the second sub-driving area SDA2.

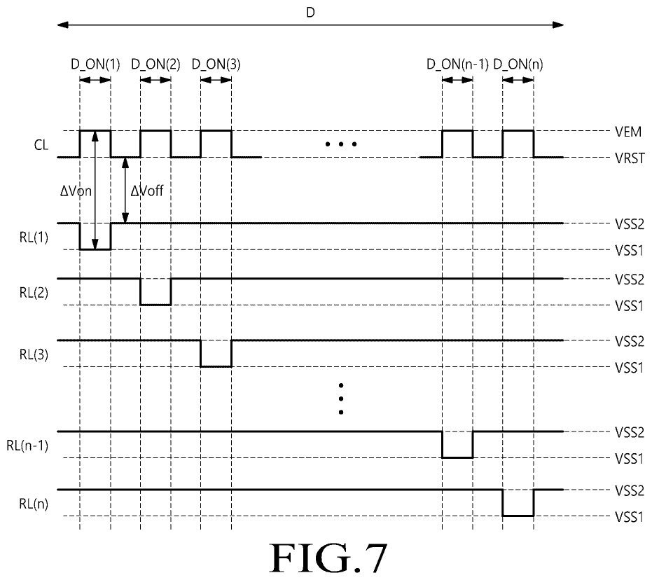

FIG. 7 illustrates a driving timing diagram for n row lines RL(1) to RL(n) and one column line CL included in a first sub-driving area SDA1 of a display panel 110 according to embodiments of the present disclosure. However, FIG. 6 is also referred to in the following description.

Referring to FIG. 7, the row driver R-DRV of the driver DRV can drive n row lines RL(1) to RL(n) arranged in the first sub-driving area SDA1.

The driving for each of the n row lines RL(1) to RL(n) arranged in the first sub-driving area SDA1 can include display-on driving for emitting light emitting devices ED arranged in each of the n row lines RL(1) to RL(n) and display-off driving for not emitting light emitting devices EDs arranged in each of the n row lines RL(1) to RL(n).

Hereinafter, it will be exemplified the driving sequence for each of the n row lines RL(1) to RL(n) arranged in the first sub-driving area SDA1.

For example, display-on driving for each of the plurality of row lines RL can be performed sequentially. As another example, display-on driving for each of the plurality of row lines RL can be performed simultaneously. As another example, display-on driving for each of two or more row lines RL among the plurality of row lines RL can be performed simultaneously. Hereinafter, for convenience of explanation, it will be described as an example a case in which display-on driving for each of the plurality of row lines RL is performed sequentially. However, it is not limited thereto.

The row driver R-DRV of the driver DRV can sequentially drive n row lines RL(1) to RL(n) arranged in the first sub-driving area SDA1. For example, display-on driving periods D_ON(1) to D_ON(n) for n row lines RL(1) to RL(n) arranged in the first sub-driving area SDA1 can be sequential.

Among the n row lines RL(1) to RL(n) arranged in the first sub-driving area SDA1, for any one row line RL, during the display driving period D, the display-on driving period D_ON(1) for the corresponding row line RL can exist at least once. During the display driving period D, all remaining times except the display-on driving period D_ON(1) for the corresponding row line RL can be display-off driving periods.

During any one display driving period D, among the n row lines RL(1) to RL(n) arranged in the unit driving area UDA, the display-on driving can be performed for at least one row line RL, and the display-on driving may not be performed for the remaining row lines RL, but the display-off driving can be performed.

For example, during any one display driving period D, among the n row lines RL(1) to RL(n) arranged in the unit driving area UDA, display-on driving can be performed for a first row line RL(1), and display-off driving can be performed for the second to n-th row lines RL(2) to RL(n).

For another example, during any one display driving period D, among the n row lines RL(1) to RL(n) arranged in the unit driving area UDA, display-on driving can be performed for the second row line RL(2), and display-on driving may not be performed for the first row line RL(1) and a third to n-th row lines RL(3) to RL(n).

For another example, during any one display driving period D, among the n row lines RL(1) to RL(n) arranged in the unit driving area UDA, display-on driving can be performed for the third row line RL(3), and display-off driving can be performed instead of display-on driving for the first and second row lines RL(1), RL(2) and the fourth to n-th row lines RL(4) to RL(n).

For another example, during any one display driving period D, among the n row lines RL(1) to RL(n) arranged in the unit driving area UDA, display-on driving can be performed for the (n−1)-th row line RL (n−1), and display-off driving can be performed instead of display-on driving for the first to (n−2)-th row lines RL(1) to RL (n−2) and the n-th row line RL(n).

For another example, during any one display driving period D, among the n row lines RL(1) to RL(n) arranged in the unit driving area UDA, display-on driving can be performed for the n-th row line RL(n), and display-off driving can be performed instead of display-on driving for the first to (n−1)-th row lines RL(1) to RL (n−1).

If display-on driving is performed for any row line RL among the n row lines RL(1) to RL(n) arranged in the unit driving area UDA, it can mean that a first low-potential voltage VSS1 of a predefined level is supplied to the corresponding row line RL. When display-on driving is performed for any row line RL, the light emitting devices ED arranged corresponding to the corresponding row line RL can emit light.

When display-off driving is performed for any row line RL among the n row lines RL(1) to RL(n) arranged in the unit driving area UDA without display-on driving, it can mean that a second low-potential voltage VSS2 of a predefined level is supplied to the corresponding row line RL. When display-off driving is performed for a specific row line RL, the light emitting devices ED arranged corresponding to the corresponding row line RL may not emit light.

The first low-potential voltage VSS1 can be a low-potential voltage VSS for display-on driving, and the second low-potential voltage VSS2 can be a low-potential voltage VSS for display-off driving. The second low-potential voltage VSS2 can be a voltage higher than the first low-potential voltage VSS1.

Any one row line RL among the n row lines RL(1) to RL(n) arranged in the unit driving area UDA can be supplied with the first low-potential voltage VSS1 during a first period, and can be supplied with the second low-potential voltage VSS2 higher than the first low-potential voltage VSS1 during a second period different from the first period. For example, the first period and the second period can be included in one display driving period D. For another example, the first period and the second period can be included in different display driving periods D.

For example, among the n row lines RL(1) to RL(n) arranged in the unit driving area UDA, the first row line RL(1) can be supplied with a first low-potential voltage VSS1 during a first display-on driving period D_ON(1), and can be supplied with a second low-potential voltage VSS2 higher than the first low-potential voltage VSS1 during a second to the n-th display-on driving period D_ON(2) to D_ON(n) different from the first display-on driving period D_ON(1).

For example, during the first display-on driving period D_ON(1), the first row line RL(1) can be supplied with a first low-potential voltage VSS1, and the second to n-th row lines RL(2) to RL(n) can be supplied with a second low-potential voltage VSS2. During the second display-on driving period D_ON(2), the second row line RL(2) can be supplied with a first low-potential voltage VSS1, and the first row line RL(1) and the third to n-th row lines RL(3) to RL(n) can be supplied with a second low-potential voltage VSS2.

For example, during the first display-on driving period D_ON(1), a plurality of light emitting devices ED overlapping with the first row line RL(1) and arranged in the first row can emit light, and a plurality of light emitting devices ED overlapping with the second to n-th row lines RL(2) to RL(n) and arranged in the second to n-th rows may not emit light. During the second display-on driving period D_ON(2), a plurality of light emitting devices ED overlapping with the second row line RL(2) and arranged in the second row can emit light, and a plurality of light emitting devices ED overlapping with the first row line RL(1) and the third to n-th row lines RL(3) to RL(n) and arranged in the first row and the third to n-th rows may not emit light.

For example, the first display-on driving period D_ON(1) and the second to the n-th display-on driving period D_ON(2) to D_ON(n) can be included in one display driving period D. For another example, the first display-on driving period D_ON(1) and the second to the n-th display-on driving period D_ON(2) to D_ON(n) can be included in different display driving periods D.

Further, (m×k) column lines CL can be arranged in a unit driving area UDA. In the unit driving area UDA, the (m×k) column lines CL can intersect with n row lines RL(1) to RL(n). The column line CL illustrated in FIG. 7 can be one of the (m×k) column lines CL.

During the display driving period D, each of the (m×k) column lines CL intersecting the n row lines RL(1) to RL(n) can be supplied with a display voltage VEM required to emit light from the corresponding light emitting device ED in synchronization with the display-on driving period D_ON(1) to D_ON(n) of each of the n row lines RL(1) to RL(n). Here, the display voltage VEM can also be referred to as a light emitting driving voltage or an emission driving voltage.

During the display driving period D, during all remaining times except for the display-on driving period D_ON(1) to D_ON(n) of each of the n row lines RL(1) to RL(n), a reset voltage VRST can be applied to each of the (m×k) column lines CL intersecting the n row lines RL(1) to RL(n).

The display voltage VEM can be a constant voltage or a voltage that varies depending on the image signal. The reset voltage VRST can be a voltage that is lower than the display voltage VEM, and can be a constant voltage or a variable voltage.

During the display driving period D, during the display-on driving period D_ON(1) to D_ON(n) of each of the n row lines RL(1) to RL(n), the voltage difference VEM-VSS1 between the display voltage VEM applied to the corresponding column line CL and the first low-potential voltage VSS1 applied to the corresponding row line RL can be a display-on voltage ΔVon.

A light emitting device ED can be connected between the corresponding column line CL and the corresponding row line RL. A display voltage VEM and a first low-potential voltage VSS1 can be applied to each of the first electrode Ecl and the second electrode Erl of the light emitting device ED.

The display-on voltage ΔVon is a voltage difference between the first electrode Ecl and the second electrode Erl of the light emitting device ED, and can be a voltage that can cause the light emitting device ED to emit light. For example, the display-on voltage ΔVon can be equal to or higher than a threshold voltage, which is a unique characteristic value of the light emitting device ED.

During the display driving period D, during all the remaining time except for the display-on driving period D_ON(1) to D_ON(n) of each of the n row lines RL(1) to RL(n), the voltage difference VRST-VSS2 between the reset voltage VRST applied to the corresponding column line CL and the second low-potential voltage VSS2 applied to the corresponding row line RL can be a display-off voltage ΔVoff.

A light emitting device ED can be connected between the corresponding column line CL and the corresponding row line RL. A reset voltage VRST and a second low-potential voltage VSS2 can be applied to each of the first electrode Ecl and the second electrode Erl of the light emitting device ED.

The display-off voltage ΔVoff is a voltage difference between the first electrode Ecl and the second electrode Erl of the corresponding light emitting device ED, and can be a voltage that does not allow the corresponding light emitting device ED to emit light. For example, the display-off voltage ΔVoff can be less than the threshold voltage, which is a unique characteristic value of the corresponding light emitting device ED. For example, the display-on voltage ΔVon can be greater than or equal to the display-off voltage ΔVoff.

Hereinafter, it will be described in more detail a circuit for driving n light emitting devices ED(1) to ED(n) connected to one column line CL in the display panel 110 according to embodiments of the present disclosure.

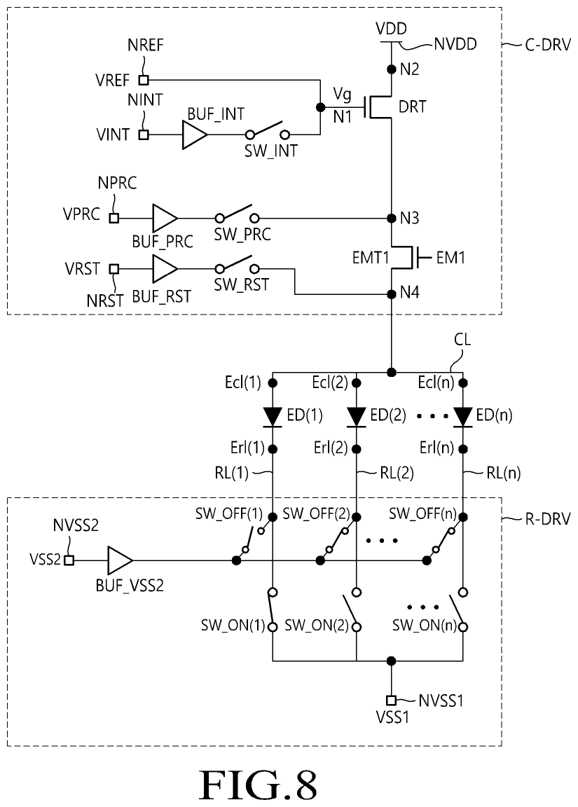

FIG. 8 illustrates a circuit for driving n light emitting devices ED(1) to ED(n) connected to one column line CL included in a first sub-driving area SDA1 of a display panel 110 according to embodiments of the present disclosure. FIG. 4 and FIG. 6 can also be referred to in the following description.

Referring to FIG. 8, n light emitting devices ED(1) to ED(n) connected to one column line CL can be arranged in the same column. The n light emitting devices ED(1) to ED(n) arranged in the same column can be connected to one column line CL. The n light emitting devices ED(1) to ED(n) connected to one column line CL can be arranged in one of the first sub-driving area SDA1 and the second sub-driving area SDA2 included in the unit driving area UDA.

The n light emitting devices ED(1) to ED(n) connected to one column line CL can be light emitting devices emitting the same color light. The n light emitting devices ED(1) to ED(n) arranged in the same column can be light emitting devices emitting the same color light.

For example, the n light emitting devices ED(1) to ED(n) arranged in the same column can emit light sequentially. As another example, the n light emitting devices ED(1) to ED(n) arranged in the same column can emit light simultaneously. As another example, two or more of n light emitting devices ED(1) to ED(n) arranged in the same column can emit light simultaneously.

Further, n light emitting devices ED(1) to ED(n) arranged in the same column can include first electrodes Ecl(1) to Ecl(n) and second electrodes Erl(1) to Erl(n).

All first electrodes Ecl(1) to Ecl(n) of n light emitting devices ED(1) to ED(n) arranged in the same column can be connected to one column line CL. The second electrodes Erl(1) to Erl(n) of the n light emitting devices ED(1) to ED(n) arranged in the same column can be respectively connected to the n row lines RL(1) to RL(n).

A circuit for driving the n light emitting devices ED(1) to ED(n) arranged in the same column can include a column driver C-DRV and a row driver R-DRV.

The column driver C-DRV can be configured to drive the column line CL connected to all of the first electrodes Ecl(1) to Ecl(n) of the n light emitting devices ED(1) to ED(n) arranged in the same column.

The row driver R-DRV can be configured to drive n row lines RL(1) to RL(n) which are respectively connected to the second electrodes Erl(1) to Erl(n) of n light emitting devices ED(1) to ED(n) arranged in the same column.

The column driver C-DRV can include first to fourth nodes N1 to N4, and can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the n light emitting devices ED(1) to ED(n) are electrically connected, and can be a node to which the column line CL is electrically connected. Here, the source electrode or the drain electrode of the first emission control transistor EMT1 and the first electrodes Ecl(1) to Ecl(n) of the n light emitting devices ED(1) to ED(n) can be commonly connected to the column line CL.

The driving transistor DRT supplies a driving current to emit light to n light emitting devices ED(1) to ED(n), is connected between the second node N2 and the third node N3, and can control the connection between the second node N2 and the third node N3 according to the voltage of the first node N1.

The gate electrode of the driving transistor DRT is electrically connected to the first node N1, and is supplied with a gate voltage Vg. The drain electrode or the source electrode of the driving transistor DRT can be electrically connected to the second node N2. The source electrode or the drain electrode of the driving transistor DRT can be electrically connected to the third node N3.

The first emission control transistor EMT1 can control the connection of a path through which the driving current flows, and can play a role in controlling an emission of the light emitting device ED.

The first emission control transistor EMT1 is connected between the third node N3 and the fourth node N4, and can control the connection between the third node N3 and the fourth node N4 according to the first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or the drain electrode of the first emission control transistor EMT1 can be electrically connected to the fourth node N4.

The first emission control signal EM1 can be a pulse width modulation signal that varies at a predefined time (for example, each frame, or each sub-frame included in one frame), but the embodiments of the present disclosure are not limited thereto.

The first emission control signal EM1 can be generated from the driver DRV or supplied to the driver DRV from a driving-related circuit such as a timing controller.

The column driver C-DRV can further include a reference voltage node NREF electrically connected to the first node N1. A reference voltage VREF can be applied to the reference voltage node NREF. Here, the reference voltage VREF can be a gate voltage Vg of the driving transistor DRT.

For example, the reference voltage VREF can have a constant voltage value.

For another example, the reference voltage VREF can have a different voltage value depending on the color of the light emitted from the light emitting device ED in which the display-on operation is performed. For example, the reference voltage VREF applied to the first node N1 during the driving period for emitting light of the light emitting device EDa emitting a first color light, the reference voltage VREF applied to the first node N1 during the driving period for emitting light of the light emitting device EDb emitting a second color light, and the reference voltage VREF applied to the first node N1 during the driving period for emitting light of the light emitting device EDe emitting a third color light can have different voltage values.

The column driver C-DRV can further include an initialization voltage node NINT electrically connected to the first node N1 through an initialization switch SW_INT. An initialization voltage VINT can be applied to the initialization voltage node NINT. Here, the initialization voltage VINT can be a gate voltage Vg of the driving transistor DRT.

The column driver C-DRV can further include an initialization buffer BUF_INT connected between the initialization switch SW_INT and the initialization voltage node NINT. The initialization buffer BUF_INT can amplify the initialization voltage VINT applied to the initialization voltage node NINT and supply an amplified initialization voltage to the first node N1.

The column driver C-DRV can further include a pre-charge voltage node NPRC electrically connected to a third node N3 through a pre-charge switch SW_PRC. A pre-charge voltage VPRC can be applied to the pre-charge voltage node NPRC.

The column driver C-DRV can further include a pre-charge buffer BUF_PRC connected between the pre-charge switch SW_PRC and the pre-charge voltage node NPRC. The pre-charge buffer BUF_PRC can amplify the pre-charge voltage VPRC applied to the pre-charge voltage node NPRC and supply the amplified pre-charge voltage to the third node N3.

The column driver C-DRV can further include a reset voltage node NRST electrically connected to a fourth node N4 through a reset switch SW_RST. A reset voltage VRST can be applied to the reset voltage node NRST.

The column driver C-DRV can further include a reset buffer BUF_RST connected between the reset switch SW_RST and the reset voltage node NRST. The reset buffer BUF_RST can amplify the reset voltage VRST applied to the reset voltage node NRST and supply the amplified reset voltage to the fourth node N4. Here, the fourth node N4 can be electrically connected to the corresponding column line CL.

The row driver R-DRV can be configured to drive n row lines RL(1) to RL(n) each connected to the second electrodes Erl(1) to Erl(n) of n light emitting devices ED(1) to ED(n) arranged in the same column.

The row driver R-DRV can include n display-on switches SW_ON(1) to SW_ON(n) that electrically connect each of n row lines RL(1) to RL(n) to a first low-potential voltage node NVSS1. A first low-potential voltage VSS1 can be applied to the first low-potential voltage node NVSS1.

The turn-on timing of each of the n display-on switches SW_ON(1) to SW_ON(n) can be different from each other. Accordingly, display-on driving for the n row lines RL(1) to RL(n) can be sequentially performed.

The row driver R-DRV can include n display-off switches SW_OFF(1) to SW_OFF(n) that electrically connect each of the n row lines RL(1) to RL(n) to a second low-potential voltage node NVSS2 to which a second low-potential voltage VSS2 is applied. The second low-potential voltage VSS2 can be a low-potential voltage higher than the first low-potential voltage VSS1. The row driver R-DRV can further include a second low-potential buffer BUF_VSS2 connected between the n display-off switches SW_OFF(1) to SW_OFF(n) and the second low-potential voltage node NVSS2.

The turn-on timing of each of the n display-off switches SW_OFF(1) to SW_OFF(n) can be different from each other. Accordingly, the display-off driving for the n display-off switches SW_OFF(1) to SW_OFF(n) can be performed at different timings.

According to the example of FIG. 8, the row driver R-DRV can perform display-on driving for the first row line RL(1) among the n row lines RL(1) to RL(n), and perform display-off driving for the second to n-th row lines RL(2) to RL(n).

To this end, among the n display-on switches SW_ON(1) to SW_ON(n), a first display-on switch SW_ON(1) can be in a turn-on state, and a second to n-th display-on switches SW_ON(2) to SW_ON(n) can be in a turn-off state. In addition, among the n display-off switches SW_OFF(1) to SW_OFF(n), the first display-off switch SW_OFF(1) can be in a turn-off state, and the second to n-th display-off switches SW_OFF(2) to SW_OFF(n) can be in a turn-on state.

Accordingly, among the n row lines RL(1) to RL(n), a first low-potential voltage VSS1 can be applied to the first row line RL(1), and a second low-potential voltage VSS2 can be applied to the second to n-th row lines RL(2) to RL(n). Here, the first low-potential voltage VSS1 can have a lower voltage value than the second low-potential voltage VSS2.

Each of the transistors DRT and EMT1 included in the column driver C-DRV can be an n-type transistor or a p-type transistor. The switches SW_ON(1) to SW_ON(n), and SW_OFF(1) to SW_OFF(n) included in the row driver R-DRV can be implemented as an n-type transistor or a p-type transistor. The column driver C-DRV can further include at least one capacitor.

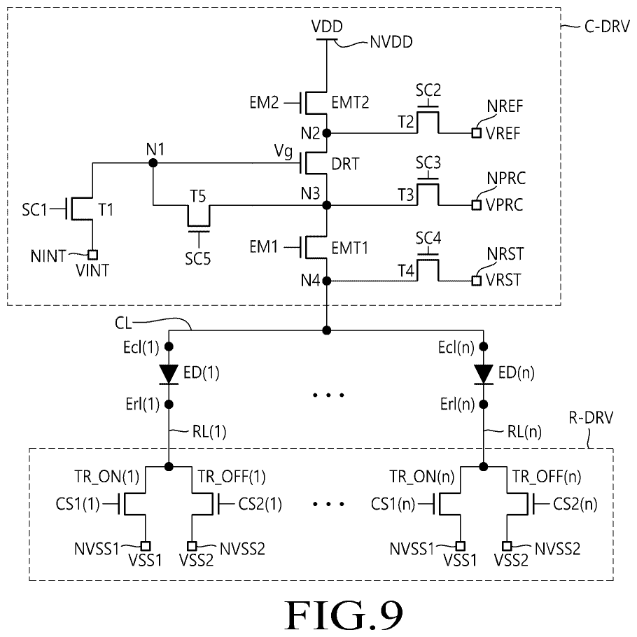

Hereinafter, it will be described the different circuit structures of the column driver C-DRV and the row driver R-DRV with reference to FIG. 9.

FIG. 9 illustrates another circuit for driving n light emitting devices ED(1) to ED(n) connected to one column line CL included in the first sub-driving area SDA1 of the display panel 110 according to the embodiments of the present disclosure. In the following description, the description of the same content as in the circuit of FIG. 8 can be omitted.

Referring to FIG. 9, n light emitting devices ED(1) to ED(n) connected to one column line CL can be arranged in the same column. The n light emitting devices ED(1) to ED(n) arranged in the same column can be connected to one column line CL. The n light emitting devices ED(1) to ED(n) connected to one column line CL can be arranged in one of the first sub-driving area SDA1 and the second sub-driving area SDA2 included in the unit driving area UDA.

The n light emitting devices ED(1) to ED(n) connected to one column line CL can be light emitting devices emitting the same color light. The n light emitting devices ED(1) to ED(n) arranged in the same column can be light emitting devices emitting the same color light.

The n light emitting devices ED(1) to ED(n) arranged in the same column can include first electrodes Ecl(1) to Ecl(n) and second electrodes Erl(1) to Erl(n).

The first electrodes Ecl(1) to Ecl(n) of the n light emitting devices ED(1) to ED(n) arranged in the same column can all be connected to one column line CL. The second electrodes Erl(1) to Erl(n) of the n light emitting devices ED(1) to ED(n) arranged in the same column can be respectively connected to the n row lines RL(1) to RL(n).

A circuit for driving the n light emitting devices ED(1) to ED(n) arranged in the same column can include a column driver C-DRV and a row driver R-DRV.

The column driver C-DRV can include first to fourth nodes N1 to N4, and can include a driving transistor DRT, a first emission control transistor EMT1, and a second emission control transistor EMT2.

The first node N1 can be a node to which a voltage Vg for controlling on-off of the driving transistor DRT is applied. The second node N2 can be a node to which the second emission control transistor EMT2 and the driving transistor DRT are connected. The third node N3 can be a node to which the driving transistor DRT and the first emission control transistor EMT1 are connected. The fourth node N4 can be a node to which the first emission control transistor EMT1 and the n light emitting devices ED(1) to ED(n) are electrically connected, and can be a node to which the column line CL is electrically connected. Here, the source electrode or the drain electrode of the first emission control transistor EMT1 and the first electrodes Ecl(1) to Ecl(n) of the n light emitting devices ED(1) to ED(n) can be commonly connected to the column line CL.

The driving transistor DRT supplies a driving current to emit light to n light emitting devices ED(1) to ED(n), is connected between the second node N2 and the third node N3, and can control the connection between the second node N2 and the third node N3 according to the voltage of the first node N1.

The gate electrode of the driving transistor DRT is electrically connected to the first node N1, and can be supplied with a gate voltage Vg. The drain electrode or the source electrode of the driving transistor DRT can be electrically connected to the second node N2. The source electrode or the drain electrode of the driving transistor DRT can be electrically connected to the third node N3.

The first emission control transistor EMT1 and the second emission control transistor EMT2 can control the connection of a path through which a driving current flows, and can play a role in controlling an emission of a light emitting device ED.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or the drain electrode of the first emission control transistor EMT1 can be electrically connected to the fourth node N4.

The first emission control signal EM1 can be a pulse width modulation signal that varies at a predefined time (for example, each frame, or each sub-frame included in a frame), but the embodiments of the present disclosure are not limited thereto. The first emission control signal EM1 can be generated by the driver DRV, or can be supplied to the driver DRV from a driving-related circuit such as a timing controller.

The second emission control transistor EMT2 is connected between the high-potential voltage node NVDD and the second node N2, and can control the connection between the high-potential voltage node NVDD and the second node N2 according to a second emission control signal EM2. The second emission control signal EM2 can be applied to the gate electrode of the second emission control transistor EMT2.

The drain electrode or the source electrode of the second emission control transistor EMT2 can be electrically connected to the high-potential voltage node NVDD. The source electrode or drain electrode of the second emission control transistor EMT2 can be electrically connected to the second node N2. Here, the second emission control signal EM2 can be the same as or different from the first emission control signal EM1.

The column driver C-DRV can further include a first transistor T1 whose on-off is controlled according to a first scan signal SC1 and which controls the connection between the first node N1 and the initialization voltage node NINT. Here, the initialization voltage VINT can be applied to the initialization voltage node NINT.

The column driver C-DRV can further include a second transistor T2 whose on-off is controlled according to a second scan signal SC2 and which controls the connection between the second node N2 and the reference voltage node NREF. Here, a reference voltage VREF can be applied to the reference voltage node NREF.

The column driver C-DRV can further include a third transistor T3 whose on-off is controlled according to a third scan signal SC3 and which controls the connection between the third node N3 and the pre-charge voltage node NPRC. Here, a pre-charge voltage VPRC can be applied to the pre-charge voltage node NPRC.

The column driver C-DRV can further include a fourth transistor T4 whose on-off is controlled according to a fourth scan signal SC4 and which controls the connection between the fourth node N4 and the reset voltage node NRST. Here, a reset voltage VRST can be applied to the reset voltage node NRST.

The column driver C-DRV can further include a fifth transistor T5 that controls the connection between the first node N1 and the third node N3 by controlling the on-off according to a fifth scan signal SC5. If the fifth transistor T5 is turned on, the first node N1 and the third node N3 are electrically connected, so that the driving transistor DRT can be in a diode-connected state. Here, for example, the fifth scan signal SC5 can be a scan signal that is different from or the same as the second scan signal SC2.

The row driver R-DRV can be configured to drive n row lines RL(1) to RL(n) that are respectively connected to the second electrodes Erl(1) to Erl(n) of n light emitting devices ED(1) to ED(n) arranged in the same column.

The row driver R-DRV can include n display-on transistors TR_ON(1) to TR_ON(n) that electrically connect each of n row lines RL(1) to RL(n) to a first low-potential voltage node NVSS1. A first low-potential voltage VSS1 can be applied to the first low-potential voltage node NVSS1. The n display-on transistors TR_ON(1) to TR_ON(n) can be turned on and off by n display-on control signals CS1(1) to CS1(n).

The turn-on timing of each of the n display-on transistors TR_ON(1) to TR_ON(n) can be different from each other. Accordingly, display-on driving for the n row lines RL(1) to RL(n) can be sequentially performed.

The row driver R-DRV can include n display-off transistors TR_OFF(1) to TR_OFF(n) that electrically connect each of n row lines RL(1) to RL(n) to a second low-potential voltage node NVSS2 to which a second low-potential voltage VSS2 is applied. The second low-potential voltage VSS2 can be a low-potential voltage higher than the first low-potential voltage VSS1. The n display-off transistors TR_OFF(1) to TR_OFF(n) can be turned on and off by n display-off control signals CS2(1) to CS2(n).

The turn-on timing of each of the n display-off transistors TR_OFF(1) to TR_OFF(n) can be different from each other. Accordingly, display-off driving for n display-off transistors TR_OFF(1) to TR_OFF(n) can be performed at different timings.

For example, one display-on transistor among n display-on transistors TR_ON(1) to TR_ON(n) and one display-off transistor among n display-off transistors TR_OFF(1) to TR_OFF(n) can be connected to each of n row lines RL(1) to RL(n).

Only one of the display-on transistors and display-off transistors connected to each of n row lines RL(1) to RL(n) can be selectively turned on.

For example, if a display-on driving is performed for the first row line RL(1) among the n row lines RL(1) to RL(n), among the first display-on transistor TR_ON(1) and the first display-off transistor TR_OFF(1) connected to the first row line RL(1), the first display-on transistor TR_ON(1) can be turned on and the first display-off transistor TR_OFF(1) can be turned off. At this time, if display-on driving is performed for the second to n-th row lines RL(2) to RL(n), among the display-on transistors and display-off transistors connected to each of the second to n-th row lines RL(2) to RL(n), the display-on transistor can be turned off and the display-off transistor can be turned on. Accordingly, a first low-potential voltage VSS1, which is a low-potential voltage for driving the display-on, can be applied only to the first row line RL(1) among the n row lines RL(1) to RL(n), and a second low-potential voltage VSS2, which is a low-potential voltage for driving the display-off, can be applied to the remaining second to n-th row lines RL(2) to RL(n). Referring to FIG. 9, the driving timing of the subpixel SP is as follows.

During a first driving period, the first transistor T1 among the first to fifth transistors T1 to T5 can be turned on, and the initialization voltage VINT can be applied to the first node N1. The driving transistor DRT can be turned on by the initialization voltage VINT applied to the first node N1.

Thereafter, during a second driving period, the second transistor T2 can be turned on, and the reference voltage VREF can be applied to the second node N2. In this case, the fifth transistor T5 can also be turned on.

Thereafter, during a third driving period, the third transistor T3 can be turned on, so that the pre-charge voltage VPRC can be applied to the third node N3.

Then, during a fourth driving period, one of the n light emitting devices ED(1) to ED(n) can emit light. During the fourth driving period, the light emitting devices in an emission state among the light emitting devices arranged in n row lines RL(1) to RL(n) can be supplied with the first low-potential voltage VSS1, which is a low-potential voltage for display-on driving, and the light emitting devices in a non-emission state can be supplied with the second low-potential voltage VSS2, which is a low-potential voltage for display-off driving.

To this end, among the n row lines RL(1) to RL(n), the row line on which display-on driving is performed can be supplied with the first low-potential voltage VSS1, and the remaining row lines on which display-off driving is performed can be supplied with the second low-potential voltage VSS2.

Therefore, among the display-on transistor and the display-off transistor connected to the row line where the display-on driving is performed, the display-on transistor can be in a turn-on state and the display-off transistor can be in a turn-off state.

Among the display-on transistor and the display-off transistor connected to the row line where the display-off driving is performed, the display-on transistor can be in a turn-off state and the display-off transistor can be in a turn-on state.

Thereafter, during a fifth driving period, the fourth transistor T4 can be turned on, so that the reset voltage VRST can be applied to the fourth node N4. Accordingly, the column line CL can be reset to the reset voltage VRST. In addition, all of the first electrodes Ecl(1) to Ecl(n) of the n light emitting devices ED(1) to ED(n) connected to the column line CL can be reset to the reset voltage VRST.

The first to fourth scan signals SC1 to SC4 and the first and second emission control signals EM1 and EM2 can be generated by the corresponding driver DRV, or can be supplied to the corresponding driver DRV from a driving-related circuit such as a timing controller.

Each of the transistors DRT and T1 to T5 included in the column driver C-DRV can be an n-type transistor or a p-type transistor. Each of the transistors TR_ON(1) to TR_ON(n) and TR_OFF(1) to TR_OFF(n) included in the row driver R-DRV can be an n-type transistor or a p-type transistor. The column driver C-DRV can further include at least one capacitor.

As described above, the column driver C-DRV and the row driver R-DRV can be included in the driver DRV.

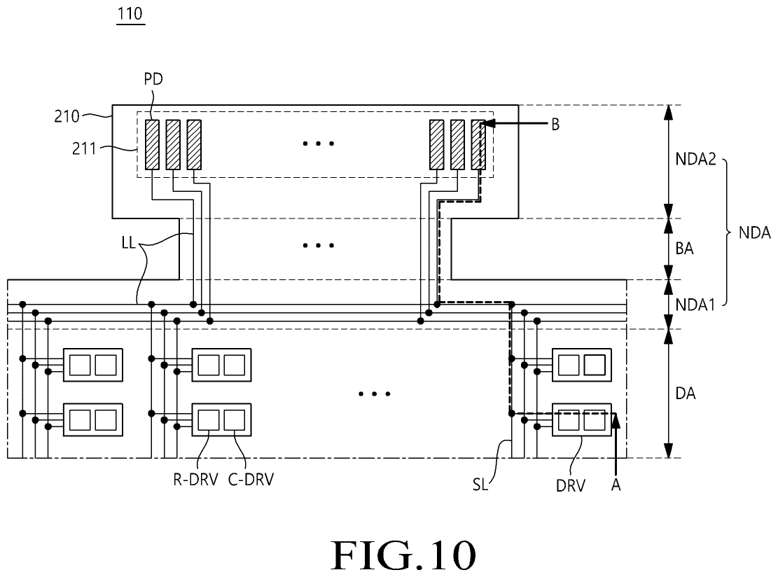

In order for the plurality of drivers DRV included in the display device 100 according to the embodiments of the present disclosure to perform a driving operation, the plurality of drivers DRV are required to be supplied with power required for the driving operation. Accordingly, hereinafter, it will be described a power supply structure for supplying power required for the driving operation to the plurality of drivers DRV with reference to FIG. 10.

FIG. 10 is a plan view of the display panel 110 according to the embodiments of the present disclosure.

Referring to FIG. 10, the substrate 210 of the display panel 110 according to the embodiments of the present disclosure can include a display area DA and a non-display area NDA, and the non-display area NDA can include a first non-display area NDA1, a bending area BA, and a second non-display area NDA2.

A plurality of drivers DRV can be arranged in the display area DA. Each of the plurality of drivers DRV can be a circuit for driving light emitting devices of a plurality of subpixels included in a corresponding unit driving area (UDA of FIGS. 4 and 6). Each of the plurality of drivers DRV can include a row driver R-DRV for driving a plurality of row lines and a column driver C-DRV for driving a plurality of column lines, in order to drive a plurality of light emitting devices ED included in a corresponding unit driving area (UDA of FIGS. 4 and 6).

A pad section 211 including a plurality of pads PD can be arranged in the second non-display area NDA2.

A plurality of signal lines SL and a plurality of link lines LL for signal transmission between a plurality of drivers DRV arranged in the display area DA and the pad section 211 can be arranged on the substrate 210. The plurality of signal lines SL can be electrically connected between the plurality of link lines LL and the plurality of drivers DRV. The plurality of link lines LL can electrically connect the plurality of pads PD and the plurality of signal lines SL.

The plurality of link lines LL can be arranged in the non-display area NDA, and all or part of each of the plurality of signal lines SL can be arranged in the display area DA.

Each of the plurality of drivers DRV can receive various signals to perform a driving operation through the plurality of link lines LL and the plurality of signal lines SL. Here, the various signals can include various power voltages and various signals required for the driving operation of each of the plurality of drivers DRV.

As the bending area BA is bent, a portion of the plurality of link lines LL can also be bent. Stress can be concentrated on a portion of the bent link line LL, and thus cracks can occur in the link line LL. Accordingly, the plurality of link lines LL can be formed of a conductive material having excellent ductility to reduce cracks when the bending area BA is bent. For example, the plurality of link lines LL can be formed of a conductive material having excellent ductility, such as gold (Au), silver (Ag), aluminum (Al), but the embodiments of the present disclosure are not limited thereto. In addition, the plurality of link lines LL can be composed of one of various conductive materials used in the display area DA. For example, the plurality of link lines LL can be composed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto. The plurality of link lines LL can be composed of a multilayer structure including various conductive materials. For example, the plurality of link lines LL can be composed of a triple layer structure of titanium (Ti)/aluminum (Al)/titanium (Ti), but the embodiments of the present disclosure are not limited thereto.

The plurality of link lines LL can be composed of various shapes to reduce stress. At least a portion of the plurality of link lines LL arranged on the bending area BA can extend in the same direction as the extension direction of the bending area BA, or can extend in a direction different from the extension direction of the bending area BA to reduce stress. For example, if the bending area BA extends in one direction from the first non-display area NDA1 toward the second non-display area NDA2, at least a portion of the link lines LL arranged on the bending area BA can extend in a direction oblique to the one direction. As another example, at least a portion of the plurality of link lines LL can be configured as patterns of various shapes. For example, at least a portion of the plurality of link lines LL arranged on the bending area BA can be a shape in which conductive patterns having at least one shape among a diamond shape, a rhombus shape, a trapezoidal wave shape, a triangular wave shape, a sawtooth wave shape, a sine wave shape, a circular shape, and an omega (Ω) shape are repeatedly arranged, but the embodiments of the present disclosure are not limited thereto. Therefore, in order to minimize the stress concentrated on the plurality of link lines LL and the resulting cracks, the shapes of the plurality of link lines LL can be formed in various shapes including the shapes described above, but the embodiments of the present disclosure are not limited thereto.

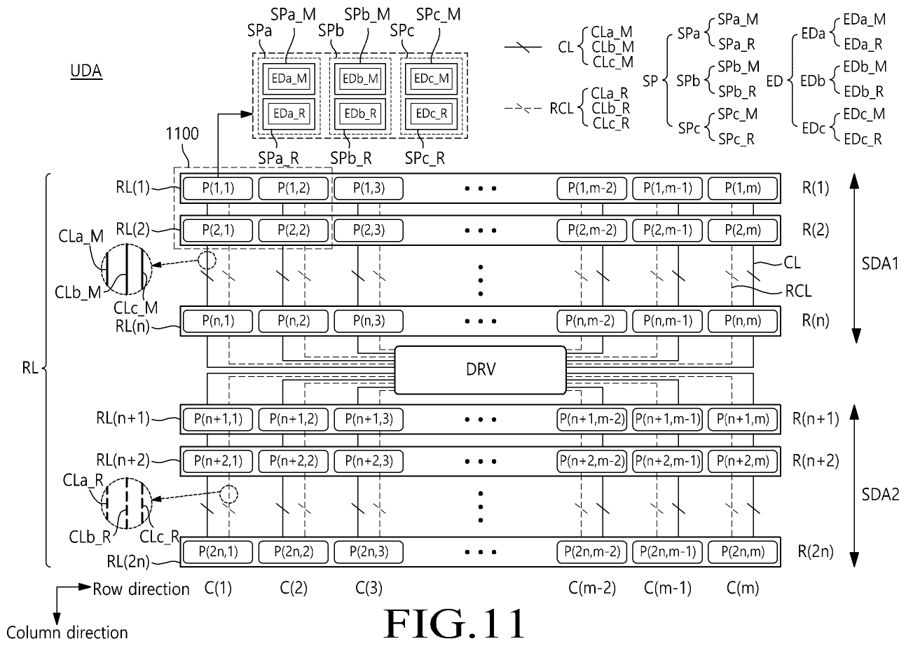

FIG. 11 illustrates a unit driving area UDA of a display panel 110 according to embodiments of the present disclosure. In the following description, FIG. 3 and FIG. 4 are also referred to, and the same contents described with reference to FIG. 3 and FIG. 4 can be omitted.

Referring to FIG. 11, the display panel 110 according to embodiments of the present disclosure can include a plurality of pixels P, a plurality of row lines RL, and a plurality of column lines CL.

According to the example of FIG. 11, the plurality of pixels P can include pixels P(1, 1), . . . , P(1, m), P(2, 1), . . . , P(2, m), . . . , P(2n, 1), . . . , P(2n, m) of (2n×m) pixels arranged in the unit driving area UDA. The plurality of row lines RL can include 2n row lines RL(1) to RL(2n) arranged in the unit driving area UDA.

The display panel 110 according to the embodiments of the present disclosure can include a redundancy structure.

According to the redundancy structure, each of the plurality of pixels P can include k main subpixels and k redundancy subpixels. Each of the k main subpixels can include a main light emitting device, and each of the k redundancy subpixels can include a redundancy light emitting device. In other words, each of the plurality of pixels P can include k main light emitting devices EDa_M, EDb_M and EDc_M and k redundancy light emitting devices EDa_R, EDb_R and EDc_R.

Each of the plurality of pixels P(1, 1), . . . , P(1, m), P(2, 1), . . . , P(2, m), . . . , P(2n, 1), . . . , P(2n, m) can include a first subpixel SPa, a second subpixel SPb, and a third subpixel SPc.

The first subpixel SPa can include a first main subpixel SPa_M and a first redundancy subpixel SPa_R. The first main subpixel SPa_M can include a first main light emitting device EDa_M, and the first redundancy subpixel SPa_R can include a first redundancy light emitting device EDa_R.

The first subpixel SPa can include a first light emitting device EDa that emits a first color light, and the first light emitting device EDa can include a first main light emitting device EDa_M and a first redundancy light emitting device EDa_R.

The second subpixel SPb can include a second main subpixel SPb_M and a second redundancy subpixel SPb_R. The second main subpixel SPb_M can include a second main light emitting device EDb_M, and the second redundancy subpixel SPb_R can include a second redundancy light emitting device EDb_R.

The second subpixel SPb can include a second light emitting device EDb that emits second color light, and the second light emitting device EDb can include a second main light emitting device EDb_M and a second redundancy light emitting device EDb_R.

The third subpixel SPc can include a third main subpixel SPc_M and a third redundancy subpixel SPc_R. The third main subpixel SPc_M can include a third main light emitting device EDc_M, and the third redundancy subpixel SPc_R can include a third redundancy light emitting device EDc_R.

The third subpixel SPc can include a third light emitting device EDc that emits a third color light, and the third light emitting device EDc can include a third main light emitting device EDc_M and a third redundancy light emitting device EDc_R.

The plurality of column lines CL can include a plurality of main column lines CLa_M, CLb_M and CLc_M and a plurality of redundancy column lines CLa_R, CLb_R and CLc_R.

In each of the plurality of columns (i.e., a plurality of pixel columns) included in each of the first sub-driving area SDA1 and the second sub-driving area SDA2, k main column lines CLa_M, CLb_M and CLc_M, and k redundancy column lines CLa_R, CLb_R and CLc_R can be arranged.

In each column (i.e., each pixel column), k main column lines CLa_M, CLb_M and CLc_M can be connected to the first electrodes Ecl of k main light emitting devices EDa_M, EDb_M and EDc_M.

In each column (i.e., each pixel column), k redundancy column lines CLa_R, CLb_R and CLc_R can be connected to the first electrodes Ecl of k redundancy light emitting devices EDa_R, EDb_R and EDc_R.

Hereinafter, in order to examine the planar structure of the display panel 110 according to the embodiments of the present disclosure in more detail, it will be described the planar structure of a portion 1100 of the planar view of FIG. 11 in more detail as an example.

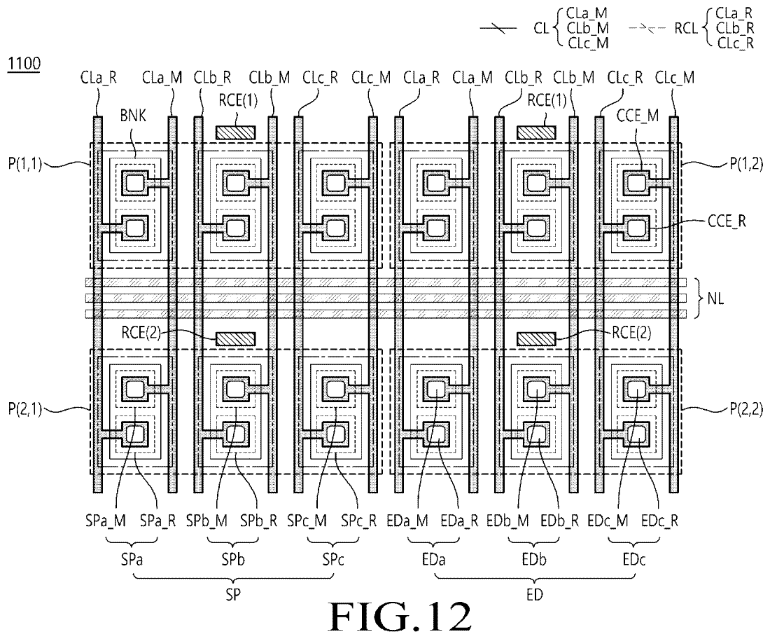

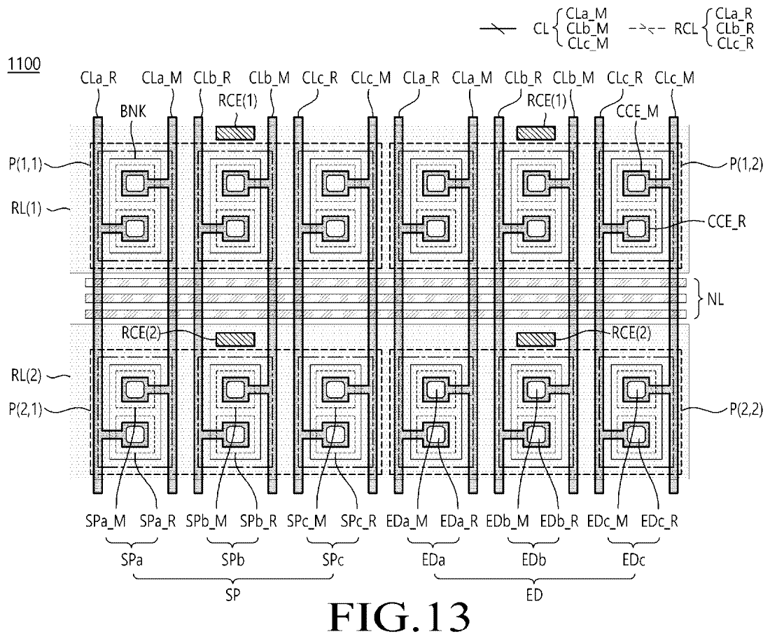

FIGS. 12 and 13 are plan views of a portion 1100 of a display panel 110 according to embodiments of the present disclosure. Particularly, FIGS. 12 and 13 are enlarged plan views of a portion 1100 of the plan view of FIG. 11, and are enlarged plan views of a two-row, two-column area 1100.

For example, FIG. 12 is a plan view that does not represent two row lines RL(1) and RL(2) arranged in a two-row, two-column area 1100, and FIG. 13 is a plan view that adds two row lines RL(1) and RL(2) arranged in a two-row, two-column area 1100 to the plan view of FIG. 12.

Referring to FIGS. 12 and 13, in the two-row, two-column area 1100, four pixels P(1,1), P(1,2), P(2,1), P(2,2) can be arranged in two rows and two columns. For example, in the two-row, two-column area 1100, two pixels P(1,1) and P(1,2) can be arranged in a first row (e.g., a first pixel row), and two pixels P(2,1) and P(2,2) can be arranged in a second row (e.g., a second pixel row). In addition, two pixels P(1,1) and P(2,1) can be arranged in a first column (e.g., a first pixel column), and two pixels P(1,2) and P(2,2) can be arranged in a second column (e.g., a second pixel column).

In the two-row, two-column area 1100, each of the four pixels P(1,1), P(1,2), P(2,1) and P(2,2) arranged in two rows and two columns can include k subpixels. Here, k is the number of subpixels included in one pixel.

It is exemplified a case where k is 3 is as an example. Accordingly, in the two-row, two-column area 1100, each of the four pixels P(1,1), P(1,2), P(2,1) and P(2,2)) arranged in two rows and two columns can include three subpixels SPa, SPb and SPc. In the following description, it can be explained assuming the case where k is 3.

The three subpixels can include a first subpixel SPa including a first light emitting device EDa that emits a first color light, a second subpixel SPb including a second light emitting device EDb that emits a second color light, and a third subpixel SPc including a third light emitting device EDc that emits a third color light.

If the display panel 110 according to the embodiments of the present disclosure has a redundancy structure, the subpixel redundancy structure is as follows.

The first subpixel SPa can include a first main subpixel SPa_M including a first main light emitting device EDa_M and a first redundancy subpixel SPa_R including a first redundancy light emitting device EDa_R, the second subpixel SPb can include a second main subpixel SPb_M including a second main light emitting device EDb_M and a second redundancy subpixel SPb_R including a second redundancy light emitting device EDb_R, and the third subpixel SPc can include a third main subpixel SPc_M including a third main light emitting device EDc_M and a third redundancy subpixel SPc_R including a third redundancy light emitting device EDc_R.

If the display panel 110 according to the embodiments of the present disclosure has a redundancy structure, the light emitting device redundancy structure is as follows.

The first light emitting device EDa can include a first main light emitting device EDa_M that emits a first color light and a first redundancy light emitting device EDa_R that emits a first color light, the second light emitting device EDb can include a second main light emitting device EDb_M that emits a second color light and a second redundancy light emitting device EDb_R that emits a second color light, and the third light emitting device EDb can include a third main light emitting device EDc_M that emits a third color light and a third redundancy light emitting device EDc_R that emits a third color light.

In the two-row, two-column area 1100, a first row line RL(1) and a second row line RL(2) can be arranged. The first row line RL(1) can be arranged in the first row (i.e., the first pixel row), and the second row line RL(2) can be arranged in the second row (i.e., the second pixel row).

The first row line RL(1) can correspond to two pixels P(1,1) and P(1,2) arranged in the first row (or the first pixel row), and can correspond to three subpixels SPa, SPb and SPc included in each of the two pixels P(1,1) and P(1,2) arranged in the first row (or the first pixel row).

In terms of the subpixel redundancy structure, the first row line RL(1) can be connected to the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the first row (or the first pixel row).

At least a portion of the first row line RL(1) can overlap with the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the first row (or the first pixel row).

From the perspective of the light emitting device redundancy structure, the first row line RL(1) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

At least a part of the first row line RL(1) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

The second row line RL(2) can correspond to two pixels P(2,1) and P(2,2) arranged in a second row (or the second pixel row), and can correspond to three subpixels SPa, SPb and SPc included in each of the two pixels P(2,1) and P(2,2) arranged in the second row (or the second pixel row).

In terms of the subpixel redundancy structure, the second row line RL(2) can be connected to the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the second row (or the second pixel row).

At least a portion of the second row line RL(2) can overlap with the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the second row (or the second pixel row).

In terms of the light emitting device redundancy structure, the second row line RL(2) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

At least a portion of the second row line RL(2) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

A plurality of column lines CL can be arranged in the two-row two-column area 1100. A plurality of column lines CL arranged in a two-row two-column area 1100 can include a plurality of first column lines CL connected to two pixels P(1,1) and P(2,1) arranged in a first column (or a first pixel column), and a plurality of second column lines CL connected to two pixels P(1,2) and P(2,2) arranged in a second column (or a second pixel column).

From the perspective of subpixel redundancy, a plurality of first column lines CL arranged in a first column (or first pixel column) can include a first main column line CLa_M that is commonly connected to a first main subpixel SPa_M included in each of two pixels P(1,1) and P(2,1) arranged in the first column (or first pixel column), and a first redundancy column line CLa_R that is commonly connected to a first redundancy subpixel SPa_R included in each of two pixels P(1,1) and P(2,1) arranged in the first column (or first pixel column).

The first main subpixel SPa_M included in each of the two pixels P(1,1) and P(2,1) arranged in the first column (or the first pixel column) can include a first main light emitting device EDa_M, and the first redundancy subpixel SPa_R included in each of the two pixels P(1,1) and P(2,1) arranged in the first column (or the first pixel column) can include a first redundancy light emitting device EDa_R.

The first main column line CLa_M arranged in the first column (or the first pixel column) can be commonly connected to the first electrodes Ecl of the two first main light emitting devices EDa_M arranged in the first column (or the first pixel column).

The first redundancy column line CLa_R arranged in the first column (or the first pixel column) can be commonly connected to the first electrodes Ecl of two first redundancy light emitting devices EDa_R arranged in the first column (or the first pixel column).

In addition, the plurality of first column lines CL arranged in the first column (or the first pixel column) can further include a second main column line CLb_M commonly connected to a second main subpixel SPb_M included in each of the two pixels P(1,1) and P(2,1) arranged in the first column (or the first pixel column), and a second redundancy column line CLb_R commonly connected to a second redundancy subpixel SPb_R included in each of the two pixels P(1,1) and P(2,1) arranged in the first column (or the first pixel column).

The second main subpixel SPb_M included in each of the two pixels P(1,1) and P(2,1) arranged in the first column (or the first pixel column) can include a second main light emitting device EDb_M, and the second redundancy subpixel SPb_R included in each of the two pixels P(1,1) and P(2,1) arranged in the first column (or the first pixel column) can include a second redundancy light emitting device EDb_R.

The second main column line CLb_M arranged in the first column (or the first pixel column) can be commonly connected to the first electrodes Ecl of the two second main light emitting devices EDb_M arranged in the first column (or the first pixel column).

The second redundancy column line CLb_R arranged in the first column (or the first pixel column) can be commonly connected to the first electrodes Ecl of the two second redundancy light emitting devices EDb_R arranged in the first column (or the first pixel column).

In addition, the plurality of first column lines CL arranged in the first column (or the first pixel column) can further include a third main column line CLc_M commonly connected to the third main subpixel SPc_M included in each of the two pixels P(1,1) and P(2,1) arranged in the first column (or the first pixel column), and a third redundancy column line CLc_R commonly connected to the third redundancy subpixel SPc_R included in each of the two pixels P(1,1) and P(2,1) arranged in the first column (or the first pixel column).

The third main subpixel SPc_M included in each of the two pixels P(1,1) and P(2,1) arranged in the first column (or the first pixel column) can include a third main light emitting device EDc_M, and the third redundancy subpixel SPc_R included in each of the two pixels P(1,1) and P(2,1) arranged in the first column (or the first pixel column) can include a third redundancy light emitting device EDc_R.

The third main column line CLc_M arranged in the first column (or the first pixel column) can be commonly connected to the first electrodes Ecl of the two third main light emitting devices EDc_M arranged in the first column (or the first pixel column).

The third redundancy column line CLc_R arranged in the first column (or the first pixel column) can be commonly connected to the first electrodes Ecl of two third redundancy light emitting devices EDc_R arranged in the first column (or the first pixel column).

From the perspective of subpixel redundancy, a plurality of second column lines CL arranged in a second column (or second pixel column) can include a first main column line CLa_M that is commonly connected to a first main subpixel SPa_M included in each of two pixels P(1,2) and P(2,2) arranged in the second column (or second pixel column), and a first redundancy column line CLa_R that is commonly connected to a first redundancy subpixel SPa_R included in each of two pixels P(1,2) and P(2,2) arranged in the second column (or second pixel column).

The first main subpixel SPa_M included in each of the two pixels P(1,2) and P(2,2) arranged in the second column (or the second pixel column) can include a first main light emitting device EDa_M, and the first redundancy subpixel SPa_R included in each of the two pixels P(1,2) and P(2,2) arranged in the second column (or the second pixel column) can include a first redundancy light emitting device EDa_R.

The first main column line CLa_M arranged in the second column (or the second pixel column) can be commonly connected to the first electrodes Ecl of the two first main light emitting devices EDa_M arranged in the second column (or the second pixel column).

The first redundancy column line CLa_R arranged in the second column (or the second pixel column) can be commonly connected to the first electrodes Ecl of the two first redundancy light emitting devices EDa_R arranged in the second column (or the second pixel column).

In addition, the plurality of second column lines CL arranged in the second column (or second pixel column) can further include a second main column line CLb_M commonly connected to a second main subpixel SPb_M included in each of two pixels P(1,2) and P(2,2) arranged in the second column (or second pixel column), and a second redundancy column line CLb_R commonly connected to a second redundancy subpixel SPb_R included in each of two pixels P(1,2) and P(2,2) arranged in the second column (or second pixel column).

The second main subpixel SPb_M included in each of the two pixels P(1,2) and P(2,2) arranged in the second column (or the second pixel column) can include a second main light emitting device EDb_M, and the second redundancy subpixel SPb_R included in each of the two pixels P(1,2) and P(2,2) arranged in the second column (or the second pixel column) can include a second redundancy light emitting device EDb_R.

The second main column line CLb_M arranged in the second column (or the second pixel column) can be commonly connected to the first electrodes Ecl of the two second main light emitting devices EDb_M arranged in the second column (or the second pixel column).

The second redundancy column line CLb_R arranged in the second column (or the second pixel column) can be commonly connected to the first electrodes Ecl of two second redundancy light emitting devices EDb_R arranged in the second column (or the second pixel column).

In addition, the plurality of first column lines CL arranged in the second column (or the second pixel column) can further include a third main column line CLc_M commonly connected to a third main subpixel SPc_M included in each of two pixels P(1,2) and P(2,2) arranged in the second column (or the second pixel column), and a third redundancy column line CLc_R commonly connected to a third redundancy subpixel SPc_R included in each of two pixels P(1,2) and P(2,2) arranged in the second column (or the second pixel column).

The third main subpixel SPc_M included in each of the two pixels P(1,2) and P(2,2) arranged in the second column (or the second pixel column) can include a third main light emitting device EDc_M, and the third redundancy subpixel SPc_R included in each of the two pixels P(1,2) and P(2,2) arranged in the second column (or the second pixel column) can include a third redundancy light emitting device EDc_R.

The third main column line CLc_M arranged in the second column (or the second pixel column) can be commonly connected to the first electrodes Ecl of the two third main light emitting devices EDc_M arranged in the second column (or the second pixel column).

The third redundancy column line CLc_R arranged in the second column (or the second pixel column) can be commonly connected to the first electrodes Ecl of two third redundancy light emitting devices EDc_R arranged in the second column (or the second pixel column).

In each of the first column (or the first pixel column) and the second column (or the second pixel column), each of the plurality of column lines CL can include at least one column connection electrode having a shape protruding above a bank BNK. For example, the at least one column connection electrode can be an electrode electrically connected to each of the plurality of column lines CL or a portion protruding from each of the plurality of column lines CL.

Each of the first main column line CLa_M, the second main column line CLb_M, and the third main column line CLc_M can include a main column connection electrode CCE_M protruding above the bank BNK and extending above the bank BNK.

The first main light emitting devices EDa_M, the second main light emitting devices EDb_M, and the third main light emitting devices EDc_M can be arranged on the main column connection electrodes CCE_M arranged to extend above the bank BNK.

Referring to FIGS. 12 and 13, in each of the first column (or first pixel column) and the second column (or second pixel column), each of the first redundancy column line CLa_R, the second redundancy column line CLb_R, and the third redundancy column line CLc_R can include a redundancy column connection electrode CCE_R that protrudes toward the bank BNK and extends above the bank BNK.

On the redundancy column connection electrodes CCE_R arranged to extend above the bank BNK, the first redundancy light emitting devices EDa_R, the second redundancy light emitting devices EDb_R, and the third redundancy light emitting devices EDc_R can be arranged.

The main column connection electrodes CCE_M and the redundancy column connection electrodes CCE_R arranged in the first column (or the first pixel column) can be disposed between the first main column line CLa_M and the first redundancy column line CLa_R.

The main column connection electrodes CCE_M and the redundancy column connection electrodes CCE_R arranged in the second column (or the second pixel column) can be disposed between the second main column line CLb_M and the second redundancy column line CLb_R.

The main column connection electrodes CCE_M and the redundancy column connection electrodes CCE_R arranged in the third column (or the third pixel column) can be disposed between the third main column line CLc_M and the third redundancy column line CLc_R.

The display panel 110 according to the embodiments of the present disclosure can further include at least one row connection electrode for electrically connecting each of the plurality of row lines RL to the driver DRV.

The display panel 110 according to the embodiments of the present disclosure can further include at least one first row connection electrode RCE(1) connected to a first row line RL(1) arranged in a first row (or a first pixel row), and at least one second row connection electrode RCE(2) connected to a second row line RL(2) arranged in a second row (or a second pixel row).

The first row line RL(1) can be vertically overlapped with at least one first row connection electrode RCE(1), and the second row line RL(2) can be vertically overlapped with at least one second row connection electrode RCE(2).

The first row line RL(1) can be electrically connected to the row driver R-DRV of the corresponding driver DRV through at least one first row connection electrode RCE(1). The second row line RL(2) can be electrically connected to the row driver R-DRV of the corresponding driver DRV through at least one second row connection electrode RCE(2).

According to embodiments of the present disclosure, a bank BNK can be arranged in each of a plurality of subpixels SP. The plurality of banks BNK can be structures on which a plurality of light emitting devices ED are mounted. When manufacturing a panel, in a transfer process for transferring a plurality of light emitting devices ED to a display device 100, a plurality of banks BNK can guide the positions of the plurality of light emitting devices ED. For example, when manufacturing a panel, a plurality of light emitting devices ED can be transferred onto a plurality of banks BNK in a transfer process of the plurality of light emitting devices ED. The plurality of banks BNK can be an organic insulating layer, a bank pattern, or a structure, but the embodiments of the present disclosure are not limited thereto.

The banks BNK of each of the plurality of subpixels SP can be arranged to be spaced apart from each other. The banks BNK of each of the plurality of subpixels SP can be configured to be separated from each other. Accordingly, the banks BNK of the first subpixel SPa, the second subpixel SPb, and the third subpixel SPc to which different types of light emitting devices ED are transferred can be easily identified.

The bank BNK of the first main subpixel SPa_M and the bank BNK of the first redundancy subpixel SPa_R can be connected to each other, or can be formed spaced apart from each other or separately. For example, considering the design of the transfer process requirements, the bank BNK of the first main subpixel SPa_M and the bank BNK of the first redundancy subpixel SPa_R, in which light emitting devices EDa_M, EDa_R of the same type (for example, types that emit the same color light) are arranged, can be connected to each other, or can be formed spaced apart from each other or separately. In addition, the bank BNK of the second main subpixel SPb_M and the bank BNK of the second redundancy subpixel SPb_R can be connected to each other, or can be formed spaced apart from each other or separately. The bank BNK of the third main subpixel SPc_M and the bank BNK of the third redundancy subpixel SPc_R can be connected to each other, or can be formed to be spaced apart from each other or separated from each other.

The bank BNK of the first main subpixel SPa_M and the first redundancy subpixel SPa_R, the bank BNK of the second main subpixel SPb_M and the second redundancy subpixel SPb_R, and the bank BNK of the third main subpixel SPc_M and the third redundancy subpixel SPc_R can be formed in various ways, and the embodiments of the present disclosure are not limited thereto.

For example, the plurality of banks BNK can be formed of an organic insulating material. The plurality of banks BNK can be formed of a single layer or multiple layers of an organic insulating material. For example, the plurality of banks BNK can be composed of a photo resist, a polyimide (PI), or an acrylic material, but the embodiments of the present disclosure are not limited thereto.

The plurality of row lines RL can be formed of a transparent conductive material, but the embodiments of the present disclosure are not limited thereto. The plurality of row lines RL can be composed of a transparent conductive material so that light emitted from the light emitting devices ED can be directed upward through the row lines RL. For example, the plurality of row lines RL can be composed of a transparent conductive material such as indium tin oxide (ITO), indium zinc oxide (IZO), indium gallium zinc oxide (IGZO), and the like, but the embodiments of the present disclosure are not limited thereto.

The plurality of column lines CL can be made of a conductive material. For example, the plurality of column lines CL can be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), but the embodiments of the present disclosure are not limited thereto. For another example, the plurality of column lines CL can have a multilayer structure of conductive materials. For example, the plurality of column lines CL can be made of a multilayer structure of titanium (Ti)/aluminum (Al)/titanium (Ti)/indium tin oxide (ITO), but the embodiments of the present disclosure are not limited thereto.

For example, if the light emitting device ED is a device manufactured through a semiconductor process, such as a micro LED, a plurality of light emitting devices ED can be formed on a wafer and the light emitting devices ED can be transferred to a substrate 210 of the display panel 110 to manufacture the display panel 110. In the process of transferring a plurality of light emitting devices ED having a microscopic size from the wafer to the substrate 210, various defects can occur. For example, a non-transfer defect can occur in which the light emitting device ED is not transferred in some subpixels SP, and a misalignment defect can occur in which the light emitting device ED is transferred out of its proper position due to an alignment error in other subpixels SP. In addition, the transfer process can proceed normally, but the transferred light emitting device ED itself can have a defect. Therefore, considering the defects (including non-transfer defects) that occur during the transfer process of the light emitting devices EDs, the main light emitting device and the redundancy light emitting device, which are light emitting devices of the same type (e.g., light emitting devices that emit light of the same color), can be transferred to one subpixel SP. A lighting test can be performed on the main light emitting device and the redundancy light emitting device of the same type, and it is possible to utilize only one of the main light emitting device and the redundancy light emitting device that is finally determined to be normal.

For example, the first main light emitting device EDa_M and the first redundancy light emitting device EDa_R can be transferred together to one first subpixel SPa, and the first main light emitting device EDa_M and the first redundancy light emitting device EDa_R can be inspected for defects. If, as a result of the inspection, both the first main light emitting device EDa_M and the first redundancy light emitting device EDa_R are determined to be normal, only the first main light emitting device EDa_M can be used, and the first redundancy light emitting device EDa_R can be not used. If, as a result of the inspection, only the first redundancy light emitting device EDa_R among the first main light emitting device EDa_M and the first redundancy light emitting device EDa_R is normal, the first main light emitting device EDa_M is not used, and only the first redundancy light emitting device EDa_R can be used. Accordingly, even if the same first main light emitting device EDa_M and the first redundancy light emitting device EDa_R are transferred to one first subpixel SPa, only one of the first main light emitting device EDa_M and the first redundancy light emitting device EDa_R can be used finally.

Accordingly, among the main light emitting device and the redundancy light emitting device arranged in one subpixel SP, the redundancy light emitting device can be a spare light emitting device transferred in preparation for a failure of the main light emitting device. In the event of a failure of the main light emitting device, the redundancy light emitting device can be used as a replacement. Therefore, by transferring the main light emitting device and the redundancy light emitting device together to one subpixel SP, it is possible to minimize the deterioration of display quality due to a defect in one of the main light emitting device and the redundancy light emitting device.

In the embodiments of the present disclosure, the first main subpixel SPa_M and the first redundancy subpixel SPa_R can also be referred to as a 1-1 subpixel and a 1-2 subpixel, respectively, the second main subpixel SPb_M and the second redundancy subpixel SPb_R can also be referred to as a 2-1 subpixel and a 2-2 subpixel, respectively, and the third main subpixel SPc_M and the third redundancy subpixel SPc_R can also be referred to as a 3-1 subpixel and a 3-2 subpixel, respectively.

In the embodiments of the present disclosure, the first main light emitting device EDa_M and the first redundancy light emitting device EDa_R can also be referred to as a 1-1 light emitting device and a 1-2 light emitting device, the second main light emitting device EDb_M and the second redundancy light emitting device EDb_R can also be referred to as a 2-1 light emitting device and a 2-2 light emitting device, and the third main light emitting device EDc_M and the third redundancy light emitting device EDc_R can also be referred to as a 3-1 light emitting device and a 3-2 light emitting device.

The display panel 110 according to the embodiments of the present disclosure can further include a plurality of communication lines NL. The plurality of communication lines NL can be arranged so as not to overlap with the metal layer in a vertical direction. For example, a plurality of communication lines NL can be arranged between a first row line RL(1) and a second row line RL(2).

For example, the plurality of communication lines NL can be wires for short-range communication such as NFC (Near Field Communication) and Bluetooth. The plurality of communication lines NL can serve as signal transmission wires and/or antennas, but the embodiments of the present disclosure are not limited thereto.

Referring to FIG. 13, the first row line RL(1) can be arranged above a plurality of light emitting devices arranged in the first row (or the first pixel row) and can be arranged in a bar shape overlapping with all of the plurality of light emitting devices arranged in the first row (or the first pixel row).

The second row line RL(2) can be arranged above the plurality of light emitting devices arranged in the second row (or the second pixel row), and can be arranged in a bar shape overlapping with all of the plurality of light emitting devices arranged in the second row (or the second pixel row).

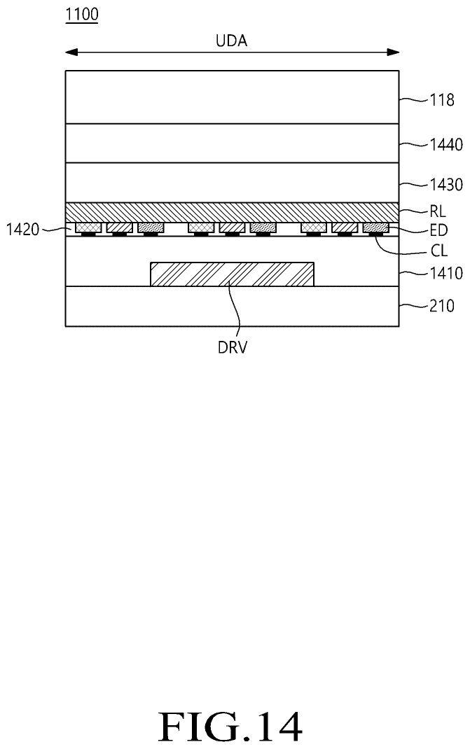

FIG. 14 is a cross-sectional view of a display panel 110 according to embodiments of the present disclosure. However, FIG. 14 is a cross-sectional view of a portion 1100 of a unit driving area UDA in which one driver DRV is arranged.

Referring to FIG. 14, a display panel 110 according to embodiments of the present disclosure can include a substrate 210, a driver DRV on the substrate 210, a layer stack 1410 on the driver DRV, a plurality of light emitting devices ED disposed on the layer stack 1410, an optical layer 1420 disposed on the layer stack 1410 and between the plurality of light emitting devices ED, an overcoat layer 1430 disposed on the plurality of light emitting devices ED and the optical layer 1420, an adhesive layer 1440 disposed on the overcoat layer 1430, and a cover member 118 disposed on the adhesive layer 1440.

A plurality of column lines CL can be arranged on a layer stack 1410. Each of the plurality of column lines CL can be arranged between the layer stack 1410 and a light emitting device ED. A plurality of row lines RL can be arranged on a plurality of light emitting devices ED and an optical layer 1420.

A display panel 110 according to embodiments of the present disclosure can include a substrate 210 including a display area DA, a plurality of light emitting devices ED arranged in the display area DA, a plurality of column lines CL electrically connected to first electrodes Ecl of each of the plurality of light emitting devices ED, a plurality of row lines RL electrically connected to second electrodes Erl of each of the plurality of light emitting devices ED, and a plurality of drivers DRV configured to drive the plurality of light emitting devices ED, the plurality of column lines CL, and the plurality of row lines RL.

A plurality of drivers DRV can be arranged in the display area DA, and can be positioned closer to the substrate 210 than the plurality of light emitting devices ED.

The layer stack 1410 can include a plurality of insulating layers. The plurality of insulating layers can include a plurality of organic layers. At least one of the plurality of organic layers can be arranged on a side of the driver DRV. For example, two or more organic layers can be arranged on a side of the driver DRV.

The layer stack 1410 can further include at least one metal layer connecting the driver DRV and the column line CL, and at least one metal layer connecting the driver DRV and the row line RL.

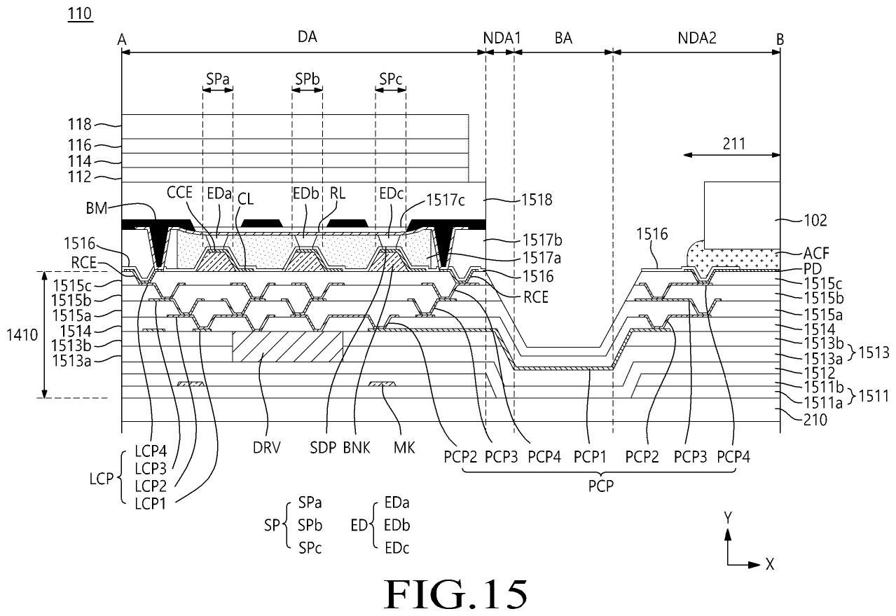

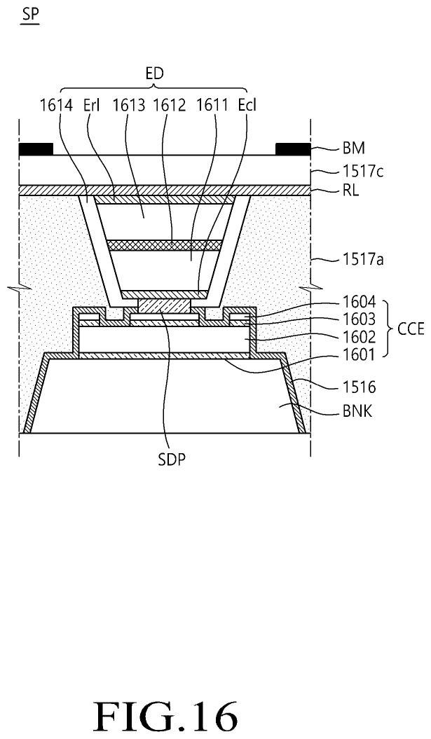

FIG. 15 is a detailed cross-sectional view of a display panel 110 according to embodiments of the present disclosure taken along the A-B cutting line of FIG. 10, and FIG. 16 is an enlarged cross-sectional view of a subpixel SP of a display panel 110 according to embodiments of the present disclosure. However, FIG. 15 is a cross-sectional view of a display area DA, a first non-display area NDA1, a bending area BA, and a second non-display area NDA2.

Meanwhile, for convenience of illustration, the A-B cutting line in FIG. 10 is illustrated as not overlapping with a signal line SL and a link line LL, but the A-B cutting line in FIG. 10 is intended to indicate the same position as the adjacent signal line SL and the link line LL.

Referring to FIG. 15, a buffer layer 1511 can be included on the substrate 210. The buffer layer 1511 can include a first buffer layer 1511a and a second buffer layer 1511b. The first buffer layer 1511a and the second buffer layer 1511b can be arranged in the display area DA, the first non-display area NDA1, and the second non-display area NDA2, and may not be arranged in the entirety or part of the bending area BA. However, the present disclosure is not limited thereto.

The first buffer layer 1511a and the second buffer layer 1511b can reduce the penetration of moisture or impurities through the substrate 210. The first buffer layer 1511a and the second buffer layer 1511b can be made of an inorganic insulating material. For example, the first buffer layer 1511a and the second buffer layer 1511b can be composed of a single layer or multiple layers of silicon oxide (SiOx) or silicon nitride (SiNx), but the embodiments of the present disclosure are not limited thereto.

For example, a portion of the first buffer layer 1511a and the second buffer layer 1511b on the bending area BA can be removed. The upper surface of the substrate 210 located on the bending area BA can be exposed by the area (e.g., opening) where the first buffer layer 1511a and the second buffer layer 1511b are removed.

By removing the first buffer layer 1511a and the second buffer layer 1511b from the bending area BA, it is possible to minimize an occurrence of cracks in the first buffer layer 1511a and the second buffer layer 1511b that can occur during bending.

A plurality of alignment keys MK can be arranged between the first buffer layer 1511a and the second buffer layer 1511b. The plurality of alignment keys MK can be configured to identify the position of the driver DRV during the manufacturing process of the display panel 110. For example, the plurality of alignment keys MK can be configured to align the position of the driver DRV transferred on the adhesive layer 1512. In another example, the plurality of alignment keys MK can be omitted.

An adhesive layer 1512 can be disposed on the second buffer layer 1511b. The adhesive layer 1512 can be disposed in the display area DA, the first non-display area NDA1, the bending area BA, and the second non-display area NDA2. For another example, at least a portion of the adhesive layer 1512 can be removed in the non-display area NDA including the bending area BA. For example, the adhesive layer 1512 can be made of any one of an adhesive polymer, an epoxy resin, a UV-curable resin, a polyimide series, an acrylate series, a urethane series, and a polydimethylsiloxane (PDMS), but the embodiments of the present disclosure are not limited thereto.

A driver DRV can be disposed on the adhesive layer 1512 in the display area DA. If the driver DRV is implemented as a driving chip (e.g., driver integrated circuit), the driving driver can be mounted on the adhesive layer 1512 by a transfer process, but the embodiments of the present disclosure are not limited thereto.

The display panel 110 can further include a side protection layer 1513 disposed on the side of the plurality of drivers DRV, and an upper protection layer 1514 disposed on the plurality of drivers DRV and the side protection layer 1513. For example, the side protection layer 1513 can include at least one of a first protection layer 1513a and a second protection layer 1513b disposed on the side of the plurality of drivers DRV, and in some cases, can further include at least one additional protection layer. The first protection layer 1513a and the second protection layer 1513b can be disposed on the adhesive layer 1512. The first protection layer 1513a and the second protection layer 1513b can be arranged to surround the side surface of the driver DRV, but the embodiments of the present disclosure are not limited thereto. For example, the second protection layer 1513b can be arranged to cover at least a portion of the upper surface of the driver DRV. For example, at least one of the first protection layer 1513a and the second protection layer 1513b arranged on the bending area BA can be omitted. For example, the first protection layer 1513a can be arranged entirely on the display area DA and the non-display area NDA, and the second protection layer 1513b can be partially arranged on the display area DA, the first non-display area NDA1, and the second non-display area NDA2. For example, at least a portion of the second protection layer 1513b can be removed in all or part of the bending area BA. However, the embodiments of the present disclosure are not limited thereto.

For example, the side protection layer 1513 including at least one of the first protection layer 1513a and the second protection layer 1513b can be composed of an organic insulating material (i.e., organic layer), but the embodiments of the present disclosure are not limited thereto. For example, the first protection layer 1513a and the second protection layer 1513b can be composed of a photo resist, a polyimide (PI), or a photo acryl-based material, but the embodiments of the present disclosure are not limited thereto. For example, the first protection layer 1513a and the second protection layer 1513b can be an overcoating layer or an insulating layer, but the embodiments of the present disclosure are not limited thereto.

According to embodiments of the present disclosure, in the display area DA, a plurality of line connection patterns LCP can be arranged on the second protection layer 1513b. The plurality of line connection patterns LCP can be wiring for electrically connecting the driver DRV to other components. For example, the driver DRV can be electrically connected to a plurality of column lines CL, a plurality of row lines RL, and a plurality of row connection electrodes RCE through the plurality of line connection patterns LCP.

For example, the plurality of line connection patterns LCP can include a first line connection pattern LCP1, a second line connection pattern LCP2, a third line connection pattern LCP3, and a fourth line connection pattern LCP4, but the embodiments of the present disclosure are not limited thereto. For example, the first line connection pattern LCP1, the second line connection pattern LCP2, the third line connection pattern LCP3, and the fourth line connection pattern LCP4 can be arranged in different metal layers.

For example, a plurality of first line connection patterns LCP1 can be arranged on the second protection layer 1513b. The plurality of first line connection patterns LCP1 can be electrically connected to the driver DRV. The plurality of first line connection patterns LCP1 can transmit the voltage output from the driver DRV to the column line CL or the row line RL.

The display panel 110 can further include a side protection layer 1513 including at least one of the first protection layer 1513a and the second protection layer 1513b, and an upper protection layer 1514 arranged on the plurality of drivers DRV. For example, the upper protection layer 1514 can include a third protection layer 1514, and in some cases, can further include at least one additional protection layer. The third protection layer 1514 can be disposed on the second protection layer 1513b and the plurality of first line connection patterns LCP1. The third protection layer 1514 can be disposed entirely in the display area DA and the non-display area NDA. In the bending area BA, the third protection layer 1514 can cover or enclose the side surface of the second protection layer 1513b and the upper surface of the first protection layer 1513a.

For example, the third protection layer 1514 can be composed of an organic insulating material. For example, the third protection layer 1514 can be composed of a photo resist, a polyimide (PI), or a photo acryl-based material, but the embodiments of the present disclosure are not limited thereto. For example, the first protection layer 1513a, the second protection layer 1513b, and the third protection layer 1514 can be composed of the same insulating material, or at least one of the first protection layer 1513a, the second protection layer 1513, and the third protection layer 1514 can be composed of a different insulating material from the rest. However, the embodiments of the present disclosure are not limited thereto.

A plurality of second line connection patterns LCP2 can be arranged on the third protection layer 1514. The plurality of second line connection patterns LCP2 can be electrically connected or directly connected to the driver DRV. For example, some of the second line connection patterns LCP2 can be directly or indirectly connected to the driver DRV through contact holes of the third protection layer 1514. Other parts of the second line connection patterns LCP2 can be electrically connected to the first line connection pattern LCP1 through contact holes of the third protection layer 1514. However, the embodiments of the present disclosure are not limited thereto. The voltage output from the driver DRV can be transmitted to the column line CL or the row line RL through the plurality of second line connection patterns LCP2 and other connection patterns.

A first insulating layer 1515a can be disposed on the plurality of second line connection patterns LCP2. The first insulating layer 1515a can be disposed entirely over the display area DA and the non-display area NDA, but the embodiments of the present disclosure are not limited thereto. The first insulating layer 1515a can be composed of an organic insulating material, but the embodiments of the present disclosure are not limited thereto. For example, the first insulating layer 1515a can be composed of a photo resist, a polyimide (PI), or a photo acryl-based material, but the embodiments of the present disclosure are not limited thereto.

A plurality of third line connection patterns LCP3 can be disposed on the first insulating layer 1515a. The plurality of third line connection patterns LCP3 can be electrically connected to the plurality of second line connection patterns LCP2. For example, the third line connection pattern LCP3 can be electrically connected to the second line connection pattern LCP2 through a contact hole of the first insulating layer 1515a.

A second insulating layer 1515b can be disposed on a plurality of third line connection patterns LCP3. The second insulating layer 1515b can be disposed in the display area DA, the first non-display area NDA1, and the second non-display area NDA2, and may not be disposed in the entirety or part of the bending area BA, but the embodiments of the present disclosure are not limited thereto. For example, the second insulating layer 1515b can be removed from the entirety or part of the bending area BA. The second insulating layer 1515b can be composed of an organic insulating material, but the embodiments of the present disclosure are not limited thereto. For example, the second insulating layer 1515b can be composed of a photo resist, a polyimide (PI), or a photo acryl-based material, but the embodiments of the present disclosure are not limited thereto.

A plurality of fourth line connection patterns LCP4 can be arranged on the second insulating layer 1515b. The plurality of fourth line connection patterns LCP4 can be electrically connected to a plurality of third line connection patterns LCP3. For example, the fourth line connection patterns LCP4 can be electrically connected to the third line connection patterns LCP3 through a contact hole of the second insulating layer 1515b.

According to the embodiments of the present disclosure, in the non-display area NDA, a plurality of pad connection patterns PCP can be arranged on the second protection layer 1513b. A plurality of pad connection patterns PCPs can be wiring for transmitting a signal transmitted from a flexible printed circuit 102 to a pad section 211 to a driver DRV of a display area DA. For example, a plurality of pad connection patterns PCP can be electrically connected to a plurality of pads PDs and can receive signals from the flexible printed circuit 102 through the plurality of pads PDs. The flexible printed circuit 102 can be connected to a printed circuit board 104 (see FIGS. 1 and 2).

For example, a plurality of pad connection patterns PCP can extend from the pad section 211 toward the display area DA and transmit signals to the wiring of the display area DA. In this case, a plurality of pad connection patterns PCP can function as link wiring LL (see FIG. 10). The plurality of pad connection patterns PCP can include a first pad connection pattern PCP1, a second pad connection pattern PCP2, a third pad connection pattern PCP3, and a fourth pad connection pattern PCP4.

The plurality of first pad connection patterns PCP1 can be arranged on the second protection layer 1513b. Each of the plurality of first pad connection patterns PCP1 can be arranged across the second non-display area NDA2, the bending area BA, and the first non-display area NDA1. Each of the plurality of first pad connection patterns PCP1 can include a first portion arranged in the bending area BA, a second portion extending from the first portion to the first non-display area NDA1, and a third portion extending from the first portion to the second non-display area NDA2. Each of the plurality of first pad connection patterns PCP1 can extend from the first non-display area NDA1 to a portion of the display area DA. The plurality of first pad connection patterns PCP1 can transmit a signal transmitted from the flexible printed circuit 102 to the pad portion 211 to the driver DRV of the display area DA.

Each of the plurality of first pad connection patterns PCP1 can be electrically connected to the pad PD of the pad section 211 through connection patterns arranged in the second non-display area NDA2. Here, the connection patterns electrically connecting each of the plurality of first pad connection patterns PCP1 to the pad PD can include at least one of the second pad connection pattern PCP2, the third pad connection pattern PCP3, and the fourth pad connection pattern PCP4 arranged in the second non-display area NDA2.

Each of the plurality of first pad connection patterns PCP1 can be electrically connected to the driver DRV through connection patterns arranged in the display area DA. Here, the connection patterns electrically connecting each of the plurality of first pad connection patterns PCP1 to the driver DRV can include at least one of the second pad connection pattern PCP2, the third pad connection pattern PCP3, and the fourth pad connection pattern PCP4 arranged in the display area DA.

The plurality of second pad connection patterns PCP2 can be arranged on the third protection layer 1514. The plurality of second pad connection patterns PCP2 can be arranged in the second non-display area NDA2. The second pad connection pattern PCP2 can be electrically connected to the first pad connection pattern PCP1 through a contact hole of the third protection layer 1514. Therefore, the signal supplied from the flexible printed circuit 102 can be transmitted to the first pad connection pattern PCP1 through the second pad connection pattern PCP2.

The third pad connection pattern PCP3 can be arranged on the first insulating layer 1515a. The third pad connection pattern PCP3 can be arranged in the second non-display area NDA2. The third pad connection pattern PCP3 can be electrically connected to the second pad connection pattern PCP2 through a contact hole of the first insulating layer 1515a. Therefore, the signal supplied from the flexible printed circuit 102 can be transmitted to the second pad connection pattern PCP2 through the third pad connection pattern PCP3, and the signal transmitted to the second pad connection pattern PCP2 can be transmitted again to the first pad connection pattern PCP1.

The fourth pad connection pattern PCP4 can be arranged on the second insulating layer 1515b. The fourth pad connection pattern PCP4 can be arranged in the second non-display area NDA2. The fourth pad connection pattern PCP4 can be electrically connected to the third pad connection pattern PCP3 through a contact hole of the second insulating layer 1515b. The pad PD of the pad section 211 can be electrically connected to the fourth pad connection pattern PCP4 through a contact hole of the third insulating layer 1515c.

A signal supplied from a flexible printed circuit 102 is input to a pad PD of a pad section 211, and a signal input to the pad PD is transmitted to a third pad connection pattern PCP3 through a fourth pad connection pattern PCP4, and a signal transmitted to the third pad connection pattern PCP3 can be transmitted again to a first pad connection pattern PCP1 through a second pad connection pattern PCP2. A signal transmitted to the first pad connection pattern PCP1 can be transmitted to a driver DRV through connection patterns arranged in a display area DA.

A plurality of line connection patterns LCP and a plurality of pad connection patterns PCP can be arranged in various metal layers. The plurality of line connection patterns LCP and the plurality of pad connection patterns PCP can be formed of any one of a conductive material having excellent ductility and various conductive materials used in a display area DA.

For example, a metal pattern such as a first pad connection pattern PCP1 at least partially disposed in the bending area BA can be composed of a conductive material having excellent ductility, such as gold (Au), silver (Ag), or aluminum (Al), but the embodiments of the present disclosure are not limited thereto. For another example, the plurality of line connection patterns LCP and the plurality of pad connection patterns PCP can be composed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto.

A third insulating layer 1515c can be disposed on the plurality of line connection patterns LCP and the plurality of pad connection patterns PCP. The third insulating layer 1515c is disposed in the display area DA, the first non-display area NDA1, and the second non-display area NDA2, and can be disposed in all or part of the bending area BA, but the embodiments of the present disclosure are not limited thereto. In the bending area BA, a part of the third insulating layer 1515c can be removed. The third insulating layer 1515c can be composed of an organic insulating material, but the embodiments of the present disclosure are not limited thereto. For example, the third insulating layer 1515c can be composed of a photo resist, a polyimide (PI), or a photo acryl-based material, but the embodiments of the present disclosure are not limited thereto.

A plurality of banks BNK can be disposed on the third insulating layer 1515c in the display area DA. The plurality of banks BNKs can be arranged to overlap with at least a portion of each of the plurality of subpixels SPa, SPb and SPc. For example, the first subpixel SPa can include a first light emitting device EDa that emits a first color light, the second subpixel SPb can include a second light emitting device EDb that emits a second color light, and the third subpixel SPc can include a third light emitting device EDc that emits a third color light.

As an example, one light emitting device ED can be arranged on top of each of the plurality of banks BNKs. As another example, two or more light emitting devices ED can be arranged on top of each of the plurality of banks BNK. The two or more light emitting devices EDs arranged on top of each of the plurality of banks BNK can be light emitting devices of the same type. For example, the light emitting devices of the same type can be light emitting devices that emit the same color light. For example, the two or more light emitting devices ED arranged on top of each of the plurality of banks BNK can include a main light emitting device and a redundancy light emitting device.

In the display area DA, a plurality of row connection electrodes RCE can be arranged on the third insulating layer 1515c. The plurality of row connection electrodes RCE can transfer a low-potential voltage VSS output from the driver DRV to the row line RL.

In the display area DA, a plurality of column lines CL can be arranged on the third insulating layer 1515c. The plurality of column lines CL can be arranged in an area between the plurality of banks BNK. For example, the plurality of column lines CL can be arranged adjacent to one of the plurality of banks BNK.

Each of the plurality of column lines CL can include a wiring portion and a column connection electrode CCE protruding from the wiring portion. The wiring portion and the column connection electrode CCE included in each of the plurality of column lines CL can be formed integrally or can be different metals that are electrically connected.

For example, each of the plurality of column lines CL can include a column connection electrode CCE that is a portion protruding above an adjacent bank BNK among the plurality of banks BNK. The column connection electrode CCE of each of the plurality of column lines CL can be arranged to extend along the side and upper surface of the bank BNK. The column connection electrode CCE can be an electrode electrically connected to each of the plurality of column lines CL or can be a portion protruding from each of the plurality of column lines CL.

Referring to FIG. 16, the column connection electrode CCE of the column line CL can be composed of one conductive layer or multiple conductive layers. For example, a column connection electrode CCE electrically connected to a column line CL or protruding from the column line CL can include a first conductive layer 1601, a second conductive layer 1602, a third conductive layer 1603, and a fourth conductive layer 1604, but the embodiments of the present disclosure are not limited thereto.

The first conductive layer 1601 can be disposed on a bank BNK. The second conductive layer 1602 can be disposed on the first conductive layer 1601. The third conductive layer 1603 can be disposed on the second conductive layer 1602, and the fourth conductive layer 1604 can be disposed on the third conductive layer 1603. For example, each of the first conductive layer 1601, the second conductive layer 1602, the third conductive layer 1603, and the fourth conductive layer 1604 can be composed of titanium (Ti), molybdenum (Mo), aluminum (Al), or titanium (Ti) and indium tin oxide (ITO), but the embodiments of the present disclosure are not limited thereto.

According to the embodiments of the present disclosure, among the plurality of conductive layers constituting the column connection electrode CCE, some conductive layers having good reflection efficiency can be configured as an alignment key and/or a reflector for aligning the light emitting devices ED. For example, among the plurality of conductive layers constituting the column connection electrode CCE, the second conductive layer 1602 can include a reflective material. For example, the second conductive layer 1602 can include aluminum (Al), but the embodiments of the present disclosure are not limited thereto. Accordingly, the second conductive layer 1602 can be configured as a reflector. In addition, due to the high reflection efficiency of the second conductive layer 1602, it can be easily identified in the manufacturing process, and thus the position or transfer position of the light emitting device ED can be aligned based on the second conductive layer 1602.

For example, in order to configure the second conductive layer 1602 as a reflector, the third conductive layer 1603 and the fourth conductive layer 1604 disposed on the second conductive layer 1602 can be partially removed or etched. For example, a portion of the third conductive layer 1603 and the fourth conductive layer 1604 disposed on the bank BNK can be removed or etched to expose the upper surface of the second conductive layer 1602. For example, the openings of the third conductive layer 1603 and the fourth conductive layer 1604 can overlap with a portion of the upper surface of the second conductive layer 1602. For example, in the third conductive layer 1603 and the fourth conductive layer 1604, the central portion and the edge portion where a solder pattern SDP is arranged can remain, and the remaining portions excluding this portion (e.g., the central portion, the edge portion) can be removed. For example, the edge portion of each of the third conductive layer 1603 made of titanium (Ti) and the fourth conductive layer 1604 made of indium tin oxide (ITO) may not be etched. Accordingly, it is possible to prevent other conductive layers of the column connection electrode CCE of the column line CL from being corroded by the TMAH (Tetra Methyl Ammonium Hydroxide) solution used in the mask process of the column connection electrode CCE.

According to the embodiments of the present disclosure, the first conductive layer 1601 and the third conductive layer 1603 can include titanium (Ti) or molybdenum (Mo). The second conductive layer 1602 can include aluminum (Al). The fourth conductive layer 1604 can include a transparent conductive oxide layer such as indium tin oxide (ITO) or indium zinc oxide (IZO) that has good adhesion to the solder pattern SDP and corrosion resistance and acid resistance. However, the embodiments of the present disclosure are not limited thereto.

The first conductive layer 1601, the second conductive layer 1602, the third conductive layer 1603, and the fourth conductive layer 1604 can be sequentially deposited and then patterned by performing a photolithography process and an etching process, but the embodiments of the present disclosure are not limited thereto.

According to embodiments of the present disclosure, two or more of the column connection electrode CCE, the column line CL, the row connection electrode RCE, and the pad PD can be arranged on the same layer. The column connection electrode CCE, the column line CL, the row connection electrode RCE, and the pad PD can be composed of a single layer or multiple layers of a conductive material, but the embodiments of the present disclosure are not limited thereto. For example, two or more of the column connection electrode CCE, the column line CL, the row connection electrode RCE, and the pad PD can be composed of a multiple layer of indium tin oxide (ITO)/titanium (Ti)/aluminum (Al)/titanium (Ti), but the embodiments of the present disclosure are not limited thereto.

According to embodiments of the present disclosure, a solder pattern SDP can be arranged on the column connection electrode CCE in each of a plurality of subpixels. The solder pattern SDP can bond the light emitting device ED to the column connection electrode CCE. The column connection electrode CCE and the light emitting device ED can be electrically connected through eutectic bonding using the solder pattern SDP, but the embodiments of the present disclosure are not limited thereto. For example, if the solder pattern SDP is composed of indium (In) and the first electrode Ecl of the light emitting device ED is composed of gold (Au), the solder pattern SDP and the first electrode Ecl of the light emitting device ED can be bonded by applying heat and pressure in a transfer process of the light emitting device ED. Through eutectic bonding, the light emitting device ED can be bonded to the solder pattern SDP and the column connection electrode CCE without a separate adhesive. For example, the solder pattern SDP can be composed of indium (In), tin (Sn), or an alloy thereof, but the embodiments of the present disclosure are not limited thereto. For example, the solder pattern SDP can be a bonding pad, but the embodiments of the present disclosure are not limited thereto.

According to the embodiments of the present disclosure, the passivation layer 1516 can be disposed on a plurality of column lines CL, a plurality of column connection electrodes CCE, a plurality of row connection electrodes RCE, and a third insulating layer 1515c.

For example, the passivation layer 1516 can be disposed on a display area DA, a first non-display area NDA1, and a second non-display area NDA2. In the entirety or a portion of the bending area BA, at least a portion of the passivation layer 1516 covering the plurality of pads PD can be removed. A portion of the passivation layer 1516 covering the plurality of pads PD in the second non-display area NDA2 can be removed. In addition, as illustrated in FIG. 16, the passivation layer 1516 can be removed from the area where the solder pattern SDP is arranged.

Since the passivation layer 1516 is arranged to cover the remaining area except for the bending area BA, the plurality of pads PD, and the area where the solder pattern SDP is arranged, the penetration of moisture or impurities into the light emitting device ED can be reduced. For example, the passivation layer 1516 can be composed of a single layer or multiple layers of silicon oxide (SiOx) or silicon nitride (SiNx), but the embodiments of the present disclosure are not limited thereto. For example, the passivation layer 1516 can be a protection layer or an insulating layer, but the embodiments of the present disclosure are not limited thereto. For example, as illustrated in FIG. 16, the passivation layer 1516 can include a hole through which the solder pattern SDP is exposed. For example, the hole of the passivation layer 1516 can overlap with the solder pattern SDP.

Referring to FIG. 16, a light emitting device ED can be arranged on the solder pattern SDP in each of a plurality of subpixels SP. The light emitting device ED can be formed on a silicon wafer by a method such as Metal Organic Chemical Vapor Deposition (MOCVD), Chemical Vapor Deposition (CVD), Plasma-Enhanced Chemical Vapor Deposition (PDCVD), Molecular Beam Epitaxy (MBE), Hydride Vapor Phase Epitaxy (HVPD), or Sputtering, but the embodiments of the present disclosure are not limited thereto.

The light emitting device ED can include a first electrode Ecl, a first semiconductor layer 1611, an active layer 1612, a second semiconductor layer 1613, a second electrode Erl, and an encapsulation film 1614, but the embodiments of the present disclosure are not limited thereto. For example, the encapsulation film 1614 may not be included in the light emitting device ED.

The first semiconductor layer 1611 can be disposed on the solder pattern SDP. The second semiconductor layer 1613 can be disposed on the first semiconductor layer 1611.

For example, one of the first semiconductor layer 1611 and the second semiconductor layer 1613 can be implemented as a compound semiconductor of group III-V, group II-VI, and can be doped with an impurity (or dopant). For example, one of the first semiconductor layer 1611 and the second semiconductor layer 1613 can be a semiconductor layer doped with an n-type impurity, and the other can be a semiconductor layer doped with a p-type impurity, but the embodiments of the present disclosure are not limited thereto. For example, at least one of the first semiconductor layer 1611 and the second semiconductor layer 1613 can be a layer doped with an n-type or p-type impurity in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity can be silicon (Si), germanium (Ge), selenium (Se), carbon (C), tellurium (Te), or tin (Sn), but the embodiments of the present disclosure are not limited thereto. For example, the p-type impurity can be magnesium (Mg), zinc (Zn), calcium (Ca), strontium (Sr), barium (Ba), or beryllium (Be), but the embodiments of the present disclosure are not limited thereto.

For example, the first semiconductor layer 1611 and the second semiconductor layer 1613 can be a nitride semiconductor including an n-type impurity and a nitride semiconductor including a p-type impurity, respectively, but the embodiments of the present disclosure are not limited thereto. For example, the first semiconductor layer 1611 can be a nitride semiconductor containing a p-type impurity, and the second semiconductor layer 1613 can be a nitride semiconductor containing an n-type impurity, but the embodiments of the present disclosure are not limited thereto.

The active layer 1612 can be arranged between the first semiconductor layer 1611 and the second semiconductor layer 1613. The active layer 1612 can receive holes and electrons from the first semiconductor layer 1611 and the second semiconductor layer 1613 to emit light. For example, the active layer 1612 can be configured as one of a single well structure, a multi-well structure, a single quantum well structure, a multi-quantum well (MQW) structure, a quantum dot structure, and a quantum wire structure, but the embodiments of the present disclosure are not limited thereto. For example, the active layer 1612 can be configured as indium gallium nitride (InGaN) or gallium nitride (GaN), but the embodiments of the present disclosure are not limited thereto.

For another example, the active layer 1612 can include a multi-quantum well (MQW) structure having a well layer and a barrier layer having a higher band gap than the well layer. For example, the active layer 1612 can be formed of InGaN as a well layer and an AlGaN layer as a barrier layer, but the embodiments of the present disclosure are not limited thereto.

The first electrode Ecl of the light emitting device ED can be arranged between the first semiconductor layer 1611 and the solder pattern SDP. For example, the first electrode Ecl of the light emitting device ED can electrically connect the first semiconductor layer 1611 and the column connection electrode CCE. The column line voltage (e.g., the anode voltage) output from the driver DRV can be applied to the first semiconductor layer 1611 through the column line CL, the column connection electrode CCE, and the first electrode Ecl. For example, the first electrode Ecl can be composed of a conductive material capable of eutectic bonding with the solder pattern SDP, but the embodiments of the present disclosure are not limited thereto. For example, the first electrode Ecl of the light emitting device ED can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present disclosure are not limited thereto.

The second electrode Erl of the light emitting device ED can be disposed on the second semiconductor layer 1613. For example, the second electrode Erl of the light emitting device ED can electrically connect the second semiconductor layer 1613 and the row line RL. A row line voltage (e.g., referred to as a low-potential voltage VSS as a cathode voltage) output from the driver DRV can be applied to the second semiconductor layer 1613 through the row connection electrode RCE, the row line RL, and the second electrode Erl. The second electrode Erl of the light emitting device ED can be made of a transparent conductive material so that light emitted from the light emitting device ED can be directed to the upper portion of the light emitting device ED, but the embodiments of the present disclosure are not limited thereto. For example, the second electrode Erl can be made of a material such as indium tin oxide (ITO), indium zinc oxide (IZO), or indium gallium zinc oxide (IGZO), but the embodiments of the present disclosure are not limited thereto.

The encapsulation film 1614 can be disposed on at least a portion of the first semiconductor layer 1611, the active layer 1612, the second semiconductor layer 1613, the first electrode Ecl, and the second electrode Erl. For example, the encapsulation film 1614 can surround at least a portion of the first semiconductor layer 1611, the active layer 1612, the second semiconductor layer 1613, the first electrode Ecl, and the second electrode Erl.

For example, the encapsulation film 1614 can protect the first semiconductor layer 1611, the active layer 1612, and the second semiconductor layer 1613. For example, the encapsulation film 1614 can be disposed on a side surface of the first semiconductor layer 1611, a side surface of the active layer 1612, and a side surface of the second semiconductor layer 1613.

For example, the encapsulation film 1614 can be disposed on at least a portion of the first electrode Ecl and the second electrode Erl of the light emitting device ED. For example, the encapsulation film 1614 can be disposed on an edge portion (or one side) of the first electrode Ecl of the light emitting device ED and an edge portion (or one side) of the second electrode Erl of the light emitting device ED. At least a portion of the first electrode Ecl can be exposed from the encapsulation film 1614 so that the first electrode Ecl can be connected to the solder pattern SDP. For example, at least a portion of the second electrode Erl can be exposed from the encapsulation film 1614 so that the second electrode Erl can be connected to the row line RL. For example, the encapsulation film 1614 can be made of an insulating material such as silicon nitride (SiNx) or silicon oxide (SiOx), but the embodiments of the present disclosure are not limited thereto.

For another example, the encapsulation film 1614 can have a structure in which a reflective material is dispersed in a resin layer, but the embodiments of the present disclosure are not limited thereto. For example, the encapsulation film 1614 can be manufactured as a reflector of various structures, but the embodiments of the present disclosure are not limited thereto. Light emitted from the active layer 1612 can be reflected upward by the encapsulation film 1614, thereby improving light extraction efficiency. For example, the encapsulation film 1614 can be a reflective layer, but the embodiments of the present disclosure are not limited thereto.

According to the embodiments of the present disclosure, the light emitting device ED is described as having a vertical structure, but the embodiments of the present disclosure are not limited thereto. For example, the light emitting device ED can have a lateral structure or a flip chip structure.

The structure of the light emitting device ED illustrated in FIG. 16 can be substantially equally applied to all of the first light emitting device EDa, the second light emitting device EDb, and the third light emitting device EDc. According to embodiments of the present disclosure, a first optical layer 1517a can be arranged to surround a plurality of light emitting devices ED in the display area DA. For example, the first optical layer 1517a can be arranged to cover a plurality of light emitting devices ED and the bank BNK in the area of a plurality of subpixels SP. For example, the first optical layer 1517a can cover a bank BNK, a portion of the passivation layer 1516, and a region between the plurality of light emitting devices ED. The first optical layer 1517a can be arranged or covered between a plurality of light emitting devices ED included in one pixel and between a plurality of banks BNK. For example, the first optical layer 1517a can be arranged to extend in the first direction (X) and be spaced apart from each other in the second direction (Y). For example, the first optical layer 1517a can be arranged to surround the side of the light emitting devices ED and the banks BNK between the passivation layer 1516 and the row line RL, but the embodiments of the present disclosure are not limited thereto. For example, the first optical layer 1517a can be a diffusion layer or a sidewall diffusion layer, but the embodiments of the present disclosure are not limited thereto.

The first optical layer 1517a can include an organic insulating material having fine particles dispersed therein, but the embodiments of the present disclosure are not limited thereto. For example, the first optical layer 1517a can be composed of siloxane having fine metal particles, such as titanium dioxide (TiO₂) particles, dispersed therein, but the embodiments of the present disclosure are not limited thereto. Light from a plurality of light emitting devices ED can be scattered by the fine particles dispersed in the first optical layer 1517a and emitted to the outside of the display device 100. Accordingly, the first optical layer 1517a can improve the extraction efficiency of light emitted from the plurality of light emitting devices ED.

For example, the first optical layer 1517a can be arranged on each of a plurality of pixels, or can be arranged together on some pixels arranged in the same row, but the embodiments of the present disclosure are not limited thereto. For example, the first optical layer 1517a can be arranged on each of a plurality of pixels, or the plurality of pixels can share one first optical layer 1517a. For another example, each of the plurality of subpixels can separately include a first optical layer 1517a, but the embodiments of the present disclosure are not limited thereto.

According to the embodiments of the present disclosure, in the display area DA, a second optical layer 1517b can be arranged on the passivation layer 1516. For example, the second optical layer 1517b can be arranged to surround the first optical layer 1517a. For example, the second optical layer 1517b can be in contact with a side surface of the first optical layer 1517a. For example, the second optical layer 1517b can be arranged in an area between the plurality of pixels. However, the embodiments of the present disclosure are not limited thereto. For example, the second optical layer 1517b can be a diffusion layer, a diffusion layer window, or a window diffusion layer, but the embodiments of the present disclosure are not limited thereto.

The second optical layer 1517b can be composed of an organic insulating material, but the embodiments of the present disclosure are not limited thereto. The second optical layer 1517b can be composed of the same material as the first optical layer 1517a, but the embodiments of the present disclosure are not limited thereto. For example, the first optical layer 1517a can include fine particles, and the second optical layer 1517b may not include fine particles. For example, the second optical layer 1517b can be composed of siloxane, but the embodiments of the present disclosure are not limited thereto.

For example, the thickness of the first optical layer 1517a can be smaller than the thickness of the second optical layer 1517b, but the embodiments of the present disclosure are not limited thereto. Accordingly, when viewed from a planar view, the area where the first optical layer 1517a is disposed can include a concave portion that is sunken inwardly from the upper surface of the second optical layer 1517b.

According to the embodiments of the present disclosure, a row line RL can be disposed on the first optical layer 1517a and the second optical layer 1517b. For example, the row line RL can be electrically connected to a plurality of row connection electrodes RCE through contact holes of the second optical layer 1517b. For example, the row line RL can be disposed on a plurality of light emitting devices ED. For example, the row line RL can include a transparent conductive oxide such as indium tin oxide (ITO) or indium zinc oxide (IZO), but the embodiments of the present disclosure are not limited thereto. For example, the row line RL can be arranged to be in contact with the second electrode Erl of the light emitting device ED. For example, the row line RL can overlap with the first optical layer 1517a. For example, the row line RL can cover a plane on the outside of the first optical layer 1517a.

The row line RL can extend continuously in the first direction (X) of the substrate 210. Accordingly, the row line RL can be commonly connected to a plurality of pixels arranged in the first direction (X) of the substrate 210. For example, the row line RL can be commonly connected to a plurality of pixels.

According to the embodiments of the present disclosure, the row line RL can be continuously extended on the first optical layer 1517a, the second optical layer 1517b, and the light emitting device ED. The area where the first optical layer 1517a is disposed can include a concave portion that is sunken inwardly from the upper surface of the second optical layer 1517b. Accordingly, the first part of the row line RL disposed on the first optical layer 1517a can be disposed along the concave portion, and thus can be disposed at a lower position than the second part of the row line RL disposed on the second optical layer 1517b.

A third optical layer 1517c can be disposed on the row line RL. The third optical layer 1517c can be disposed so as to overlap with a plurality of light emitting devices ED and the first optical layer 1517a. Since the third optical layer 1517c is arranged on the row line RL and the plurality of light emitting devices ED, it is possible to improve a mura that can occur in some of the plurality of light emitting devices ED. For example, when transferring a plurality of light emitting devices ED onto the substrate 210 of the display panel 110, there can occur an area where the spacing between the plurality of light emitting devices ED is not uniform due to process deviation. If the spacing between the plurality of light emitting devices ED is not uniform, emission areas of each of the plurality of light emitting devices ED can be arranged unevenly, and thus a mura can be visible to the user. Accordingly, since the third optical layer 1517c is arranged to uniformly diffuse light over the plurality of light emitting devices ED, it is possible to reduce light emitted from some of the light emitting devices ED from being visible as a mura. Accordingly, since the light emitted from the plurality of light emitting devices EDs is evenly diffused by the third optical layer 1517c and extracted to the outside of the display device 100, the luminance uniformity of the display device 100 can be improved.

The third optical layer 1517c can be composed of an organic insulating material in which fine particles are dispersed, but the embodiments of the present disclosure are not limited thereto. For example, the third optical layer 1517c can be composed of siloxane in which fine metal particles such as titanium dioxide (TiO₂) particles are dispersed, but the embodiments of the present disclosure are not limited thereto. For example, the third optical layer 1517c can be composed of the same material as the first optical layer 1517a, but the embodiments of the present disclosure are not limited thereto. For example, the third optical layer 1517c can be a diffusion layer or an upper diffusion layer, but the embodiments of the present disclosure are not limited thereto.

According to the embodiments of the present disclosure, light from a plurality of light emitting devices ED can be scattered by fine particles dispersed in a third optical layer 1517c and emitted to the outside of the display device 100. The third optical layer 1517c can evenly mix light emitted from a plurality of light emitting devices ED, thereby further improving the luminance uniformity of the display device 100. In addition, the light extraction efficiency of the display device 100 can be improved by the light scattered from the plurality of fine particles, thereby enabling the display device 100 to be driven at low power.

A black matrix BM can be arranged on the row line RL, the first optical layer 1517a, the second optical layer 1517b, and the third optical layer 1517c in the display area DA. For example, the black matrix BM can fill a contact hole of the second optical layer 1517b. The black matrix BM can be configured to cover the display area DA, so that the color mixing of light and external light reflection of the plurality of subpixels can be reduced. For example, the black matrix BM can also be arranged in the contact hole where the row line RL and the row connection electrode RCE are connected, so that light leakage between the neighboring plurality of subpixels can be prevented.

For example, the black matrix BM can be composed of an opaque material, but the embodiments of the present disclosure are not limited thereto. For example, the black matrix BM can be an organic insulating material to which a black pigment or a black dye is added, but the embodiments of the present disclosure are not limited thereto.

A cover layer 1518 can be arranged on the black matrix BM in the display area DA. The cover layer 1518 can protect a configuration under the cover layer 1518. For example, the cover layer 1518 can be composed of an organic insulating material, but the embodiments of the present disclosure are not limited thereto. For example, the cover layer 1518 can be composed of a photo resist, polyimide (PI), or photo acryl-based material, but the embodiments of the present disclosure are not limited thereto. For example, the cover layer 1518 can be an overcoating layer or an insulating layer, but the embodiments of the present disclosure are not limited thereto.

A polarizing layer 114 can be arranged on the cover layer 1518 via a first adhesive layer 112. A cover member 118 can be arranged on the polarizing layer 114 via a second adhesive layer 116. For example, the first adhesive layer 112 and the second adhesive layer 116 can include an optically clear adhesive (OCA), an optically clear resin (OCR), or a pressure sensitive adhesive (PSA), but the embodiments of the present disclosure are not limited thereto.

According to embodiments of the present disclosure, a plurality of pads PD can be arranged on a third insulating layer 1515c in a second non-display area NDA2. For example, at least a portion of the plurality of pads PD can be exposed from a passivation layer 1516. For example, the plurality of pads PD can be electrically connected to a fourth pad connection pattern PCP4 through a contact hole of the third insulating layer 1515c.

An adhesive layer ACF can be arranged on the plurality of pads PD. The adhesive layer ACF can be an adhesive layer in which conductive balls are dispersed in an insulating material, but embodiments of the present disclosure are not limited thereto. When heat or pressure is applied to the adhesive layer ACF, the conductive balls can be electrically connected at a portion where the heat or pressure is applied, thereby having conductive properties. The adhesive layer ACF can be disposed between a plurality of pads PD and a flexible printed circuit 102, so that the flexible printed circuit 102 can be attached or bonded to the plurality of pads PD. For example, the adhesive layer ACF can be an anisotropic conductive film ACF, but the embodiments of the present disclosure are not limited thereto.

A flexible printed circuit 102 can be disposed on the adhesive layer ACF. The flexible printed circuit 102 can be electrically connected to the plurality of pads PD through the adhesive layer ACF. Accordingly, a signal supplied from the flexible printed circuit 102 can be transmitted to a driver DRV of a display area DA through the plurality of pads PD, the fourth pad connection pattern PCP4, the third pad connection pattern PCP3, the second pad connection pattern PCP2, and the first pad connection pattern PCP1.

Referring to FIG. 15, the display panel 110 according to the embodiments of the present disclosure can include a substrate 210, a layer stack 1410 on a plurality of drivers DRV disposed on the substrate 210, an optical layer 1517a disposed between a plurality of light emitting devices EDa, EDb and EDc on the layer stack 1410, an adhesive layer 116 disposed on the plurality of light emitting devices EDa, EDb and EDc and the optical layer 1517a, and a cover member 118 disposed on the adhesive layer 116.

A plurality of column lines CL can be disposed between the layer stack 1410 and the plurality of light emitting devices EDa, EDb and EDc.

A plurality of row lines RL can be arranged on a plurality of light emitting devices EDa, EDb and EDc and an optical layer 1517a. A plurality of row lines RL can be arranged between a plurality of light emitting devices EDa, EDb and EDc, an optical layer 1517a, and an adhesive layer 116.

A layer stack 1410 can include a plurality of protection layers 1513a, 1513b and 1514 arranged on the side and upper surface of each of a plurality of drivers DRV, a plurality of insulating layers 1515a, 1515b and 1515c arranged on the plurality of protection layers 1513a, 1513b and 1514, and a bank BNK arranged on the plurality of insulating layers.

The plurality of protection layers 1513a, 1513b and 1514 can further include a side protection layer 1513 disposed on each side of the plurality of drivers DRV and an upper protection layer 1514 disposed on the upper surface of each of the plurality of drivers DRV.

The side protection layer 1513 can include a first protection layer 1513a disposed on the substrate 210 and a second protection layer 1513b disposed on the first protection layer 1513a.

The upper protection layer 1514 can include a third protection layer 1514 disposed on a second protection layer 1513b and the plurality of drivers DRV.

The plurality of insulating layers 1515a, 1515b and 1515c can include a first insulating layer 1515a disposed on the upper protection layer 1514, and a second insulating layer 1515b disposed on the first insulating layer 1515a. The plurality of insulating layers 1515a, 1515b and 1515c can further include a third insulating layer 1515c disposed on the second insulating layer 1515b.

Each of the plurality of light emitting devices EDa, EDb and EDc can be disposed on the bank BNK and positioned in an opening of the optical layer 1517a.

At least a portion of each of the plurality of column lines CL can extend onto the bank BNK on the plurality of insulating layers 1515a, 1515b and 1515c. Each of the plurality of row lines RL can be arranged on the optical layer 1517a and the plurality of light emitting devices EDa, EDb and EDc.

A first electrode Ecl of each of the plurality of light emitting devices EDa, EDb and EDc can be electrically connected to at least a portion of a column line CL extending onto the bank BNK among the plurality of column lines CL. A second electrode Erl of each of the plurality of light emitting devices EDa, EDb and EDc can be electrically connected to one of the plurality of row lines RL.

The display panel 110 according to the embodiments of the present disclosure can include a plurality of line connection patterns LCPs that connect each of a plurality of lines including a plurality of row lines RL and a plurality of column lines CL to a plurality of drivers DRV.

The plurality of line connection patterns LCPs can include a first line connection pattern LCP1 disposed on a side protection layer 1513, a second line connection pattern LCP2 disposed on an upper protection layer 1514 and electrically connected to the first line connection pattern LCP1 through a hole in the upper protection layer 1514, a third line connection pattern LCP3 disposed on a first insulating layer 1515a and electrically connected to the second line connection pattern LCP2 through a hole in the first insulating layer 1515a, and a fourth line connection pattern LCP4 disposed on a second insulating layer 1515b and electrically connected to the third line connection pattern LCP3 through a hole in the second insulating layer 1515b.

The first line connection pattern LCP1 can be electrically connected to one of the plurality of drivers DRV. The fourth line connection pattern LCP4 can be electrically connected to a second electrode Erl of at least one of the plurality of light emitting devices EDa, EDb and EDc, or can be electrically connected to a first electrode Ecl of at least one of the plurality of light emitting devices EDa, EDb and EDc.

The side protection layer 1513 arranged on each side of the plurality of drivers DRV can include two or more organic layers.

The first and second protection layers 1513a and 1513b as the side protection layer 1513, the third protection layer 1514 as the upper protection layer 1514, and the first to third insulating layers 1515a, 1515b and 1515c can each be composed of organic layers.

In the above, there have been described the structure and operation related to the display function of the display device 100 according to the embodiments of the present disclosure.

The display device 100 according to the embodiments of the present disclosure can provide not only a display function but also a touch sensing function. Accordingly, hereinafter, it will be described a structure and an operation related to the touch sensing function of the display device 100 according to the embodiments of the present disclosure.

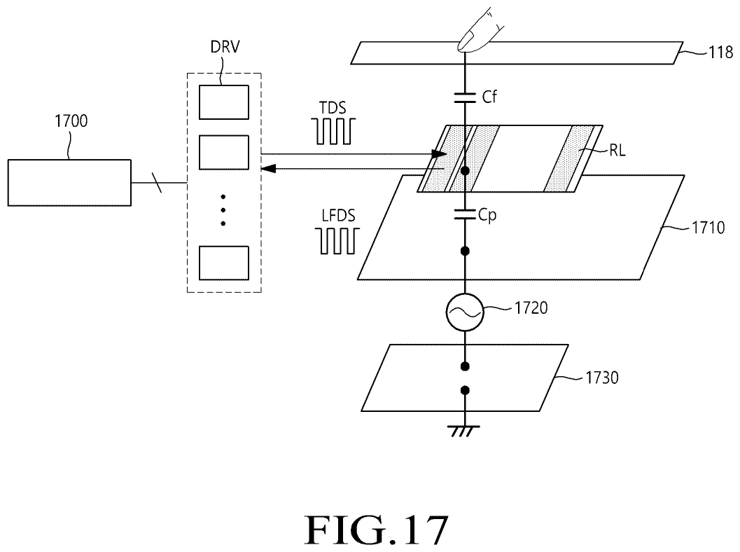

FIG. 17 is a diagram briefly illustrating the touch sensing structure of the display device 100 according to the embodiments of the present disclosure.

Referring to FIG. 17, the display device 100 according to the embodiments of the present disclosure can include a plurality of row lines RL that serve as touch sensors to perform touch sensing, a plurality of drivers DRV for driving and sensing the plurality of row lines RL, and a touch control circuit 1700 that controls the plurality of drivers DRV. The drivers DRV and the touch control circuit 1700 can be included in a driving circuit.

The plurality of drivers DRV can supply a touch driving signal TDS having a variable voltage level to at least one of the plurality of row lines RL. The touch driving signal TDS is a signal whose voltage level fluctuates, and can also be referred to as an AC signal or a pulse signal. For example, the touch driving signal TDS can have a signal waveform such as a square wave, a sine wave, or a triangular wave. For example, the frequency of the touch driving signal TDS can be constant. For another example, the frequency of the touch driving signal TDS can be variable. If the frequency of the touch driving signal TDS is variable according to the touch driving period T or time, it is possible to prevent the touch sensitivity degradation due to noise generated during the touch driving. A voltage level of the touch driving signal TDS can be outside a voltage range in which the light emitting device ED is able to emit light.

A plurality of drivers DRV can sense or detect an electrical state (e.g., a capacitance change) in at least one of a plurality of row lines RL to generate sensing data, and output the generated sensing data. Here, the sensing data can include digital sensing values.

The plurality of drivers DRV can include at least one analog-to-digital converter ADC to sense an electrical state in at least one of the plurality of row lines RL to obtain digital sensing values.

For example, the electrical state in at least one of the plurality of row lines RL can include a capacitance Cf between a touch object such as a finger or a pen and each row line RL. For another example, the electrical state in at least one of the plurality of row lines RL can include a capacitance between two row lines RL.

The touch control circuit 1700 can supply a touch driving signal TDS or a signal as a base of the touch driving signal TDS to each of the plurality of drivers DRV, and determine an occurrence of a touch or a touch position based on sensing data provided from each of the plurality of drivers DRV. For example, the touch control circuit 1700 can include a timing controller or a micro-control unit. The touch control circuit 1700 can further include a power management integrated circuit PMIC, etc.

The display device 100 according to the embodiments of the present disclosure can perform self-capacitance-based touch sensing and/or mutual-capacitance-based touch sensing.

If a touch driving signal TDS is applied to at least one of a plurality of row lines RL for touch sensing, an unwanted parasitic capacitance Cp can be formed between the row line RL supplied with the touch driving signal TDS and other electrodes or other wirings around the corresponding row line RL. The parasitic capacitance Cp can be a factor causing a reduction of the touch sensitivity.

The display device 100 according to the embodiments of the present disclosure can further include a touch ground 1710 arranged below the plurality of row lines RL. The touch ground 1710 can correspond to an electrode that forms a parasitic capacitance Cp with the row line RL.

The display device 100 according to the embodiments of the present disclosure can further include a guard driver 1720 that supplies a load free driving signal LFDS whose signal characteristics correspond to the touch driving signal TDS to the touch ground 1710 in order to prevent an unwanted parasitic capacitance Cp from being formed between the row line RL and the touch ground 1710.

The load free driving signal LFDS output from the guard driver 1720 and applied to the touch ground 1710 can be a signal whose signal characteristics are similar to the touch driving signal TDS output from the driver DRV and supplied to the row line RL. For example, the signal characteristics can include frequency, amplitude, and phase.

For example, the load free driving signal LFDS can have the same frequency as the touch driving signal TDS. The load free driving signal LFDS can have the same amplitude as the touch driving signal TDS. The load free driving signal LFDS can have the same phase as the touch driving signal TDS.

The display device 100 according to the embodiments of the present disclosure can further include a system ground 1730 that serves as a ground for the entire system.

Hereinafter, it will be described the touch sensing system and touch sensing operation of the display device 100 according to the embodiments of the present disclosure in more detail.

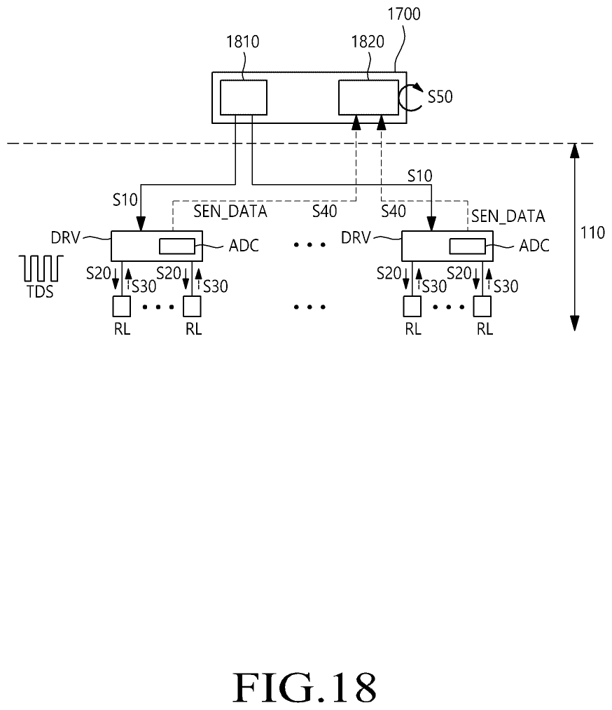

FIG. 18 illustrates the touch sensing system of the display device 100 according to the embodiments of the present disclosure.

Referring to FIG. 18, the display device 100 according to the embodiments of the present disclosure can include a plurality of row lines RL corresponding to touch sensors, a plurality of drivers DRV for driving and sensing the plurality of row lines RL, and a touch control circuit 1700 for controlling the plurality of drivers DRV.

The touch control circuit 1700 can include a signal supply circuit 1810 that supplies a touch driving signal TDS to at least one of the plurality of drivers DRV, and a touch sensing circuit 1820 that receives sensing data SEN_DATA from at least one of the plurality of drivers DRV to determine an occurrence of a touch and/or a touch position (e.g., touch coordinates).

Each of the plurality of drivers DRV can include an analog-to-digital converter ADC that converts a signal (e.g., analog signal) sensed through at least one row line RL of the plurality of row lines RL into a digital sensing value. In this way, since the analog-to-digital converter ADC exists in the display panel 110, a digital sensing value corresponding to a digital signal can exist among various signals existing in the display panel 110. For example, the display panel 110 can be a unique panel in which an analog domain in which an analog signal exists and a digital domain in which a digital signal exists coexist.

The signal supply circuit 1810 of the touch control circuit 1700 can supply a touch driving signal TDS or a signal that is the basis of the touch driving signal TDS to each of the plurality of drivers DRV (step S10).

Each of the plurality of drivers DRV can receive a touch driving signal TDS or a signal that is the basis of the touch driving signal TDS from the signal supply circuit 1810 of the touch control circuit 1700 (step S10), and output the touch driving signal TDS to at least one of two or more row lines RL arranged in the corresponding unit driving area UDA (step S20).

Each of the plurality of drivers DRV can supply a touch driving signal TDS to all or part of two or more row lines RL included in a corresponding unit driving area UDA (step S20).

Each of the plurality of drivers DRV can sense at least one of two or more row lines RL arranged in the corresponding unit driving area UDA (step S30). Each of the plurality of drivers DRV can sense at least one of the two or more row lines RL, convert a sensing signal obtained according to the sensing result into a digital sensing value, and generate sensing data SEN_DATA including the converted digital sensing values.

Each of the plurality of drivers DRV can provide sensing data SEN_DATA to a touch sensing circuit 1820 of a touch control circuit 1700 (step S40).

The touch control circuit 1700 can determine whether a touch has occurred or a touch position based on sensing data SEN_DATA provided from each of the plurality of drivers DRV (step S50).

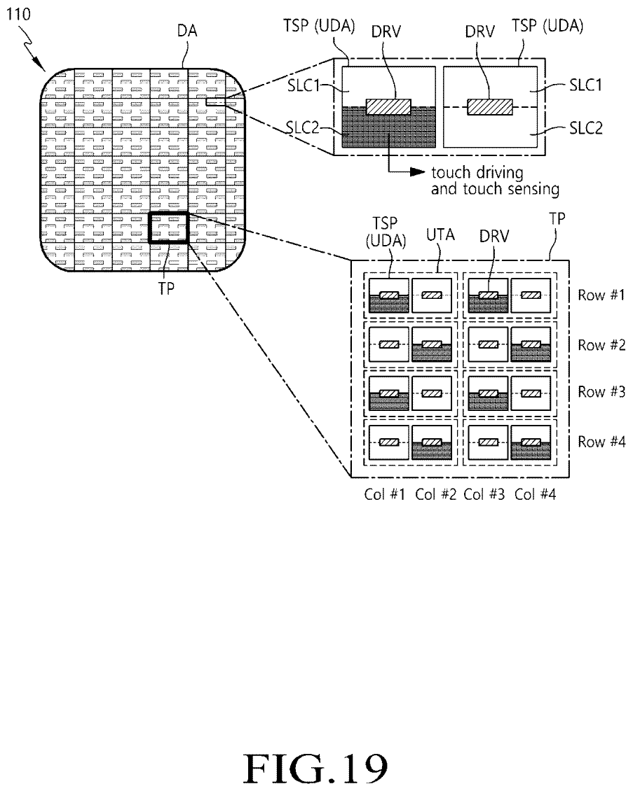

FIG. 19 illustrates a touch driving structure of a display panel 110 according to embodiments of the present disclosure. FIGS. 4, 6 and 11 can also be referred to in the following description.

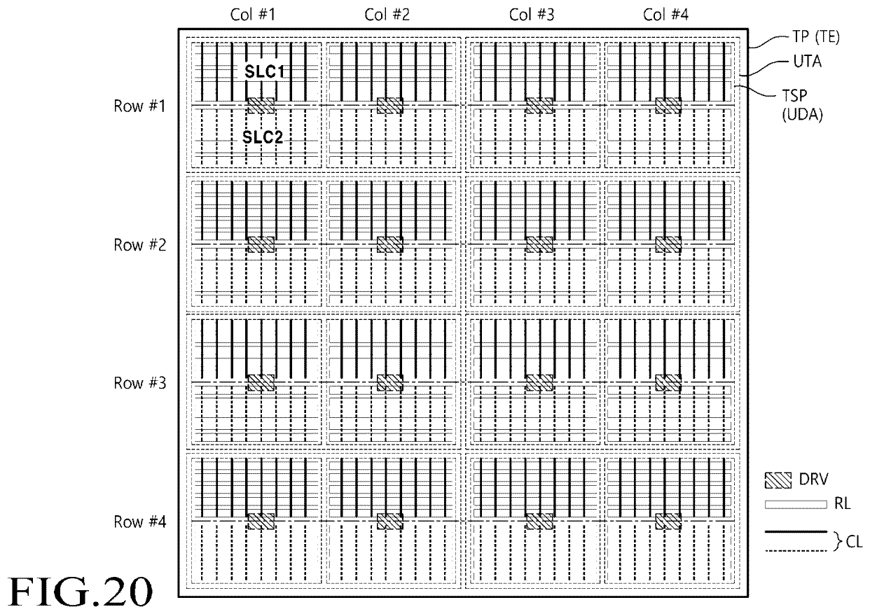

Referring to FIG. 19, the display area DA of the display panel 110 can include a plurality of touch pixel areas TP. Each of the plurality of touch pixel areas TP can be an area corresponding to one touch electrode TE (see FIG. 20).

A plurality of row lines RL arranged in one touch pixel area TP corresponding to one touch electrode and simultaneously performing touch driving can be processed as one touch electrode TE in the touch control circuit 1700 even if they are driven and sensed by a plurality of drivers DRV. For example, a plurality of row lines RL arranged in one touch pixel area TP and simultaneously performing touch driving can be recognized as one touch electrode TE electrically connected to each other.

The touch control circuit 1700 can determine an occurrence of the touch and/or a touch coordinate by considering the combined sensing data SEN_DATA obtained from each of the plurality of row lines RL arranged in one touch pixel area TP and simultaneously performing touch driving as sensing data obtained from one touch electrode TE.

Each of the plurality of touch pixel areas TP can include a plurality of touch subpixel areas TSP. According to the example of FIG. 19, each of the plurality of touch pixel areas TP can include 16 touch subpixel areas TSP. The 16 touch subpixel areas TSP can be arranged in 4 rows and 4 columns.

Each of the plurality of touch subpixel areas TSP can include one of the plurality of drivers DRV. For example, one driver DRV can be arranged in one touch subpixel area TSP. One touch subpixel area TSP can correspond to one unit driving area UDA.

Each of the plurality of touch subpixel areas TSP can include two or more row lines RL and two or more column lines CL. Each of the plurality of touch subpixel areas TSP can include two or more subpixels SP. Each of the plurality of touch subpixel areas TSP can include two or more light emitting devices ED. Each of the plurality of row lines RL can overlap with two or more light emitting devices ED.

Each of the plurality of touch pixel areas TP can include two or more unit touch driving areas UTA. Each of the two or more unit touch driving areas UTA can include at least one touch subpixel area TSP. According to the example of FIG. 19, each of the two or more unit touch driving areas UTA can include two touch subpixel areas TSP. Here, the unit touch driving area UTA is an area that becomes a basic unit of a touch driving pattern.

One touch subpixel area TSP corresponding to one unit driving area UDA can include two sub-touch driving areas SLC1 and SLC2. The two sub-touch driving areas can include a first sub-touch driving area SLC1 and a second sub-touch driving area SLC2. For example, the first sub-touch driving area SLC1 can correspond to an upper area in one touch subpixel area TSP, and the second sub-touch driving area SLC2 can correspond to a lower area in one touch subpixel area TSP. However, embodiments of the present disclosure are not limited thereto.

Two or more row lines RL and two or more column lines CL can be arranged in each of the first sub-touch driving area SLC1 and the second sub-touch driving area SLC2. Each of the first sub-touch driving area SLC1 and the second sub-touch driving area SLC2 can include two or more light emitting devices ED.

Two or more row lines RL arranged in the first sub-touch driving area SLC1 and two or more row lines RL arranged in the second sub-touch driving area SLC2 may not be connected to each other, and can be arranged separately from each other. Two or more column lines CL arranged in the first sub-touch driving area SLC1 and two or more column lines CL arranged in the second sub-touch driving area SLC2 may not be connected to each other, and can be arranged separately from each other.

The two sub-touch driving areas SLC1 and SLC2 can correspond to the two sub-driving areas SDA1 and SDA2 included in one unit driving area UDA in FIG. 4, FIG. 6, and FIG. 11, respectively.

One unit touch driving area UTA can include two touch subpixel areas TSP. One unit touch driving area UTA can include two sub-touch driving areas SLC1 and SLC2 included in each of two touch subpixel areas TSP. For example, one unit touch driving area UTA can include four sub-touch driving areas. One unit touch driving area UTA can include two drivers DRV.

For example, a touch pixel area TP can include 16 touch subpixel areas TSP arranged in four rows and four columns. Each of the 16 touch subpixel areas TSP can include one driver DRV and two sub-touch driving areas SLC1 and SLC2.

As an example, during a touch driving period for touch sensing, all four sub-touch driving areas included in one unit touch driving area UTA can be driven and sensed. Accordingly, during a touch driving period for touch sensing, each of the two drivers DRV included in one unit touch driving area UTA can drive and sense all two sub-touch driving areas SLC1 and SLC2 included in the corresponding touch subpixel area TSP.

As another example, during a touch driving period for touch sensing, only some of the four sub-touch driving areas included in one unit touch driving area UTA can be driven and sensed. According to the example of FIG. 19, during the touch driving period for touch sensing, only one sub-touch driving area among four sub-touch driving areas included in one unit touch driving area UTA can be driven and sensed. Accordingly, during the touch driving period for touch sensing, only one driver DRV among two drivers DRV included in one unit touch driving area UTA can drive and sense one of two sub-touch driving areas SLC1 and SLC2 included in the corresponding touch subpixel area TSP.

According to the embodiments of the present disclosure, the fact that the sub-touch driving area is driven and sensed can mean that two or more row lines RL arranged in the sub-touch driving area are driven (i.e., touch driven) and sensed.

The fact that two or more row lines RL arranged in the sub-touch driving area are driven (i.e., touch driven) can mean that a touch driving signal TDS having a variable voltage level is applied to two or more row lines RL arranged in the sub-touch driving area.

In the touch pixel area TP, the sub-touch driving area where touch driving and touch sensing are performed can be arranged in a zigzag shape.

For example, if a touch pixel area TP includes 16 touch subpixel areas TSP arranged in four rows and four columns, in each of the first touch subpixel row Row #1 and the third touch subpixel row Row #3, the second sub-touch driving area SLC2 among the two sub-touch driving areas SLC1 and SLC2 included in the touch subpixel area TSP located in the first column Col #1 can be driven and sensed, the two sub-touch driving areas SLC1 and SLC2 included in the touch subpixel area TSP located in the second column Col #2 can be not driven and sensed. In addition, the second sub-touch driving area SLC2 among the two sub-touch driving areas SLC1 and SLC2 included in the touch subpixel area TSP located in the third column Col #3 can be driven and sensed, and the two sub-touch driving areas SLC1 and SLC2 included in the touch subpixel area TSP located in the fourth column Col #4 may not be driven and sensed.

In the second touch subpixel row Row #2 and the fourth touch subpixel row Row #4, the two sub-touch driving areas SLC1 and SLC2 included in the touch subpixel area TSP located in the first column Col #1 may not be driven and sensed, and the second sub-touch driving area SLC2 among the two sub-touch driving areas SLC1 and SLC2 included in the touch subpixel area TSP located in the second column Col #2 can be driven and sensed. In addition, the two sub-touch driving areas SLC1 and SLC2 included in the touch subpixel area TSP located in the third column Col #3 may not be driven and sensed, and the second sub-touch driving area SLC2 among the two sub-touch driving areas SLC1 and SLC2 included in the touch subpixel area TSP located in the fourth column Col #4 can be driven and sensed.

One touch pixel area TP includes a plurality of touch subpixel areas TSP, and each of the plurality of touch subpixel areas TSP can include two or more row lines RL and two or more column lines CL. Each of the plurality of touch subpixel areas TSP can include two or more light emitting devices ED.

One touch pixel area TP includes a plurality of touch subpixel areas TSP, and each of the plurality of touch subpixel areas TSP can include two sub-touch driving areas SLC1 and SLC2. Each of the two sub-touch driving areas SLC1 and SLC2 can include two or more row lines RL and two or more column lines CL. Each of the two sub-touch driving areas SLC1 and SLC2 can include two or more light emitting devices ED.

The touch subpixel area TSP will be exemplified by using the (2n×m) pixel array structure of FIG. 4.

One touch subpixel area TSP can be a unit driving area UDA driven by one of the plurality of drivers DRV.

Each of the plurality of pixels P can include k light emitting devices ED among the plurality of light emitting devices ED, and k can be a natural number greater than or equal to 2.

Each of the plurality of touch subpixel areas TSP can include (2n×m) pixels P arranged in 2n rows and m columns among the plurality of pixels P, 2n row lines RL among the plurality of row lines RL, and (m×k) column lines CL or (m×k×2) column lines CL among the plurality of column lines CL.

Each of the 2n row lines RL can correspond to m pixels P arranged in the same row among the (2n×m) pixels P. The (2n×m) pixels P can include (2n×m×k) light emitting devices ED. The n can be a natural number greater than or equal to 1, and the m can be a natural number greater than or equal to 1.

Each of the plurality of touch subpixel areas TSP can be divided into a first sub-touch driving area SLC1 and a second sub-touch driving area SLC2, which correspond to two sub-driving areas SDA1 and SDA2.

Each of the first sub-touch driving area SLC1 and the second sub-touch driving area SLC2 can include (n×m) pixels P arranged in n rows and m columns among (2n×m) pixels P, n row lines RL among 2n row lines RL, and (m×k) column lines CL among (m×k×2) column lines CL.

One row line RL among the n row lines RL can be shared by m pixels P arranged in one row among the (n×m) pixels P. The k column lines CL among the (m×k) column lines CL can be shared by n pixels P arranged in the same column among the (n×m) pixels P.

Each of the first sub-touch driving area SLC1 and the second sub-touch driving area SLC2 can include (n×m×k) light emitting devices ED. Among the (n×m×k) light emitting devices ED, the first electrodes Ecl of the n light emitting devices ED arranged in the same column can be electrically connected in common with one of the (m×k) column lines CL. Among the (n×m×k) light emitting devices ED, the second electrodes Erl of the (m×k) light emitting devices ED arranged in the same row can be electrically connected in common with one of the n row lines RL.

Among the plurality of touch subpixel areas TSP, two adjacent touch subpixel areas TSP can be combined to define one unit touch driving area UTA.

Among the plurality of touch subpixel areas TSPs, two adjacent touch subpixel areas TSP can include four sub-touch driving areas.

For example, during the touch driving period, a touch driving signal TDS can be supplied to all four sub-touch driving areas. For example, during the touch driving period, all four sub-touch driving areas can be driven and sensed.

For another example, during the touch driving period, a touch driving signal TDS can be supplied to only one to three sub-touch driving areas among the four sub-touch driving areas. For example, during the touch driving period, one to three sub-touch driving areas among the four sub-touch driving areas can be driven and sensed.

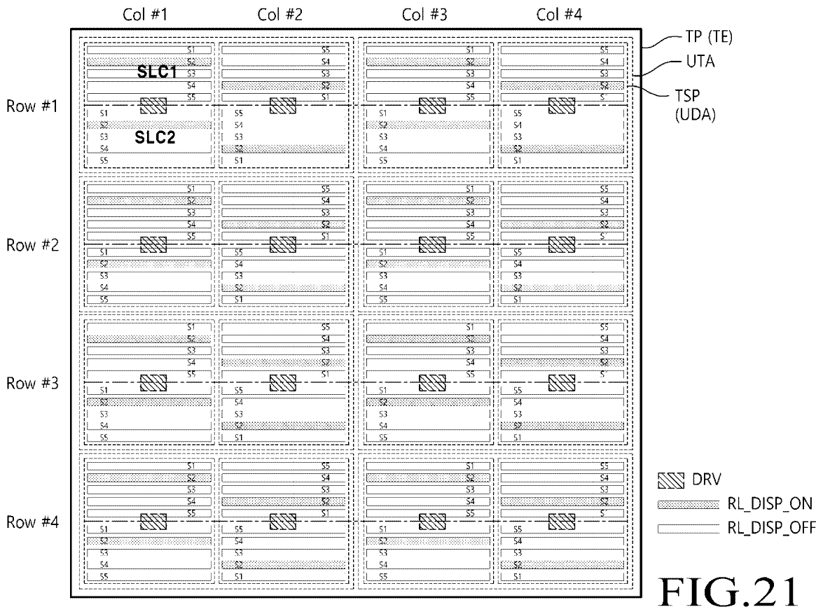

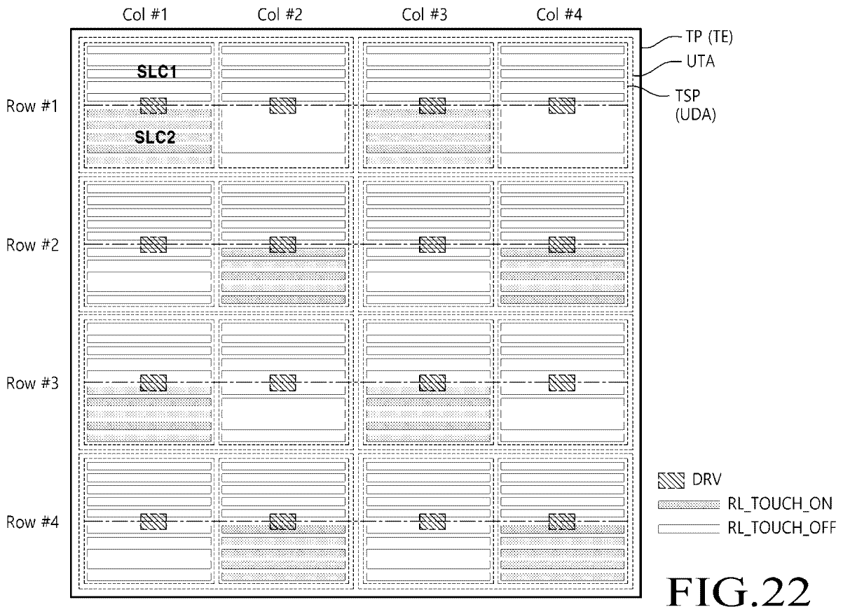

Hereinafter, it will be described a planar structure of the touch pixel area TP with reference to FIG. 20, and it will be described display driving and touch driving for the touch pixel area TP with reference to FIG. 21 and FIG. 22.

FIG. 20 is a plan view of one touch pixel area TP of a display panel 110 according to embodiments of the present disclosure.

Referring to FIG. 20, one touch pixel area TP can be an area of one touch electrode TE. At least one row line RL among a plurality of row lines RL arranged in one touch pixel area TP can constitute one touch electrode TE.

The touch pixel area TP can include a plurality of touch subpixel areas TSP arranged in a matrix form. For example, the touch pixel area TP can include 16 touch subpixel areas TSP arranged in four rows Row #1 to Row #4 and four columns Col #1 to Col #4.

Each of the 16 touch subpixel areas TSP can be a unit driving area UDA, and can include one driver DRV as a driving circuit.

Each of the 16 touch subpixel areas TSP can include a plurality of row lines RL and a plurality of column lines CL. The plurality of row lines RL and the plurality of column lines CL can overlap and intersect with each other. The plurality of row lines RL and the plurality of column lines CL can be arranged in different metal layers.

In each of the 16 touch subpixel areas TSP, a plurality of row lines RL and a plurality of column lines CL can be driven by the same driver DRV.

Each of the 16 touch subpixel areas TSP can include a first sub-touch driving area SLC1 and a second sub-touch driving area SLC2. Each of the first sub-touch driving area SLC1 and the second sub-touch driving area SLC2 can include at least one row line RL and at least one column line CL.

Each of the 16 touch subpixel areas TSP can include a plurality of pixels P, each of the plurality of pixels P can include two or more subpixels SP, and each of the two or more subpixels SP can include at least one light emitting device ED.

The light emitting device ED can include a first electrode and a second electrode. The first electrode can be electrically connected to one column line CL, and the second electrode can be electrically connected to one row line RL.

Two adjacent touch subpixel areas TSP can constitute one unit touch driving area UTA.

FIG. 21 illustrates a display driving situation for one touch pixel area TP during a display driving period D of a display device 100 according to embodiments of the present disclosure. Hereinafter, FIG. 20 is also referred to in the following description.

Referring to FIG. 21, during the display driving period D, a plurality of row lines RL can be classified into a display-on driving row line RL_DISP_ON in which display-on driving is performed and a display-off driving row line RL_DISP_OFF in which display-off driving is performed.

A first low-potential voltage VSS1 can be applied to a display-on driving row line RL_DISP_ON, and a second low-potential voltage VSS2 can be applied to a display-off driving row line RL_DISP_OFF.

When driving a display for a touch pixel area TP during a display driving period D, each of the 16 touch subpixel areas TSP included in the touch pixel area TP can be driven independently of each other.

A first sub-touch driving area SLC1 and a second sub-touch driving area SLC2 included in each of the 16 touch subpixel areas TSP can be driven independently of each other. For example, in the 16 touch subpixel areas TSP, when the first sub-touch driving area SLC1 is driven, the second sub-touch driving area SLC2 can also be driven.

In the 16 touch subpixel areas TSP, a plurality of row lines RL included in the first sub-touch driving area SLC1 can be driven sequentially, and a plurality of row lines RL included in the second sub-touch driving area SLC2 can be driven sequentially.

The display driving method of each of the 8 touch subpixel areas TSP arranged in the odd columns Col #1 and Col #3 can be the same, and the display driving method of each of the 8 touch subpixel areas TSP arranged in the even columns Col #2 and Col #4 can be the same.

The display driving method of each of the eight touch subpixel areas TSP arranged in odd columns Col #1 and Col #3 and the display driving method of each of the eight touch subpixel areas TSP arranged in even columns Col #2 and Col #4 can be different from each other.

In each of the 8 touch subpixel areas TSP arranged in odd columns Col #1 and Col #3, a plurality of row lines RL arranged in the first sub-touch driving area SLC1 can be sequentially driven from top to bottom, and a plurality of row lines RL arranged in the second sub-touch driving area SLC2 can also be sequentially driven from top to bottom. In FIGS. 21, S1 to S5 are indexes indicating the driving order, S1 is an index indicating the earliest driving order, and S5 is an index indicating the latest driving order.

In each of the 8 touch subpixel areas TSP arranged in even columns Col #2 and Col #4, a plurality of row lines RL arranged in the first sub-touch driving area SLC1 can be sequentially driven from bottom to top, and a plurality of row lines RL arranged in the second sub-touch driving area SLC2 can also be sequentially driven from bottom to top.

For example, in the touch subpixel area TSP of the first row Row #1 in the first column Col #1, a plurality of row lines RL arranged in the first sub-touch driving area SLC1 can be sequentially driven from top to bottom, and a plurality of row lines RL arranged in the second sub-touch driving area SLC2 can also be sequentially driven from top to bottom.

In the second column Col #2, in the touch subpixel area TSP of the first row Row #1, a plurality of row lines RL arranged in the first sub-touch driving area SLC1 can be sequentially driven from the bottom to the top, and a plurality of row lines RL arranged in the second sub-touch driving area SLC2 can also be sequentially driven from the bottom to the top.

FIG. 21 illustrates a situation at a specific point in time (e.g., a point in time corresponding to S2) during the display driving period D.

Referring to FIG. 21, at a specific point in time (e.g., a point in time corresponding to S2) during the display driving period D, in each touch subpixel area TSP arranged in an odd column Col #1 and Col #3, among the five row lines RL arranged in each of the first sub-touch driving area SLC1 and the second sub-touch driving area SLC2, the second row line RL from the top can be a display-on driving row line RL_DISP_ON, and the remaining row lines RL can be display-off driving row lines RL_DISP_OFF.

At a specific point in time (e.g., a point in time corresponding to S2) during the display driving period D, in each touch subpixel area TSP arranged in an even column Col #2 and Col #4, the second row line RL from the bottom among the five row lines RL arranged in each of the first sub-touch driving area SLC1 and the second sub-touch driving area SLC2 can be a display-on driving row line RL_DISP_ON, and the remaining row lines RL can be display-off driving row lines RL_DISP_OFF.

A first low-potential voltage VSS1 can be applied to the display-on driving row line RL_DISP_ON. Accordingly, the light emitting devices ED connected to the display-on driving row line RL_DISP_ON can emit light.

A second low-potential voltage VSS2 higher than the first low-potential voltage VSS1 can be applied to the display-off driving row line RL_DISP_OFF. Accordingly, the light emitting devices ED connected to the display-off driving row line RL_DISP_OFF may not emit light.

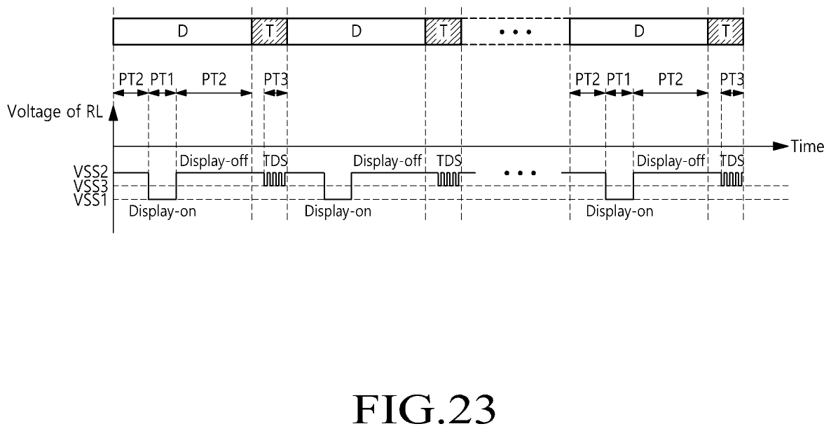

FIG. 22 illustrates a touch driving situation for one touch pixel area TP during a touch driving period T (see FIG. 23) of a display device 100 according to embodiments of the present disclosure.

Referring to FIG. 22, during the touch driving period T, a touch driving signal TDS is applied to the row line RL to drive the row line RL. The minimum voltage value of the touch driving signal TDS can be greater than the first low-potential voltage VSS1.

During the touch driving period T, a plurality of row lines RL can be classified into a touch driving row line RL_TOUCH_ON and a non-touch driving row line RL_TOUCH_OFF.

A touch driving signal TDS whose voltage level is variable can be applied to a touch driving row line RL_TOUCH_ON. The touch driving row line RL_TOUCH_ON can be sensed by a driver DRV.

A touch driving signal TDS may not be applied to a non-touch driving row line RL_TOUCH_OFF. In some cases, even if a touch driving signal TDS or a similar signal is applied to the non-touch driving row line RL_TOUCH_OFF, the non-touch driving row line RL_TOUCH_OFF may not be sensed by a driver DRV.

Hereinafter, it will be described a touch driving method for 16 touch subpixel areas TSP included in a touch pixel area TP during a touch driving period T.

As an example, during one touch driving period T, all 16 touch subpixel areas TSP included in a touch pixel area TP can be driven.

In this case, all or part of a plurality of row lines RL included in each of the 16 touch subpixel areas TSPs can be driven. For example, all or part of a plurality of row lines RL arranged in each of the first sub-touch driving area SLC1 and the second sub-touch driving area SLC2 included in each of the 16 touch subpixel areas TSP can be driven. For another example, all or part of the plurality of row lines RL arranged in one of the first sub-touch driving area SLC1 and the second sub-touch driving area SLC2 included in each of the 16 touch subpixel areas TSP can be driven.

As another example, during one touch driving period T, only at least one of the 16 touch subpixel areas TSPs included in the touch pixel area TP can be driven.

In this case, all or part of the plurality of row lines RL included in each of at least one of the 16 touch subpixel areas TSP can be driven. For example, all or part of the plurality of row lines RL arranged in each of the first sub-touch driving area SLC1 and the second sub-touch driving area SLC2 included in each of at least one of the 16 touch subpixel areas TSP can be driven. For another example, all or part of a plurality of row lines RL arranged in one of the first sub-touch driving area SLC1 and the second sub-touch driving area SLC2 included in at least one of the 16 touch subpixel areas TSP can be driven.

According to the example of FIG. 22, during one touch driving period T, among the four touch subpixel areas TSP arranged in each of the first row Row #1 and the second row Row #2, only the touch subpixel areas TSP arranged in the first column Col #1 and the third column Col #3 can be driven. In addition, in this case, among the four touch subpixel areas TSP arranged in each of the second row Row #2 and the fourth row Row #4, only the touch subpixel areas TSP arranged in the second column Col #2 and the fourth column Col #4 can be driven.

In each of the first row Row #1 and the second row Row #2, among the first sub-touch driving area SLC1 and the second sub-touch driving area SLC2 included in each of the touch subpixel areas TSP arranged in the first column Col #1 and the third column Col #3 where touch driving is performed, only the second sub-touch driving area SLC2 can be driven. If a touch driving signal TDS is applied to five row lines RL arranged in the second sub-touch driving area SLC2, which is the area where touch driving is performed, the second sub-touch driving area SLC2 can be driven.

In each of the second row Row #2 and the fourth row Row #4, among the first sub-touch driving area SLC1 and the second sub-touch driving area SLC2 included in each of the touch subpixel areas TSP arranged in the second column Col #2 and the fourth column Col #4 where touch driving is performed, only the second sub-touch driving area SLC2 can be driven. The second sub-touch driving area SLC2 can be driven by applying a touch driving signal TDS to five row lines RL arranged in the second sub-touch driving area SLC2, which is the area where touch driving is performed.

Hereinafter, it will be described a driving method of a display device 100 according to embodiments of the present disclosure in more detail.

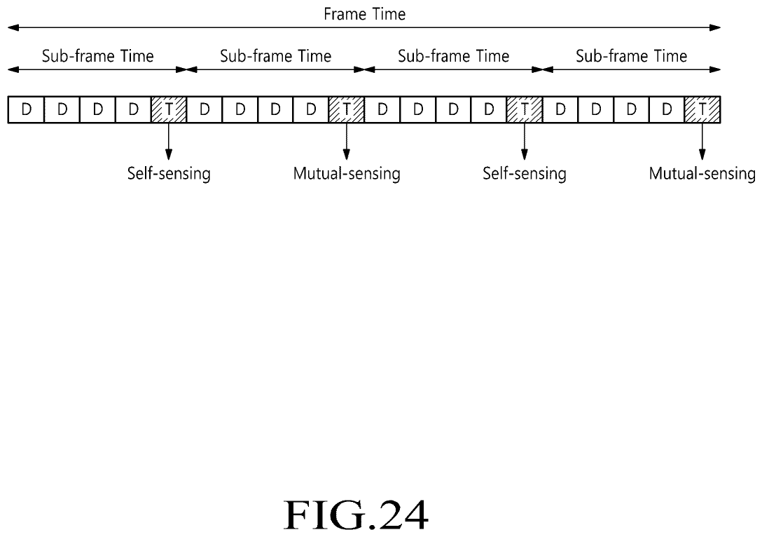

FIGS. 23 and 24 are driving timing diagrams of a display device 100 according to embodiments of the present disclosure.

Referring to FIGS. 23 and 24, the display device 100 according to the embodiments of the present disclosure can perform display driving for image display and touch driving (or touch sensing) for touch sensing.

The display device 100 according to the embodiments of the present disclosure can allocate a display driving period D and a touch driving period T, perform display driving during the display driving period D, and perform touch driving during the touch driving period T.

The display device 100 according to the embodiments of the present disclosure can perform display driving and touch driving according to a time-division driving method or a simultaneous driving method.

For example, the display device 100 according to the embodiments of the present disclosure can allocate the display driving period D and the touch driving period T as separate time periods according to the time-division driving method, and can perform display driving during the display driving period D and perform touch driving during the touch driving period T different from the display driving period D.

As another example, the display device 100 according to the embodiments of the present disclosure can perform display driving and touch driving simultaneously during the display driving period D and the touch driving period T that overlap in time according to the simultaneous driving method.

Hereinafter, for the convenience of explanation, the display device 100 according to the embodiments of the present disclosure performs display driving and touch driving at different time periods according to the time division driving method as an example. However, this is not limited thereto.

As an example of a time division driving method, as illustrated in FIG. 23, one display driving period D and one touch driving period T can alternately proceed. For example, one display driving period D can proceed, and then one touch driving period T can proceed.

As an example, one display driving period D can be a period during which display driving is performed to display an image on the entire screen. For example, the period that is the sum of one display driving period D and one touch driving period T can be a frame time. In this case, one display driving period D can correspond to an active time among the active time and a blank time included in one frame time, and one touch driving period T can correspond to a blank time among the active time and blank time included in one frame time.

As another example, two or more display driving periods D can be a period during which display driving is performed to display an image on the entire screen. For example, the time period that is the sum of two or more display driving periods D and two or more touch driving periods T can be a frame time. In this case, one frame time can include two or more sub-frame times. Each of the two or more sub-frame times can include a sub-active time and a sub-blank time. The time summing one display driving period D and one touch driving period T can be one sub-frame time among two or more sub-frame times included in one frame time. One display driving period D included in one sub-frame time can correspond to a sub-active time, and one touch driving period T can correspond to a sub-blank time.

As another example of the time division driving method, as illustrated in FIG. 24, a plurality of display driving periods D and one touch driving period T can alternately proceed. For example, a plurality of display driving periods D can proceed, and then one touch driving period T can proceed.

According to the example of FIG. 24, four display driving periods D can be performed, and then one touch driving period T can be performed. For example, the time summing four display driving periods D and one touch driving period T can correspond to one sub-frame time, and the time summing four sub-frame times can correspond to one frame time for displaying an image on the entire screen.

According to the example of FIG. 24, four touch driving periods T included in one frame time can include self-sensing-based touch driving periods T and mutual-sensing-based touch driving periods T that are alternately proceeded. For example, among the four touch driving periods T included in one frame time, the first and third touch driving periods T can be self-sensing-based touch driving periods T, and the second and fourth touch driving periods T can be mutual-sensing-based touch driving periods T.

Self-sensing-based touch driving can be a touch driving for determining the occurrence of the touch and/or a touch coordinate based on the capacitance (e.g., self-capacitance) between a plurality of row lines RL corresponding to a touch electrode TE and a touch object (e.g., a finger, a pen, etc.).

Mutual-sensing-based touch driving can be a touch driving for determining the occurrence of the touch and/or a touch coordinate based on the capacitance (e.g., mutual-capacitance) between a plurality of row lines RL corresponding to a touch electrode TE and a plurality of row lines RL corresponding to another touch electrode TE.

Referring to FIG. 23, a plurality of row lines RL can simultaneously perform the role of a cathode electrode (or an anode electrode) for display driving and the role of a touch sensor (e.g., touch electrode) for touch driving. Therefore, the electrical state of the row line RL during the display driving period D and the electrical state of the row line RL during the touch driving period T can be different.

One row line RL among the plurality of row lines RL can be supplied with a first low-potential voltage VSS1 during a first period PT1, and can be supplied with a second low-potential voltage VSS2 during a second period PT2 different from the first period PT1.

The first period PT1 and the second period PT2 can be periods included in one display driving period D or periods included in different display driving periods D.

The first low-potential voltage VSS1 and the second low-potential voltage VSS2 are a type of low-potential voltage VSS and can be a row line voltage applied to the row line RL. In addition, the first low-potential voltage VSS1 and the second low-potential voltage VSS2 can be a voltage (for example, a cathode voltage or an anode voltage) applied to the second electrode Erl of the light emitting devices ED connected to the row line RL.

Among the first low-potential voltage VSS1 and the second low-potential voltage VSS2, the first low-potential voltage VSS1 can be a low-potential voltage for driving the display-on, and the second low-potential voltage VSS2 can be a low-potential voltage for driving the display-off.

The first low-potential voltage VSS1 can be a voltage lower than the second low-potential voltage VSS2. For example, the second low-potential voltage VSS2 can be a higher voltage than the first low-potential voltage VSS1. Accordingly, during the first period PT1, the voltage difference between the first electrode Ecl and the second electrode Erl of the light emitting device ED can be higher than the threshold voltage of the light emitting device ED. Accordingly, the light emitting device ED can be in a state capable of emitting light. Then, during the second period PT2, the voltage difference between the first electrode Ecl and the second electrode Erl of the light emitting device ED can be lower than the threshold voltage of the light emitting device ED. Accordingly, the light emitting device ED can be in a state in which it cannot emit light.

Meanwhile, one of the plurality of row lines RL can be supplied with a touch driving signal TDS, which is a signal whose voltage level swings, during a third period PT3 different from the first period PT1 and the second period PT2.

The third period PT3 can be a period included in the touch driving period T.

The touch driving signal TDS can be a signal having a predetermined frequency and whose voltage level fluctuates. The touch driving signal TDS can be a signal that swings between a predefined high voltage and a low voltage. For example, the high voltage can be a second low-potential voltage VSS2, and the low voltage can be a third low-potential voltage VSS3. The amplitude of the touch driving signal TDS can be a voltage difference between the high voltage and the low voltage. For example, the third low-potential voltage VSS3 can be a voltage lower than the second low-potential voltage VSS2 and can be the same as or different from the first low-potential voltage VSS1. For example, the third low-potential voltage VSS3 can be a voltage higher than the first low-potential voltage VSS1 and lower than the second low-potential voltage VSS2.

Depending on the driving type and driving timing, each of the plurality of row lines RL can be driven in a predetermined method.

For example, the display-on driving for each of the plurality of row lines RL can be performed sequentially. For another example, the display-on driving for each of the plurality of row lines RL can be performed simultaneously. For another example, the display-on driving for each of two or more row lines RL among the plurality of row lines RL can be performed simultaneously.

For example, during a specific display driving period, among the plurality of row lines RL arranged in the unit driving area UDA, display-on driving can be performed for at least one row line RL, and display-off driving can be performed for the remaining row lines RL without display-on driving.

The display-on driving performed for a specific row line RL can mean that a first low-potential voltage VSS1 of a predefined level is supplied to the corresponding row line RL.

When the display-on driving for a specific row line RL is performed, the light emitting devices ED arranged corresponding to the corresponding row line RL can emit light.

The display-off driving performed for a specific row line RL without display-on driving can mean that a second low-potential voltage VSS2 of a predefined level is supplied to the corresponding row line RL. Here, the second low-potential voltage VSS2 can be a higher voltage than the first low-potential voltage VSS1.

When display-off driving is performed for a specific row line RL, the light emitting devices ED arranged corresponding to the row line RL may not emit light.

For example, a first row line RL among the plurality of row lines RL can be supplied with a first low-potential voltage VSS1 during a first period, and can be supplied with a second low-potential voltage VSS2 higher than the first low-potential voltage VSS1 during a second period different from the first period. For example, the first period and the second period can be included in one display driving period. For another example, the first period and the second period can be included in different display driving periods.

The situation in the display panel 110 during the first to third periods PT1, PT2 and PT3 will be described again as follows.

During the first period PT1, the first row line RL among the plurality of row lines RL can be supplied with a first low-potential voltage VSS1. Accordingly, display-on driving can be performed on the first row line RL during the first period PT1.

During a second period PT2 different from the first period PT1, the first row line RL among the plurality of row lines RL can be supplied with a second low-potential voltage VSS2 higher than the first low-potential voltage VSS1. Accordingly, during the second period PT2, display-off driving can be performed on the first row line RL.

During a third period PT3 different from the first period PT1 and the second period PT2, the first row line RL among the plurality of row lines RL can be supplied with a touch driving signal TDS, which is a signal whose voltage level swings. For example, during the third period PT3, the first row line RL can function as a touch sensor.

The plurality of row lines RL can further include a second row line RL different from the first row line RL.

The plurality of column lines CL can include a first column line CL overlapping with the first row line RL and the second row line RL.

In addition, the first row line RL, the second row line RL, and the first column line CL can be arranged together in a touch subpixel area TSP which is one unit driving area UDA. The first row line RL, the second row line RL, and the first column line CL can be driven by the same driver DRV.

During the first period PT1 in which display-on driving is performed in the first row line RL, the second row line RL can be supplied with the second low-potential voltage VSS2. For example, during the first period PT1, display-on driving can be performed in the first row line RL, and display-off driving can be performed in the second row line RL.

The plurality of light emitting devices ED can include a first light emitting device ED having a first electrode connected to a first column line CL and a second electrode connected to a first row line RL, and a second light emitting device ED having a first electrode connected to the first column line CL and a second electrode connected to a second row line RL.

During the first period PT1, display-on driving is performed on the first row line RL, and display-off driving is performed on the second row line RL. Accordingly, during the first period PT1, the first light emitting device ED can emit light, and the second light emitting device ED may not emit light.

During the third period PT3, the voltage difference between the first column line CL and the first row line RL can be less than the threshold voltage of the first light emitting device ED. Accordingly, during the third period PT3, the first light emitting device ED may not emit light.

The plurality of drivers DRV can be positioned closer to the substrate 210 than the plurality of light emitting devices ED.

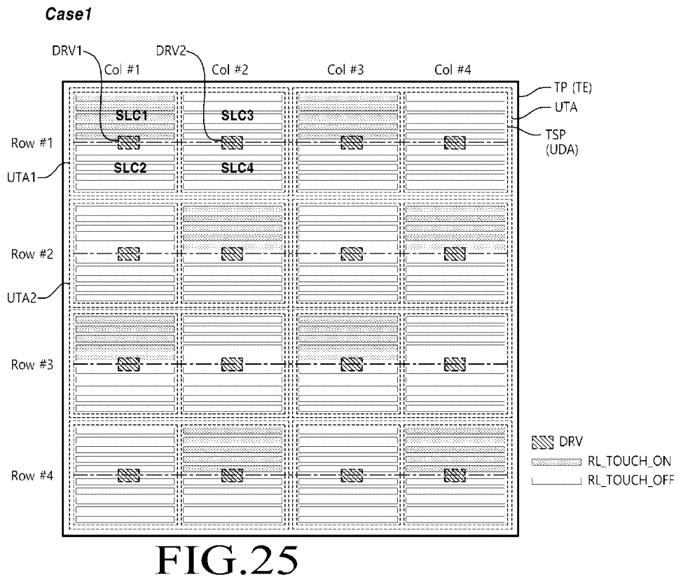

FIGS. 25 to 28 are example diagrams of a touch driving situation for one touch pixel area TP during a touch driving period T of a display device 100 according to embodiments of the present disclosure.

The touch pixel area TP illustrated in FIG. 25 is the substantially same as the touch pixel area TP illustrated in FIG. 22. However, the touch pixel areas TP illustrated in FIG. 22 and FIG. 25 differ in a row line RL_TOUCH_ON that is driven among the row lines RL_TOUCH_ON and RL_TOUCH_OFF included in the touch pixel area TP.

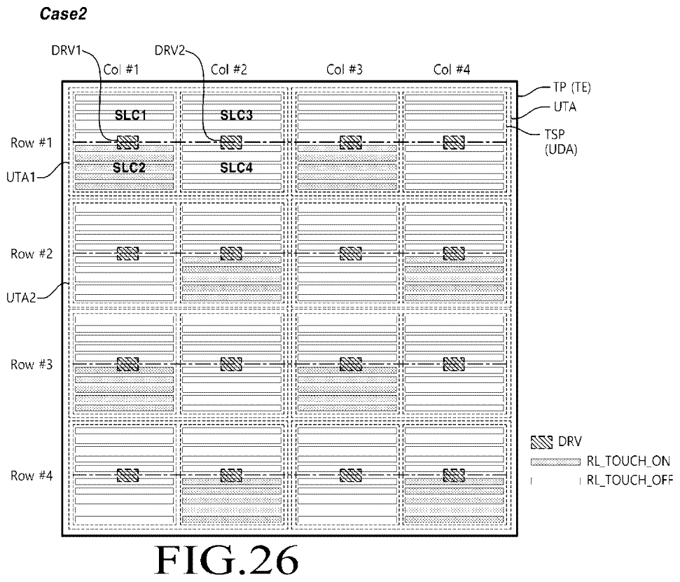

Referring to FIG. 25, the touch pixel area TP can include a plurality of unit touch driving areas UTA. Each of the plurality of unit touch driving areas UTA can include a plurality of sub-touch driving areas SLC. Referring to FIG. 26, one touch pixel area TP can include eight unit touch driving areas UTA. Each of the eight unit touch driving areas UTA can include four sub-touch driving areas SLC1, SLC2, SLC3 and SLC4. A plurality of drivers DRV can be disposed in the touch pixel area TP. Each of the plurality of drivers DRV can drive two sub-touch driving areas SLC.

A first driver DRV1 can drive a first sub-touch driving area SLC1 and a second sub-touch driving area SLC2.

A second driver DRV2 can drive a third sub-touch driving area SLC3 and a fourth sub-touch driving area SLC4.

The plurality of drivers DRV can supply a touch driving signal to all of the plurality of sub-touch driving areas SLC. Alternatively, the plurality of drivers DRV can supply a touch driving signal only to some of the plurality of sub-touch driving areas SLC. Supplying touch driving signals only to some of the plurality of sub-touch driving areas SLC can be defined as a “partial touch electrode driving.”

In the case of supplying touch driving signals only to some of the plurality of sub-touch driving areas SLCs, the display device 100 can be driven at low power. In the following description, it is assumed that the touch driving signal is supplied only to some of the plurality of sub-touch driving areas SLC.

A first unit touch driving area UTA1 can include four sub-touch driving areas SLC1, SLC2, SLC3 and SLC4. In this case, the sub-touch driving area SLC1 located at the upper left of the first unit touch driving area UTA1 can receive a touch driving signal, and the remaining sub-touch driving areas SLC2, SLC3 and SLC4 may not receive a touch driving signal. Referring to FIG. 25, the first unit touch driving area UTA1 is arranged in a first row Row #1. The unit touch driving areas UTA arranged in the first row Row #1 and a third row Row #3 can also receive a touch driving signal from the sub-touch driving area SLC located at the upper left.

A second unit touch driving area UTA2 can include four sub-touch driving areas SLC1, SLC2, SLC3 and SLC4. In this case, the sub-touch driving area SLC located at the upper right of the second unit touch driving area UTA2 can receive a touch driving signal, and the remaining sub-touch driving areas SLC may not receive a touch driving signal. Referring to FIG. 25, the second unit touch driving area UTA2 is arranged in the second row Row #2. The unit touch driving areas UTA arranged in the second row Row #2 and a fourth row Row #4 can also receive a touch driving signal from the sub-touch driving area SLC located at the upper right.

Since the sub-touch driving areas SLC receiving the touch driving signal are evenly spaced from each other, the self-capacitance can be formed relatively evenly. Accordingly, self-capacitance-based touch sensing can be performed more efficiently.

FIGS. 26 to 28 illustrate other embodiments in which a touch driving signal is supplied to some sub-touch driving areas SLC.

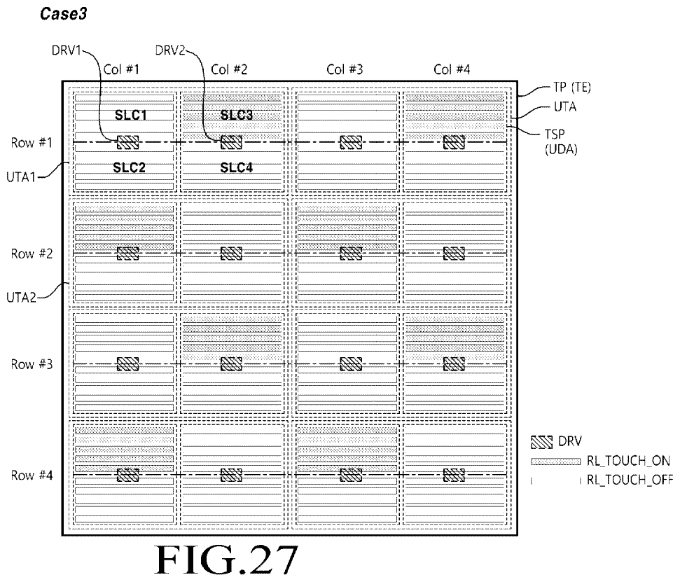

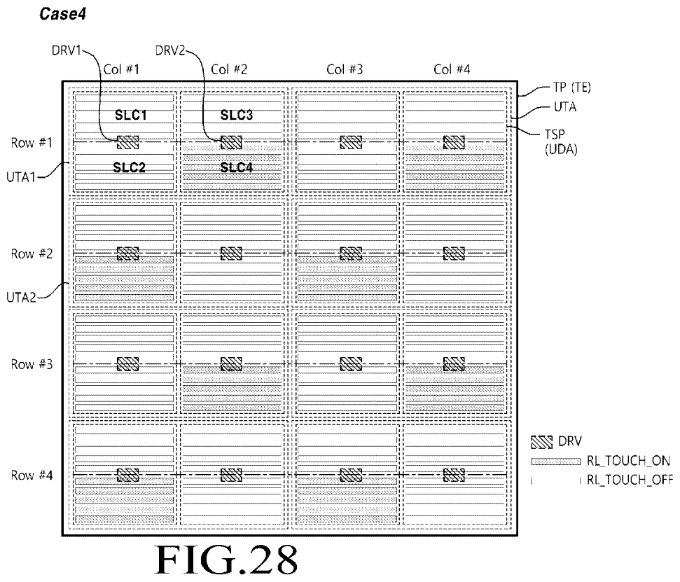

An example of supplying a touch driving signal to some sub-touch driving areas SLC illustrated in FIG. 25 can be defined as a first example Case1. In addition, an example in which a touch driving signal is supplied to some sub-touch driving areas SLC illustrated in FIG. 26 can be defined as a second example Case2. An example in which a touch driving signal is supplied to some sub-touch driving areas SLC illustrated in FIG. 27 can be defined as a third example Case3. An example in which a touch driving signal is supplied to some sub-touch driving areas SLC illustrated in FIG. 28 can be defined as a fourth example Case4.

Example 1 illustrated in FIG. 25 can be defined as “First Example (Case1).” Example 2 illustrated in FIG. 26 can be defined as “the second example (Case2)”. Example 3 illustrated in FIG. 27 can be defined as “the third example (Case3)”. Example 4 illustrated in FIG. 28 can be defined as “the fourth example (Case4)”.

Referring to FIG. 26, a first unit touch driving area UTA1 can include four sub-touch driving areas SLC1, SLC2, SLC3 and SLC4. In this case, the sub-touch driving area SLC2 located at the lower left of the first unit touch driving area UTA1 can receive a touch driving signal, and the remaining sub-touch driving areas SLC1, SLC3 and SLC4 may not receive a touch driving signal. Referring to FIG. 26, the first unit touch driving area UTA1 is arranged in the first row Row #1. The unit touch driving areas UTA arranged in the first row Row #1 and the third row Row #3 can also receive touch driving signals from the sub-touch driving area SLC located at the lower left.

The second unit touch driving area UTA2 can include four sub-touch driving areas SLC1, SLC2, SLC3 and SLC4. In this case, the sub-touch driving area SLC located at the lower right of the second unit touch driving area UTA2 can receive touch driving signals, and the remaining sub-touch driving areas SLC may not receive touch driving signals. Referring to FIG. 26, the second unit touch driving area UTA2 is arranged in the second row Row #2. The unit touch driving areas UTA arranged in the second row Row #2 and fourth row Row #4 can also receive the touch driving signal from the sub-touch driving area SLC located at the lower right.

Referring to FIG. 27, the first unit touch driving area UTA1 can include four sub-touch driving areas SLC1, SLC2, SLC3 and SLC4. In this case, the sub-touch driving area SLC3 located at the upper right of the first unit touch driving area UTA1 can receive a touch driving signal, and the remaining sub-touch driving areas SLC1, SLC2 and SLC4 may not receive a touch driving signal. Referring to FIG. 27 the first unit touch driving area UTA1 is arranged in the first row Row #1. The unit touch driving areas UTA arranged in the first row Row #1 and the third row Row #3 can also receive a touch driving signal from the sub-touch driving area SLC located at the upper right.

The second unit touch driving area UTA2 can include four sub-touch driving areas SLC1, SLC2, SLC3 and SLC4. In this case, the sub-touch driving area SLC located at the upper left of the second unit touch driving area UTA2 can receive a touch driving signal, and the remaining sub-touch driving areas may not receive a touch driving signal. Referring to FIG. 27, the second unit touch driving area UTA2 is arranged in the second row Row #2. The unit touch driving areas UTA arranged in the second row Row #2 and the fourth row Row #4 can also receive a touch driving signal from the sub-touch driving area SLC located at the upper left.

Referring to FIG. 28, the first unit touch driving area UTA1 can include four sub-touch driving areas SLC1, SLC2, SLC3 and SLC4. In this case, the sub-touch driving area SLC4 located at the lower right of the first unit touch driving area UTA1 can receive a touch driving signal, and the remaining sub-touch driving areas SLC1, SLC2 and SLC3 may not receive a touch driving signal. Referring to FIG. 28, the first unit touch driving area UTA1 is arranged in the first row Row #1. The unit touch driving areas UTA arranged in the first row Row #1 and the third row Row #3 can also receive a touch driving signal from the sub-touch driving area SLC located at the lower right.

The second unit touch driving area UTA2 can include four sub-touch driving areas SLC1, SLC2, SLC3 and SLC4. In this case, the sub-touch driving area SLC located at the lower left of the second unit touch driving area UTA2 can receive a touch driving signal, and the remaining sub-touch driving areas SLC may not receive a touch driving signal. Referring to FIG. 28, the second unit touch driving area UTA2 is arranged in the second row Row #2. The unit touch driving areas UTA arranged in the second row Row #2 and the fourth row Row #4 can also receive a touch driving signal from the sub-touch driving area SLC located at the lower left.

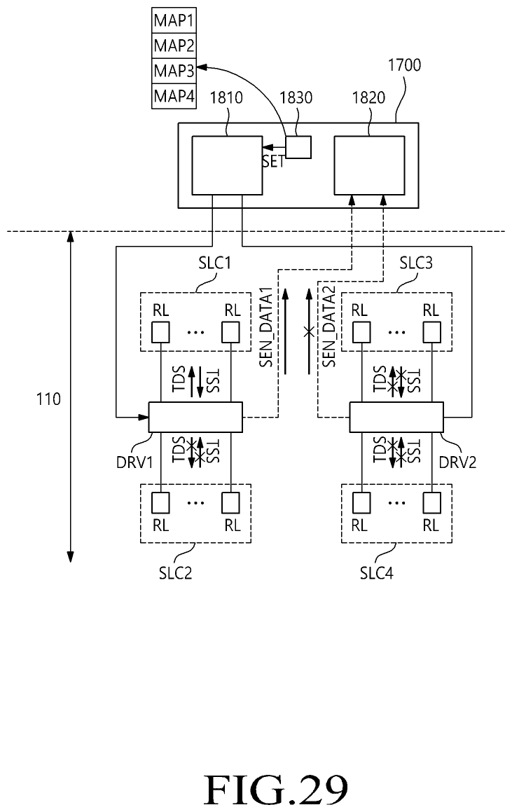

FIG. 29 schematically illustrates a touch control circuit 1700, a first driver DRV1, a second driver DRV2, and sub-touch driving areas SLC1, SLC2, SLC3 and SLC4 according to embodiments of the present disclosure.

Referring to FIG. 29, the touch control circuit 1700 can include a signal supply circuit 1810, a touch sensing circuit 1820, and a lookup table 1830. The signal supply circuit 1810 can supply a touch driving signal TDS or a signal that is the basis of the touch driving signal TDS to each of the plurality of drivers DRV. The touch sensing circuit 1820 can receive sensing data SEN_DATA from the plurality of drivers DRV. The lookup table 1830 can store touch map data.

A first sub-touch driving area SLC1, a second sub-touch driving area SLC2, a third sub-touch driving area SLC3, and a fourth sub-touch driving area SLC4 are illustrated. The first sub-touch driving area SLC1, the second sub-touch driving area SLC2, the third sub-touch driving area SLC3, and the fourth sub-touch driving area SLC4 illustrated in FIG. 29 can be included in the first unit touch driving area UTA1 illustrated in FIG. 25.

FIG. 29 briefly illustrates a first driver DRV1 supplying a touch driving signal TDS to the first sub-touch driving area SLC1 and the second sub-touch driving area SLC2, a second driver DRV2 supplying a touch driving signal TDS to the third sub-touch driving area SLC3 and the fourth sub-touch driving area SLC4, and a touch control circuit 1700.

Referring to FIG. 29, the first driver DRV1 can supply a touch driving signal TDS to only some of the row lines RL electrically connected to the first driver DRV1. In this case, the second driver DRV2 may not supply a touch driving signal TDS to all of the row lines RL electrically connected to the second driver DRV2.

A sub-touch driving area SLC supplied with a touch driving signal TDS can be defined as a target sub-touch driving area. The touch control circuit 1700 can supply a touch driving signal TDS to a plurality of row lines RL arranged in a target sub-touch driving area SLC1 selected from a plurality of sub-touch driving areas SLC1, SLC2, SLC3 and SLC4 during a touch driving.

When supplying the touch driving signal TDS to some sub-touch driving areas SLC, the second driver DRV2 does not transmit second sensing data SEN_DATA2 to the touch sensing circuit 1820. In this case, the first driver DRV1 can transmit first sensing data SEN_DATA1 to the touch sensing circuit 1820.

However, when the touch driving signal TDS is supplied to all sub-touch driving areas SLC, the first driver DRV1 can transmit the first sensing data SEN_DATA1 to the touch sensing circuit 1820. In addition, the second driver DRV2 can transmit the second sensing data SEN_DATA2 to the touch sensing circuit 1820.

The touch control circuit 1700 can include a lookup table 1830. The lookup table 1830 can store touch map data for all sub-touch driving areas SLC. The touch map data can include compensation data for compensating the sensing data SEN_DATA.

Since the touch map data for all sub-touch driving areas SLC are stored in the lookup table 1830, the display device 100 can be driven by any one of the first example (Case1) illustrated in FIG. 25, the second example (Case2) illustrated in FIG. 26, the third example (Case3) illustrated in FIG. 27, and the fourth example (Case4) illustrated in FIG. 28.

For example, if the display device 100 is driven as in the first example (Case1), the touch control circuit 1700 can retrieve the touch map data for the sub-touch driving areas SLC1, SLC2, SLC3 and SLC4 illustrated in FIG. 25 from the lookup table 1830. Referring to FIG. 29, the touch control circuit 1700 can control the first driver DRV1 to supply the touch driving signal TDS to the first sub-touch driving area SLC1. At this time, the first driver DRV1 may not supply the touch driving signal TDS to the second sub-touch driving area SLC2. In addition, the second driver DRV2 may not supply the touch driving signal TDS to the third sub-touch driving area SLC3 and the fourth sub-touch driving area SLC4.

Meanwhile, the plurality of drivers DRV can be driven by one of the first example (Case1) to the fourth example (Case4), and then driven by another of the first example (Case1) to the fourth example (Case4).

For example, the plurality of drivers DRV can be driven by the first example (Case1), and then driven by one of the second example (Case2), the third example (Case3), and the fourth example (Case4). If the touch control circuit 1700 detects abnormal sensing data SEN_DATA, the plurality of drivers DRV can change the driving method. Alternatively, if the user of the display device 100 changes the setting of the driving method, the plurality of drivers DRV can change the driving method.

However, the plurality of drivers DRV can be driven by the first example (Case1), and then not driven by another example. In this case, the plurality of drivers DRV can continue to be driven as the first example (Case1). If the touch control circuit 1700 does not detect abnormal sensing data SEN_DATA, the plurality of drivers DRV can maintain the driving mode. Alternatively, if the user of the display device 100 does not change the setting of the driving mode, the plurality of drivers DRV can maintain the driving mode.

The touch control circuit 1700 can select a target sub-touch driving area SLC among the plurality of sub-touch driving areas SLCs by referring to the touch map data including the setting information of the target sub-touch driving area SLC.

The display device 100 according to embodiments of the present disclosure can further include a lookup table 1830 that stores the touch map data.

The touch control circuit 1700 can select one of the first sub-touch driving area SLC1, the second sub-touch driving area SLC2, the third sub-touch driving area SLC3, and the fourth sub-touch driving area SLC4 as a target sub-touch driving area SLC by referring to touch map data including setting information of the target sub-touch driving area SLC.

The touch map data can include first touch map data MAP1 for selecting the first sub-touch driving area SLC1 as the target sub-touch driving area SLC, second touch map data MAP2 for selecting the second sub-touch driving area SLC2 as the target sub-touch driving area SLC, third touch map data MAP3 for selecting the third sub-touch driving area SLC3 as the target sub-touch driving area SLC, and fourth touch map data MAP4 for selecting the fourth sub-touch driving area SLC4 as the target sub-touch driving area SLC. The touch control circuit 1700 can refer to one of the touch map data MAP1, MAP2, MAP3 and MAP4 based on the touch map selection information.

The touch map selection information can be fixed information. The touch map selection information can be information that varies depending on an event. A specific sub-touch driving area among the plurality of sub-touch driving areas can be fixedly set as the target sub-touch driving area SLC. Alternatively, one sub-touch driving area among the plurality of sub-touch driving areas can be variably set as the target sub-touch driving area.

Meanwhile, the touch control circuit 1700 can sense touch and determine whether the touch sensitivity is defective based on the first sensing data SEN_DATA1. The first driver DRV1 can be electrically connected to a plurality of row lines RL. The first driver DRV1 can receive a touch sensing signal TSS from one of the row lines RL. The first driver DRV1 can convert the touch sensing signal TSS into the first sensing data SEN_DATA1. The first driver DRV1 can transmit the first sensing data SEN_DATA1 to the touch control circuit 1700. The touch control circuit 1700 can also receive sensing data SEN_DATA for other row lines RL from the first driver DRV1. The touch control circuit 1700 can generate the first integrated sensing data SEN_DATA by adding all the sensing data SEN_DATA received from the first driver DRV1. Hereinafter, it will be described a case in which the touch control circuit 1700 determines a normality of the touch based on the first integrated sensing data SEN_DATA.

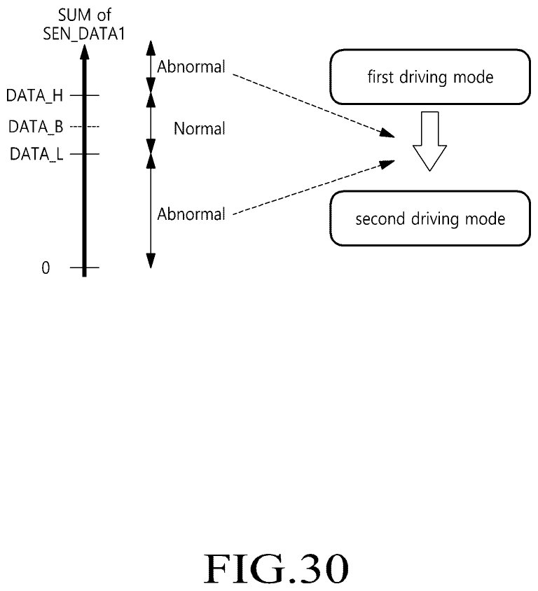

FIG. 30 is a diagram regarding the determination of the defective touch sensitivity according to embodiments of the present disclosure.

Referring to FIG. 30, a range of the first integrated sensing data SEN_DATA (the sum of SEN_DATA1) can include a normal data range Normal and an abnormal data range Abnormal.

The normal data range Normal can be a data range when the touch operation is performed normally.

The normal data range Normal can include upper limit normal data DATA_H and lower limit normal data DATA_L. The upper limit normal data DATA_H can be greater than the lower limit normal data DATA_L.

If the first integrated sensing data SEN_DATA is included between the upper limit normal data DATA_H and the lower limit normal data DATA_L, the first integrated sensing data SEN_DATA can be determined as normal data.

The first integrated sensing data SEN_DATA, which is normal data, can be identical to the upper limit normal data DATA_H. The first integrated sensing data SEN_DATA, which is normal data, can be identical to the lower limit normal data DATA_L.

The baseline data DATA_B can have a value greater than the lower limit normal data DATA_L and less than the upper limit normal data DATA_H. If the first integrated sensing data SEN_DATA is greater than the baseline data DATA_B, there can be determined that there is a touch.

The abnormal data range Abnormal can be a data range when the touch operation is performed abnormally.

If the first integrated sensing data SEN_DATA is greater than the upper limit normal data DATA_H, the first integrated sensing data SEN_DATA can be determined as abnormal data.

If the first integrated sensing data SEN_DATA is less than the lower limit normal data DATA_L, the first integrated sensing data SEN_DATA can be determined as abnormal data.

If the first integrated sensing data SEN_DATA is included in the abnormal data range Abnormal, the touch driving method can be changed. The target sub-touch driving area can be changed if the sensing data corresponds to predefined abnormal data. For example, the touch driving can proceed in the form of the first example (Case1) illustrated in FIG. 25, and then change to one of the other examples.

This can be defined as proceeding to the first driving mode and then proceeding to the second driving mode. For example, the first driving mode can be the first example (Case1) illustrated in FIG. 25, and the second driving mode can be the second example (Case2) illustrated in FIG. 26. For example, the first driving mode can be the fourth example (Case4) illustrated in FIG. 28, and the second driving mode can be the third example (Case3) illustrated in FIG. 27.

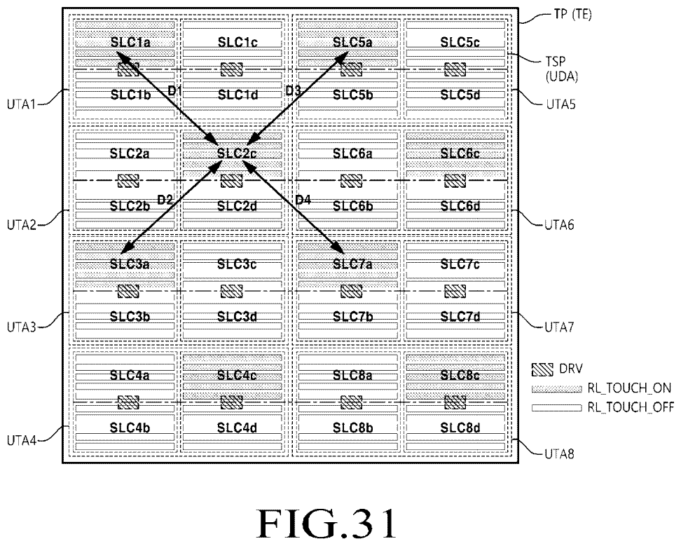

FIG. 31 illustrates a touch driving situation for one touch pixel area TP according to embodiments of the present disclosure.

The touch driving situation illustrated in FIG. 31 is the same as the touch driving situation illustrated in FIG. 25.

Referring to FIG. 31, a plurality of unit touch driving areas UTA1, . . . , UTA8 are illustrated. Each of the plurality of unit touch driving areas UTA1, . . . , UTA8 can include a target sub-touch driving area. In this case, each of the target sub-touch driving areas can be arranged at a position that is farthest from each other. Specific examples are as follows.

A first unit touch driving area UTA1 can be arranged in the same row as a fifth unit touch driving area UTA5.

A second unit touch driving area UTA2 can be arranged in the same row as a sixth unit touch driving area UTA6. The second unit touch driving area UTA2 can be arranged adjacent to the first unit touch driving area UTA1.

A third unit touch driving area UTA3 can be arranged in the same row as a seventh unit touch driving area UTA7. The third unit touch driving area UTA3 can be disposed adjacent to the second unit touch driving area UTA2.

A fourth unit touch driving area UTA4 can be arranged in the same row as an eighth unit touch driving area UTA8. The fourth unit touch driving area UTA4 can be disposed adjacent to the third unit touch driving area UTA3.

The first unit touch driving area UTA1 can include a first target sub-touch driving area SLC1a. The first unit touch driving area UTA1 can include four sub-touch driving areas SLC1a, SLC1b, SLC1c and SLC1d. The first sub-touch driving area SLC1a can be disposed at the upper left. The second sub-touch driving area SLC1b can be disposed at the lower left. The third sub-touch driving area SLC1c can be disposed at the upper right. The fourth sub-touch driving area SLC1d can be disposed at the lower right. The first target sub-touch driving area SLC1a can be disposed at the upper left.

The third unit touch driving area UTA3 can include four sub-touch driving areas SLC3a, SLC3b, SLC3c and SLC3d. A third target sub-touch driving area SLC3a can be disposed at the upper left. The fifth unit touch driving area UTA5 can include four sub-touch driving areas SLC5a, SLC5b, SLC5c and SLC5d. A fifth target sub-touch driving area SLC5a can be disposed at the upper left. The seventh unit touch driving area UTA7 can include four sub-touch driving areas SLC7a, SLC7b, SLC7c and SLC7d. A seventh target sub-touch driving area SLC7a can be disposed at the upper left.

The second unit touch driving area UTA2 can include four sub-touch driving areas SLC2a, SLC2b, SLC2c and SLC2d. A second target sub-touch driving area SLC2c can be disposed at the upper right. The fourth unit touch driving area UTA4 can include four sub-touch driving areas SLC4a, SLC4b, SLC4c and SLC4d. A fourth target sub-touch driving area SLC4c can be disposed at the upper right. The sixth unit touch driving area UTA6 can include four sub-touch driving areas SLC6a, SLC6b, SLC6c and SLC6d. A sixth target sub-touch driving area SLC6c can be disposed at the upper right. The eighth unit touch driving area UTA8 can include four sub-touch driving areas SLC8a, SLC8b, SLC8c and SLC8d. An eighth target sub-touch driving area SLC8c can be disposed at the upper right.

The distance from the second target sub-touch driving area SLC2c to the first target sub-touch driving area SLC1a can be defined as a first distance D1. The distance from the second target sub-touch driving area SLC2c to the third target sub-touch driving area SLC3a can be defined as a second distance D2. The distance from the second target sub-touch driving area SLC2c to the fifth target sub-touch driving area SLC5a can be defined as a third distance D3. The distance from the second target sub-touch driving area SLC2c to the seventh target sub-touch driving area SLC7a can be defined as a fourth distance D4.

The length of the first distance D1, the length of the second distance D2, the length of the third distance D3, and the length of the fourth distance D4 can each be equal to each other. For example, when self-sensing-based touch sensing is performed, each of the sub-touch driving areas supplied with the touch driving signal can be arranged farthest from each other. Accordingly, self-capacitance can be formed relatively uniformly among each other.

The embodiments of the present disclosure can provide a display device driven by a new touch driving method by supplying the touch driving signal only to some touch electrodes.

The embodiments of the present disclosure can provide a display device capable of low power consumption by supplying the touch driving signal only to some touch electrodes.

Embodiments of the present disclosure can provide a display device capable of stably performing touch driving by changing from a first driving mode partial touch electrode driving to a second driving mode for the partial touch electrode driving.

A display device according to embodiments of the present disclosure can be described as follows.

A display device according to embodiments of the present disclosure can include a plurality of sub-touch driving areas arranged in a display area, a plurality of row lines arranged in each of the plurality of sub-touch driving areas, and a driving circuit corresponding to the plurality of sub-touch driving areas. The driving circuit can supply, during touch driving, a touch driving signal to a plurality of row lines arranged in a target sub-touch driving area selected from the plurality of sub-touch driving areas.

A specific sub-touch driving area among the plurality of sub-touch driving areas can be fixedly set as the target sub-touch driving area.

One sub-touch driving area among the plurality of sub-touch driving areas can be variably set as the target sub-touch driving area.

The driving circuit can select the target sub-touch driving area from among the plurality of sub-touch driving areas by referring to touch map data including setting information of the target sub-touch driving area.

The display device according to embodiments of the present disclosure can further include a lookup table storing the touch map data.

The plurality of sub-touch driving areas can include a first sub-touch driving area, a second sub-touch driving area, a third sub-touch driving area, and a fourth sub-touch driving area, and the driving circuit can includes a first driver connected to a plurality of row lines arranged in the first sub-touch driving area and a plurality of row lines arranged in the second sub-touch driving area, and a second driver connected to a plurality of row lines arranged in the third sub-touch driving area and a plurality of row lines arranged in the fourth sub-touch driving area. The target sub-touch driving area can be one of the first sub-touch driving area, the second sub-touch driving area, the third sub-touch driving area, and the fourth sub-touch driving area.

The driving circuit can select one of the first sub-touch driving area, the second sub-touch driving area, the third sub-touch driving area, and the fourth sub-touch driving area as the target sub-touch driving area by referring to touch map data including setting information of the target sub-touch driving area.

The touch map data can include first touch map data selecting the first sub-touch driving area as the target sub-touch driving area, second touch map data selecting the second sub-touch driving area as the target sub-touch driving area, third touch map data selecting the third sub-touch driving area as the target sub-touch driving area, and fourth touch map data selecting the fourth sub-touch driving area as the target sub-touch driving area. The driving circuit can refer to one of the first to fourth touch map data based on touch map selection information.

The touch map selection information can be fixed information.

The touch map selection information can be information varying depending on an event.

The display device according to embodiments of the present disclosure can further include a controller electrically connected to the driving circuit. The driving circuit can supply the touch driving signal to the plurality of row lines arranged in the target sub-touch driving area, sense the plurality of row lines arranged in the target sub-touch driving area, and output sensing data. The controller can sense a touch based on the sensing data.

The target sub-touch driving area can be changed if the sensing data corresponds to predefined abnormal data.

Each of the plurality of row lines can overlap with two or more light emitting devices.

The driving circuit can be disposed in the display area.

The display device according to embodiments of the present disclosure can further include a touch electrode including the plurality of sub-touch driving areas, and the touch electrode can include a plurality of unit touch driving areas. Each of the plurality of unit touch driving areas can include at least two sub-touch driving areas among the plurality of sub-touch driving areas.

The touch driving signal can be in the form of an AC voltage.

The display device according to embodiments of the present disclosure can further include a light emitting device disposed in the display area, and a voltage level of the touch driving signal can be outside a voltage range in which the light emitting device is able to emit light.

The display device according to embodiments of the present disclosure can further include a substrate including the display area, a plurality of pixels arranged in the display area and including a plurality of light emitting devices, a plurality of column lines electrically connected to a first electrodes of each of the plurality of light emitting devices, and a plurality of drivers disposed on the substrate, positioned in the display area, and configured to drive the plurality of column lines and the plurality of row lines. The plurality of row lines can be electrically connected to a second electrode of each of the plurality of light emitting devices.

The display area can include a plurality of unit driving areas corresponding to the plurality of drivers, and each of the plurality of unit driving areas can include two or more row lines among the plurality of row lines and two or more column lines among the plurality of column lines. Each of the plurality of drivers can include a row driver configured to drive two or more row lines arranged in a corresponding unit driving area among the plurality of row lines, and a column driver configured to drive two or more column lines arranged in a corresponding unit driving area among the plurality of column lines.

The display device according to embodiments of the present disclosure can further include a layer stack on the plurality of drivers disposed on the substrate, an optical layer disposed between the plurality of light emitting devices on the layer stack, an adhesive layer disposed on the plurality of light emitting devices and the optical layer, and a cover member disposed on the adhesive layer. The plurality of column lines can be arranged between the layer stack and the plurality of light emitting devices, and the plurality of row lines can be arranged on the plurality of light emitting devices and the optical layer.

The layer stack can include a side protection layer, an upper protection layer, and a plurality of insulating layers, and the plurality of insulating layers can include a first insulating layer on the upper protection layer and a second insulating layer on the first insulating layer. The layer stack can further include a plurality of line connection patterns connecting each of a plurality of lines including the plurality of row lines and the plurality of column lines to the plurality of drivers. The plurality of line connection patterns can include a first line connection pattern disposed on the side protection layer, a second line connection pattern disposed on the upper protection layer and electrically connected to the first line connection pattern through a hole in the upper protection layer, a third line connection pattern disposed on the first insulating layer and electrically connected to the second line connection pattern through a hole in the first insulating layer, and a fourth line connection pattern disposed on the second insulating layer and electrically connected to the third line connection pattern through a hole in the second insulating layer. The first line connection pattern can be electrically connected to one of the plurality of drivers, and the fourth line connection pattern can be electrically connected to a second electrode of at least one of the plurality of light emitting devices, or can be electrically connected to a first electrode of at least one of the plurality of light emitting devices.

The display device according to embodiments of the present disclosure can further include a touch ground disposed below the plurality of row lines.

The display device according to embodiments of the present disclosure can further include a guard driver that supplies a load-free driving signal having signal characteristics corresponding to the touch driving signal to the touch ground.

Each of the plurality of drivers can include an analog-to-digital converter that converts a signal sensed through at least one row line among the plurality of row lines into a digital sensing value.

The display device according to embodiments of the present disclosure can further include a plurality of light emitting devices disposed in the display area. The plurality of row lines can be supplied with a first low-potential voltage and a second low-potential voltage different from the first low-potential voltage during a display period in which the light emitting device is able to emit light, and the plurality of row lines can be supplied with the touch driving signal in the form of an AC voltage during the touch driving. The minimum voltage value of the touch driving signal can be greater than the first low-potential voltage.

The plurality of light emitting devices can emit light when the first low-potential voltage is supplied to the plurality of row lines, and the plurality of light emitting devices may not emit light when the second low-potential voltage different from the first low-potential voltage is supplied to the plurality of row lines.

The display device according to embodiments of the present disclosure can further include a first unit touch driving area including a first target sub-touch driving area, which is the target sub-touch driving area, a second unit touch driving area including a second target sub-touch driving area, and a third unit touch driving area including a third target sub-touch driving area. A distance from the second target sub-touch driving area to the first target sub-touch driving area can be equal to a distance from the second target sub-touch driving area to the third target sub-touch driving area.

A display device according to embodiments of the present disclosure can include a plurality of sub-touch driving areas disposed in a display area, a plurality of row lines and a plurality of column lines arranged in each of the plurality of sub-touch driving areas, a plurality of light emitting devices arranged in each of the plurality of sub-touch driving areas, and a driving circuit configured to drive the plurality of row lines and the plurality of column lines. Each of the plurality of column lines can be electrically connected in common with a first electrode of two or more light emitting devices among the plurality of light emitting devices, and each of the plurality of row lines can be electrically connected in common with a second electrode of two or more light emitting devices among the plurality of light emitting devices. A first low-potential voltage can be applied to at least some of a plurality of row lines arranged in each of the plurality of sub-touch driving areas during a display driving, and a touch driving signal can be applied to a plurality of row lines arranged in at least one of the plurality of sub-touch driving areas during a touch driving.

A display device according to embodiments of the present disclosure can include a first sub-touch driving area, a second sub-touch driving area disposed adjacent to the first sub-touch driving area, a first driver disposed between the first sub-touch driving area and the second sub-touch driving area, a third sub-touch driving area, a fourth sub-touch driving area disposed adjacent to the third sub-touch driving area, and a second driver disposed between the third sub-touch driving area and the fourth sub-touch driving area. When the first driver supplies a touch driving signal to one of the first sub-touch driving area and the second sub-touch driving area, the second driver may not supply a touch driving signal to the third sub-touch driving area and the fourth sub-touch driving area.

The display device according to embodiments of the present disclosure can further include a first unit touch driving area including a first target sub-touch driving area to which the touch driving signal is supplied among the first sub-touch driving area, the second sub-touch driving area, the third sub-touch driving area, and the fourth sub-touch driving area, a second unit touch driving area including a second target sub-touch driving area, a third unit touch driving area including a third target sub-touch driving area, a fourth unit touch driving area including a fourth target sub-touch driving area, and a fifth unit touch driving area including a fifth target sub-touch driving area. The distances from each of the first target sub-touch driving area to the fourth target sub-touch driving area to the fifth target sub-touch driving area can be equal to each other.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a plurality of sub-touch driving areas arranged in a display area;
a plurality of row lines arranged in each of the plurality of sub-touch driving areas; and
a driving circuit corresponding to the plurality of sub-touch driving areas,
wherein the driving circuit supplies, during touch driving, a touch driving signal to a plurality of row lines arranged in a target sub-touch driving area selected from the plurality of sub-touch driving areas.

2. The display device of claim 1, wherein a specific sub-touch driving area among the plurality of sub-touch driving areas is fixedly set as the target sub-touch driving area.

3. The display device of claim 1, wherein one sub-touch driving area among the plurality of sub-touch driving areas is variably set as the target sub-touch driving area.

4. The display device of claim 1, wherein the driving circuit selects the target sub-touch driving area from among the plurality of sub-touch driving areas by referring to touch map data including setting information of the target sub-touch driving area.

5. The display device of claim 4, further comprising a lookup table storing the touch map data.

6. The display device of claim 1, wherein the plurality of sub-touch driving areas include a first sub-touch driving area, a second sub-touch driving area, a third sub-touch driving area, and a fourth sub-touch driving area,
wherein the driving circuit includes:
a first driver connected to a plurality of row lines arranged in the first sub-touch driving area and a plurality of row lines arranged in the second sub-touch driving area, and
a second driver connected to a plurality of row lines arranged in the third sub-touch driving area and a plurality of row lines arranged in the fourth sub-touch driving area, and
wherein the target sub-touch driving area is one of the first sub-touch driving area, the second sub-touch driving area, the third sub-touch driving area, and the fourth sub-touch driving area.

7. The display device of claim 6, wherein the driving circuit selects one of the first sub-touch driving area, the second sub-touch driving area, the third sub-touch driving area, and the fourth sub-touch driving area as the target sub-touch driving area by referring to touch map data including setting information of the target sub-touch driving area.

8. The display device of claim 7, wherein the touch map data include:
first touch map data selecting the first sub-touch driving area as the target sub-touch driving area;
second touch map data selecting the second sub-touch driving area as the target sub-touch driving area;
third touch map data selecting the third sub-touch driving area as the target sub-touch driving area; and
fourth touch map data selecting the fourth sub-touch driving area as the target sub-touch driving area, and
wherein the driving circuit refers to one of the first to fourth touch map data based on touch map selection information.

9. The display device of claim 8, wherein the touch map selection information is fixed information.

10. The display device of claim 8, wherein the touch map selection information is information varying depending on an event.

11. The display device of claim 1, further comprising a controller electrically connected to the driving circuit,
wherein the driving circuit supplies the touch driving signal to the plurality of row lines arranged in the target sub-touch driving area, senses the plurality of row lines arranged in the target sub-touch driving area, and outputs sensing data, and
wherein the controller senses a touch based on the sensing data.

12. The display device of claim 11, wherein the target sub-touch driving area is changed when the sensing data corresponds to predefined abnormal data.

13. The display device of claim 1, wherein each of the plurality of row lines overlaps with two or more light emitting devices.

14. The display device of claim 1, wherein the driving circuit is disposed in the display area.

15. The display device of claim 1, further comprising a touch electrode including the plurality of sub-touch driving areas,
wherein the touch electrode includes a plurality of unit touch driving areas, and
wherein each of the plurality of unit touch driving areas includes at least two sub-touch driving areas among the plurality of sub-touch driving areas.

16. The display device of claim 1, wherein the touch driving signal is in the form of an AC voltage.

17. The display device of claim 16, further comprising a light emitting device disposed in the display area,
wherein a voltage level of the touch driving signal is outside a voltage range in which the light emitting device is able to emit light.

18. The display device of claim 1, further comprising:
a substrate including the display area;
a plurality of pixels arranged in the display area and including a plurality of light emitting devices;
a plurality of column lines electrically connected to a first electrode of each of the plurality of light emitting devices; and
a plurality of drivers disposed on the substrate, positioned in the display area, and configured to drive the plurality of column lines and the plurality of row lines,
wherein the plurality of row lines are electrically connected to a second electrode of each of the plurality of light emitting devices.

19. The display device of claim 18, wherein the display area includes a plurality of unit driving areas corresponding to the plurality of drivers,
wherein each of the plurality of unit driving areas includes two or more row lines among the plurality of row lines and two or more column lines among the plurality of column lines, and
wherein each of the plurality of drivers includes:
a row driver configured to drive two or more row lines arranged in a corresponding unit driving area among the plurality of row lines; and
a column driver configured to drive two or more column lines arranged in a corresponding unit driving area among the plurality of column lines.

20. The display device of claim 18, further comprising:
a layer stack on the plurality of drivers disposed on the substrate;
an optical layer disposed between the plurality of light emitting devices on the layer stack;
an adhesive layer disposed on the plurality of light emitting devices and the optical layer; and
a cover member disposed on the adhesive layer,
wherein the plurality of column lines are arranged between the layer stack and the plurality of light emitting devices, and
wherein the plurality of row lines are arranged on the plurality of light emitting devices and the optical layer.

21. The display device of claim 20, wherein the layer stack includes a side protection layer, an upper protection layer, and a plurality of insulating layers,
wherein the plurality of insulating layers include a first insulating layer on the upper protection layer and a second insulating layer on the first insulating layer,
wherein the layer stack further includes a plurality of line connection patterns connecting each of a plurality of lines including the plurality of row lines and the plurality of column lines to the plurality of drivers,
wherein the plurality of line connection patterns include:
a first line connection pattern disposed on the side protection layer;
a second line connection pattern disposed on the upper protection layer and electrically connected to the first line connection pattern through a hole in the upper protection layer;
a third line connection pattern disposed on the first insulating layer and electrically connected to the second line connection pattern through a hole in the first insulating layer; and
a fourth line connection pattern disposed on the second insulating layer and electrically connected to the third line connection pattern through a hole in the second insulating layer,
wherein the first line connection pattern is electrically connected to one of the plurality of drivers, and
wherein the fourth line connection pattern is electrically connected to a second electrode of at least one of the plurality of light emitting devices, or is electrically connected to a first electrode of at least one of the plurality of light emitting devices.

22. The display device of claim 1, further comprising a touch ground disposed below the plurality of row lines.

23. The display device of claim 22, further comprising a guard driver configured to supply a load-free driving signal having signal characteristics corresponding to the touch driving signal to the touch ground.

24. The display device of claim 18, wherein each of the plurality of drivers includes an analog-to-digital converter configured to convert a signal sensed through at least one row line among the plurality of row lines into a digital sensing value.

25. The display device of claim 1, further comprising a plurality of light emitting devices disposed in the display area,
wherein the plurality of row lines are supplied with a first low-potential voltage and a second low-potential voltage different from the first low-potential voltage during a display period in which the light emitting device is able to emit light,
wherein the plurality of row lines are supplied with the touch driving signal in the form of an AC voltage during the touch driving, and
wherein the minimum voltage value of the touch driving signal is greater than the first low-potential voltage.

26. The display device of claim 25, wherein the plurality of light emitting devices emit light when the first low-potential voltage is supplied to the plurality of row lines, and
wherein the plurality of light emitting devices do not emit light when the second low-potential voltage different from the first low-potential voltage is supplied to the plurality of row lines.

27. The display device of claim 1, further comprising:
a first unit touch driving area including a first target sub-touch driving area, which is the target sub-touch driving area;
a second unit touch driving area including a second target sub-touch driving area; and
a third unit touch driving area including a third target sub-touch driving area, and
wherein a distance from the second target sub-touch driving area to the first target sub-touch driving area is equal to a distance from the second target sub-touch driving area to the third target sub-touch driving area.

28. The display device of claim 15, wherein each of the plurality of unit touch driving areas includes the target sub-touch driving area, and
wherein the target sub-touch driving areas of the plurality of unit touch driving areas are arranged in a zigzag shape.

29. The display device of claim 15, wherein each of the plurality of unit touch driving areas includes the target sub-touch driving area, and each of the target sub-touch driving areas is arranged at a position that is farthest from each other.

30. The display device of claim 19, wherein the column driver includes:
an emission control transistor electrically connected between a first electrode of each of the plurality of light emitting devices and a driving voltage node, and
a driving transistor electrically connected between the driving voltage node and the emission control transistor.

31. The display device of claim 30, wherein the column driver further includes:
an initialization buffer connected between an initialization switch and an initialization voltage node for amplifying an initialization voltage applied to the initialization voltage node and supplying an amplified initialization voltage to a gate electrode of the driving transistor;
a pre-charge buffer connected between a pre-charge switch and a pre-charge voltage node for amplifying a pre-charge voltage applied to the pre-charge voltage node and supplying the amplified pre-charged voltage to a node between the emission control transistor and the driving transistor, and
a reset buffer connected between a reset switch and a reset voltage node for amplifying a reset voltage applied to the reset voltage node and supplying the amplified reset voltage to the first electrode.

32. The display device of claim 30, wherein the emission control transistor includes:
a first emission control transistor connected between the driving voltage node and the driving transistor, and
a second emission control transistor connected between the driving transistor and the first electrode.

33. The display device of claim 21, wherein the side protection layer, the upper protection layer, and the plurality of insulating layers are each composed of organic layers.

34. The display device of claim 26, wherein the second low-potential voltage is higher than the first low-potential voltage.

35. A display device comprising:
a plurality of sub-touch driving areas disposed in a display area;
a plurality of row lines and a plurality of column lines arranged in each of the plurality of sub-touch driving areas;
a plurality of light emitting devices arranged in each of the plurality of sub-touch driving areas; and
a driving circuit configured to drive the plurality of row lines and the plurality of column lines,
wherein each of the plurality of column lines is electrically connected in common with a first electrode of two or more light emitting devices among the plurality of light emitting devices,
wherein each of the plurality of row lines is electrically connected in common with a second electrode of two or more light emitting devices among the plurality of light emitting devices,
wherein a first low-potential voltage is applied to at least some of a plurality of row lines arranged in each of the plurality of sub-touch driving areas during a display driving,
wherein a touch driving signal is applied to a plurality of row lines arranged in at least one of the plurality of sub-touch driving areas during a touch driving.

36. The display device of claim 35, wherein the plurality of sub-touch driving areas include a first sub-touch driving area, a second sub-touch driving area, a third sub-touch driving area, and a fourth sub-touch driving area,
wherein the driving circuit includes;
a first driver connected to the plurality of row lines arranged in the first sub-touch driving area and the plurality of row lines arranged in the second sub-touch driving area, and
a second driver connected to the plurality of row lines arranged in the third sub-touch driving area and the plurality of row lines arranged in the fourth sub-touch driving area,
wherein the at least one of the plurality of sub-touch driving areas is a target sub-touch driving area, and the target sub-touch driving area is at least one of the first sub-touch driving area, the second sub-touch driving area, the third sub-touch driving area, and the fourth sub-touch driving area.

37. The display device of claim 36, further comprising a touch electrode including the plurality of sub-touch driving areas,
wherein the touch electrode includes a plurality of unit touch driving areas,
wherein each of the plurality of unit touch driving areas includes at least two sub-touch driving areas among the plurality of sub-touch driving areas, and
wherein each of the plurality of unit touch driving areas includes the target sub-touch driving area, and each of the target sub-touch driving areas is arranged at a position that is farthest from each other.

38. The display device of claim 36, wherein the driving circuit supplies the touch driving signal to the plurality of row lines arranged in the target sub-touch driving area, senses the plurality of row lines arranged in the target sub-touch driving area, and outputs sensing data, and
wherein the target sub-touch driving area is changed if the sensing data corresponds to predefined abnormal data.

39. A display device comprising:
a first sub-touch driving area;
a second sub-touch driving area disposed adjacent to the first sub-touch driving area;
a first driver disposed between the first sub-touch driving area and the second sub-touch driving area;
a third sub-touch driving area;
a fourth sub-touch driving area disposed adjacent to the third sub-touch driving area; and
a second driver disposed between the third sub-touch driving area and the fourth sub-touch driving area,
wherein, when the first driver supplies a touch driving signal to one of the first sub-touch driving area and the second sub-touch driving area, the second driver does not supply a touch driving signal to the third sub-touch driving area and the fourth sub-touch driving area.

40. The display device of claim 39, further comprising:
a first unit touch driving area including a first target sub-touch driving area to which the touch driving signal is supplied among the first sub-touch driving area, the second sub-touch driving area, the third sub-touch driving area, and the fourth sub-touch driving area;
a second unit touch driving area including a second target sub-touch driving area;
a third unit touch driving area including a third target sub-touch driving area;
a fourth unit touch driving area including a fourth target sub-touch driving area; and
a fifth unit touch driving area including a fifth target sub-touch driving area,
wherein the distances from each of the first target sub-touch driving area to the fourth target sub-touch driving area to the fifth target sub-touch driving area are equal to each other.

41. The display device of claim 39, wherein each of the sub-touch driving areas supplied with the touch driving signal is arranged farthest from each other.
